(19) United States
(12) Patent Application Publication
(10) Pub. No.: US 2024/0365577 A1
(43) Pub. Date: Oct. 31, 2024

(54) LIGHT EMITTING ELEMENT, AND DISPLAY DEVICE INCLUDING THE SAME

(71) Applicant: Samsung Display Co., Ltd., Yongin-si, Gyeonggi-do (KR)

(72) Inventors: HOJUNG SYN, Yongin-si (KR); SUNG-SOO BAE, Yongin-si (KR); CHANGWOONG CHU, Yongin-si (KR)

(21) Appl. No.: 18/534,508

(22) Filed: Dec. 8, 2023

(30) Foreign Application Priority Data
Feb. 17, 2023 (KR) 10-2023-0021489
May 9, 2023 (KR) 10-2023-0059592

(51) Int. Cl. H10K 50/13; H10K 59/35; H10K 85/60; H10K 102/00

(52) U.S. Cl. CPC H10K 50/13; H10K 59/35; H10K 85/626; H10K 85/633; H10K 85/657; H10K 85/6572; H10K 85/658; H10K 2102/351

(57) ABSTRACT

Light emitting element includes a first electrode, a hole transport region, a light emitting layer, an electron transport region, and a second electrode that are sequentially stacked. The light emitting layer includes a first sub light emitting layer adjacent the first electrode, a second sub light emitting layer on the first sub light emitting layer, and a light emitting auxiliary layer between the first sub light emitting layer and the second sub light emitting layer and including a plurality of auxiliary compounds. The light emitting auxiliary layer includes a first state in which an average separation distance between the auxiliary compounds is a first distance, and a second state in which an average separation distance between the auxiliary compounds is a second distance smaller than the first distance. An external quantum efficiency is larger when the light emitting auxiliary layer is in the second state than in the first state.

### CROSS-REFERENCE TO RELATED APPLICATIONS

This application claims priority to and the benefit of Korean Patent Application No. 10-2023-0021489, filed on Feb. 17, 2023, and Korean Patent Application No. 10-2023-059592, filed on May 9, 2023, in the Korean Intellectual Property Office, the entire content of each of which is hereby incorporated by reference.

### BACKGROUND

### 1. Field

One or more aspects of embodiments of the present disclosure relate to a light emitting element and a display device including the same, and, for example, a light emitting element including a light emitting auxiliary layer.

### 2. Description of the Related Art

One or more suitable display devices utilized in multimedia apparatuses such as televisions, mobile phones, tablet computers, navigation systems, and/or game consoles have been developed. In these display devices, an organic electroluminescence display device may be a so-called self-luminous type or kind of display element that includes organic compounds, quantum dots, and/or the like and is included in a light emitting layer arranged between facing electrodes. The self-luminous type or kind of display element causes a light emitting material in the organic electroluminescence display device to emit light to implement display (e.g., of an image).

Applying a light emitting element to display devices requires (or there is a desire for) high emission efficiency and a long lifespan of the light emitting element, and the development of materials and structures for a light emitting element capable of stably satisfying these requirements is continuously demanded. For example, in an effort to implement a light emitting element having relatively high efficiency and lifespan, the development of materials for a light emitting auxiliary layer having excellent or suitable energy level properties is being pursued.

### SUMMARY

The present disclosure provides a light emitting element having an improved lifespan and a display device including the same.

One or more embodiments of the present disclosure provides a light emitting element including a first electrode, a hole transport region provided on the first electrode, a light emitting layer provided on the hole transport region, an electron transport region provided on the light emitting layer, and a second electrode provided on the electron transport region, wherein the light emitting layer includes a first sub light emitting layer provided adjacent to the first electrode, a second sub light emitting layer provided on the first sub light emitting layer, and a light emitting auxiliary layer provided between the first sub light emitting layer and the second sub light emitting layer, and including a plurality of auxiliary compounds, the first sub light emitting layer and the second sub light emitting layer each contain a first compound different from the auxiliary compounds, the light emitting auxiliary layer includes a first state in which an average separation distance between the auxiliary compounds is a first distance, and a second state in which an average separation distance between the auxiliary compounds is a second distance smaller than the first distance, and an external quantum efficiency when the light emitting auxiliary layer is in the second state is larger than an external quantum efficiency when the light emitting auxiliary layer is in the first state.

In one or more embodiments, the first compound may have a lowest energy level of a first excited singlet state and a lowest energy level of a first excited triplet state, and a difference between the lowest energy level of the first excited singlet and the lowest energy level of the first excited triplet state may be a first energy gap, the auxiliary compounds may each have a lowest energy level of a second excited singlet state and a lowest energy level of a second excited triplet state, and a difference between the lowest energy level of the second excited singlet state and the lowest energy level of the second excited triplet state may be a second energy gap, and the second energy gap may be smaller than the first energy gap.

In one or more embodiments, the first sub light emitting layer and the second sub light emitting layer may each emit (e.g., be configured to emit) light having a center wavelength of about 500 nm to about 560 nm.

In one or more embodiments, the light emitting auxiliary layer may be to emit (e.g., is configured to emit) light having a center wavelength of about 500 nanometer (nm) to about 560 nm.

In one or more embodiments, the light emitting auxiliary layer may have a thickness of greater than about 0 nm and less than or equal to about 3 nm.

In one or more embodiments, the light emitting auxiliary layer may be directly provided on the first sub light emitting layer, and the second sub light emitting layer may be directly provided on the light emitting auxiliary layer.

In one or more embodiments, the first sub light emitting layer and the second sub light emitting layer may each emit (e.g., be configured to emit) thermally activated delayed fluorescence.

In one or more embodiments, the auxiliary compounds may include a substituted or unsubstituted carbazole group or a substituted or unsubstituted triazine group.

In one or more embodiments, the auxiliary compounds may include at least one of 4,4-CzSPz, DMAC-TRZ, CP-BP-DMAC, CP-BP-PXZ, CP-BP-PTZ, or PTSOPO:

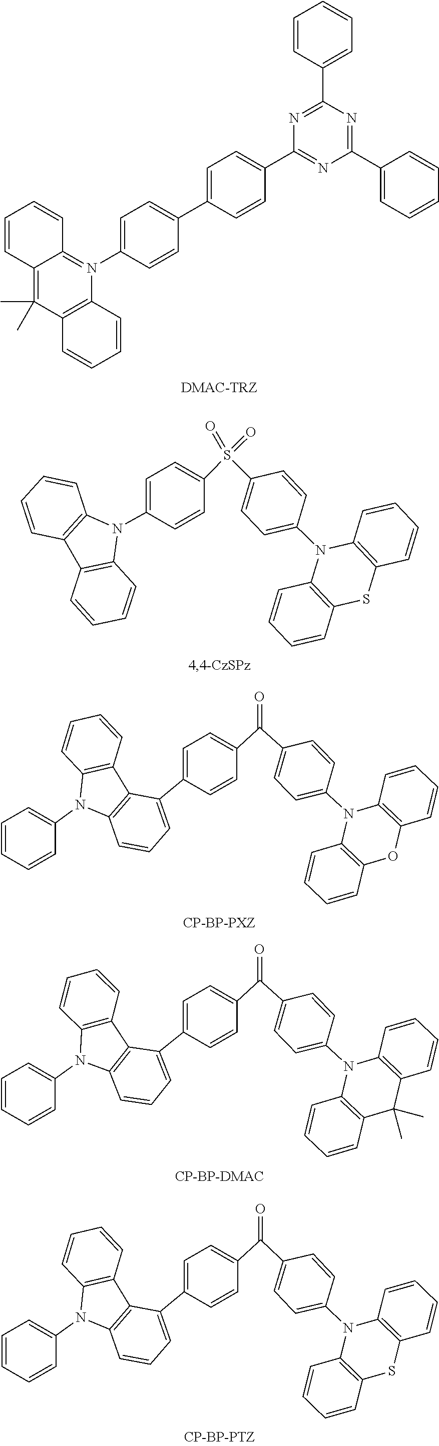

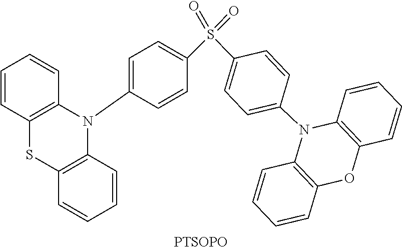

In one or more embodiments, the first compound may be represented by Formula F-c:

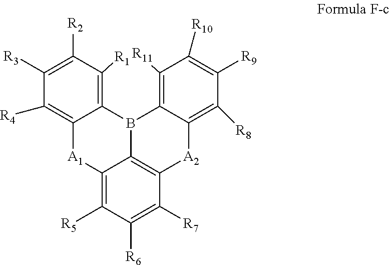

wherein, in Formula F-c, A₁ and A₂ may each independently be O, S, Se, or NRₘ, Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and R₁ to R₁₁ may each independently be, a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In one or more embodiments, each of the first sub light emitting layer and the second sub light emitting layer may further include a second compound and a third compound which are different from the first compound, the second compound may be represented by Formula HT-1, and the third compound may be represented by ET-1:

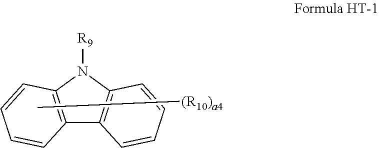

wherein, in Formula HT-1, a4 may be an integer of 0 to 8, and R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms,

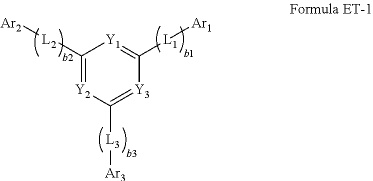

where, in Formula ET-1, at least one among Y₁ to Y₃ may be N, and the rest (i.e., each of the remaining Y₁ to Y₃ that are not N) may be CRₐ, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms, and Ar₁ to Ar₃ may each independently be a hydrogen atom, a deuterium atom, a substituted or unsubstituted alkyl group having 1 to 20 carbon atoms, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, each of the first sub light emitting layer and the second sub light emitting layer may further include a fourth compound represented by Formula D-1:

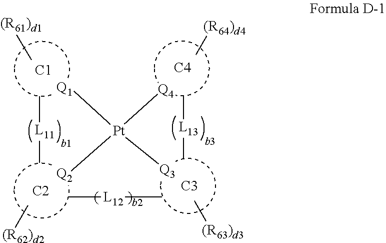

wherein, in Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted hetero ring having 2 to 30 ring-forming carbon atoms, L₁₁ to L₁₃ may each independently be a direct linkage,

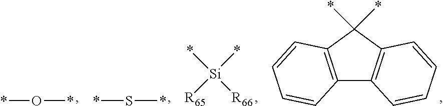

a substituted or unsubstituted divalent alkyl group having 1 to 20 carbon atoms, a substituted or unsubstituted arylene group having 6 to 30 carbon atoms, or a substituted or unsubstituted heteroarylene group having 2 to 30 ring-forming carbon atoms, b1 to b3 may each independently be 0 or 1, d1 to d4 may each independently be an integer of 0 to 4, and R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

In one or more embodiments of the present disclosure, a display device is divided into a first light emitting region emitting red light, a second light emitting region emitting green light, and a third light emitting region emitting blue light, and includes a base layer, and a display element layer provided on the base layer, and including first to third light emitting elements provided corresponding to the first to third light emitting regions, respectively, wherein the first to third light emitting elements each include a first electrode, a light emitting layer provided on the first electrode, and a second electrode provided on the light emitting layer, the light emitting layer of the second light emitting element includes a first sub light emitting layer provided adjacent to the first electrode, a second sub light emitting layer provided on the first sub light emitting layer, and a light emitting auxiliary layer provided between the first sub light emitting layer and the second sub light emitting layer, the first sub light emitting layer and the second sub light emitting layer each include a first compound which is a dopant, a second compound which is a hole transporting host, and a third compound which is an electron transporting host, the light emitting auxiliary layer includes auxiliary compounds different from the first compound, the light emitting auxiliary layer includes a first state in which an average separation distance between the auxiliary compounds is a first distance, and a second state in which an average separation distance between the auxiliary compounds is a second distance smaller than the first distance, and an external quantum efficiency when the light emitting auxiliary layer is in the second state is larger than an external quantum efficiency when the light emitting auxiliary layer is in the first state.

In one or more embodiments, the first compound may have a lowest energy level of a first excited singlet state and a lowest energy level of a first excited triplet state, and a difference between the lowest energy level of the first excited singlet state and the lowest energy level of the first excited triplet state may be a first energy gap, the auxiliary compounds may have a lowest energy level of a second excited singlet state and a lowest energy level of a second excited triplet state, and a difference between the lowest energy level of the second excited singlet state and the lowest energy level of the second excited triplet state may be a second energy gap, and the second energy gap may be smaller than the first energy gap.

In one or more embodiments, the light emitting auxiliary layer may have a thickness of greater than about 0 nm and less than or equal to 3 nm.

In one or more embodiments, the light emitting auxiliary layer may be directly provided on the first sub light emitting layer, and the second sub light emitting layer may be directly provided on the light emitting auxiliary layer.

In one or more embodiments, a light control layer provided on the display element layer and including a quantum dot.

In one or more embodiments of the present disclosure, a display device is divided into a first light emitting region emitting red light, a second light emitting region emitting green light, and a third light emitting region emitting blue light, includes a base layer; and a display element layer provided on the base layer, and including first to third light emitting elements provided corresponding to the first to third light emitting regions, respectively, wherein each of the first to third light emitting elements includes a first electrode, a light emitting layer provided on the first electrode, and a second electrode provided on the light emitting layer, the light emitting layer of the second light emitting element includes a first sub light emitting layer provided adjacent to the first electrode, a second sub light emitting layer provided on the first sub light emitting layer, and a light emitting auxiliary layer provided between the first sub light emitting layer and the second sub light emitting layer, the first sub light emitting layer and the second sub light emitting layer each include a first compound, the light emitting auxiliary layer includes auxiliary compounds different from the first compound, the light emitting auxiliary layer includes a first state in which an average separation distance between the auxiliary compounds is a first distance, and a second state in which an average separation distance between the auxiliary compounds is a second distance smaller than the first distance, and an external quantum efficiency when the light emitting auxiliary layer is in the second state is larger than an external quantum efficiency when the light emitting auxiliary layer is in the first state.

In one or more embodiments, the light emitting auxiliary layer may have a thickness of greater than about 0 nm and less than or equal to about 3 nm.

In one or more embodiments, the first compound may have a lowest energy level of a first excited singlet state and a lowest energy level of a first excited triplet state, and a difference between the lowest energy level of the first excited singlet state and the lowest energy level of the first excited triplet state may be a first energy gap, the auxiliary compounds may have a lowest energy level of a second excited singlet state and a lowest energy level of a second excited triplet state, and a difference between the lowest energy level of the second excited singlet state and the lowest energy level of the second excited triplet state may be a second energy gap, and the second energy gap may be smaller than the first energy gap.

In one or more embodiments, the light emitting auxiliary layer may be directly provided on the first sub light emitting layer, and the second sub light emitting layer may be directly provided on the light emitting auxiliary layer.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view illustrating a display device according to one or more embodiments of the present disclosure;

FIG. 2 is a cross-sectional view of a display device according to one or more embodiments of the present disclosure;

FIG. 3A is a cross-sectional view schematically illustrating a light emitting element according to one or more embodiments of the present disclosure;

FIG. 3B is an enlarged view of the light emitting auxiliary layer illustrated in FIG. 3A;

FIG. 3C is an enlarged view of the light emitting auxiliary layer illustrated in FIG. 3A;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a light emitting element schematically a light emitting element according to one or more embodiments of the present disclosure;

FIG. 7 is a cross-sectional view of a display device according to one or more embodiments of the present disclosure;

FIG. 8 is a cross-sectional view illustrating a display device according to one or more embodiments of the present disclosure;

FIG. 9 is a cross-sectional view illustrating a display device according to one or more embodiments of the present disclosure;

FIG. 10 is a cross-sectional view of a display device according to one or more embodiments of the present disclosure; and

FIG. 11 is a diagram illustrating an interior of a vehicle in which a display device according to one or more embodiments of the present disclosure is arranged or disposed.

### DETAILED DESCRIPTION

The present disclosure may be modified in one or more suitable manners and have many forms, and thus example embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements, and duplicate descriptions thereof may not be provided. In the accompanying drawings, the dimensions of each structure are exaggeratingly illustrated for clarity of the present disclosure. It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” and “the” are intended to include the plural forms as well, unless the context clearly indicates otherwise.

In the present application, it will be understood that the terms “include,” “includes,” “including,” “have,” “has,” “having,” “comprise,” “comprises,” “comprising,” and/or the like when utilized specify the presence of features, numbers, steps, operations, component, parts, or combinations thereof disclosed in the specification, but do not exclude the possibility of presence or addition of one or more other features, numbers, steps, operations, component, parts, or combinations thereof.

As used herein, the terms “use,” “using,” and “used” may be considered synonymous with the terms “utilize,” “utilizing,” and “utilized,” respectively.

As used herein, expressions such as “at least one of,” “one of,” and “selected from,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In the present application, when a layer, a film, a region, a plate and/or the like is referred to as being “on,” “connected to,” “coupled to,” or “in an upper portion of” another layer, film, region, or plate, it may be not only “directly, e.g., on” the layer, film, region, or plate, but intervening layers, films, regions, or plates may also be present. In contrast to this, when a layer, a film, a region, a plate, and/or the like is referred to as being “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Unless otherwise defined, all terms (including chemical, technical, and scientific terms) used herein have the same meaning as commonly understood by those of ordinary skill in the art to which the present disclosure pertains. It is also to be understood that terms defined in commonly used dictionaries should be interpreted as having meanings consistent with meanings in the context of the related art, unless expressly defined herein, and should not be interpreted in an ideal or overly formal sense.

In this context, “consisting essentially of” means that any additional components will not materially affect the chemical, physical, optical, or electrical properties of the semiconductor film.

Further, in this specification, the phrase “on a plane,” or “plan view,” means viewing a target portion from the top, and the phrase “on a cross-section” means viewing a cross-section formed by vertically cutting a target portion from the side.

### Definitions

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

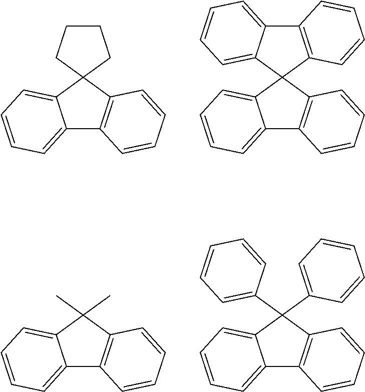

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of carbon atoms in an amino group is not specifically limited, but may be 1 to 30. The amino group may include an alkyl amino group and an aryl amino group. Examples of the amino group may include a methylamino group, a dimethylamino group, a phenylamino group, a diphenylamino group, a naphthylamino group, a 9-methyl-anthracenylamino group, a triphenylamine group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

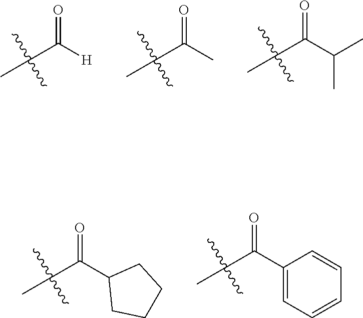

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and/or a naphthylthio group, but the embodiment of the present disclosure is not limited thereto.

In the specification, an oxy group may refer to that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, a direct linkage may refer to a single bond.

In some embodiments, in the specification, “ [symbol] ” and “—*” refer to a position to be connected.

Hereinafter, embodiments of the present disclosure will be described with reference to the accompanying drawings.

### Display Apparatus

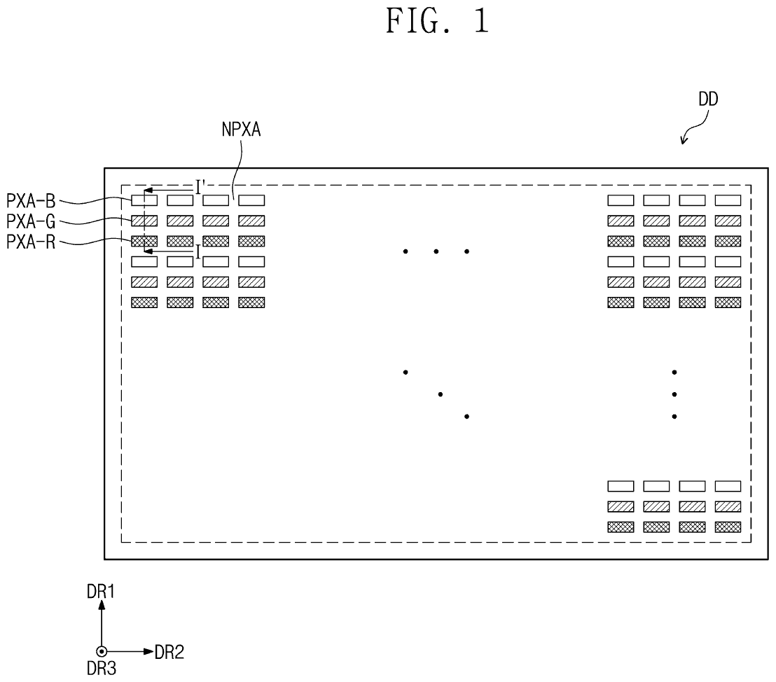

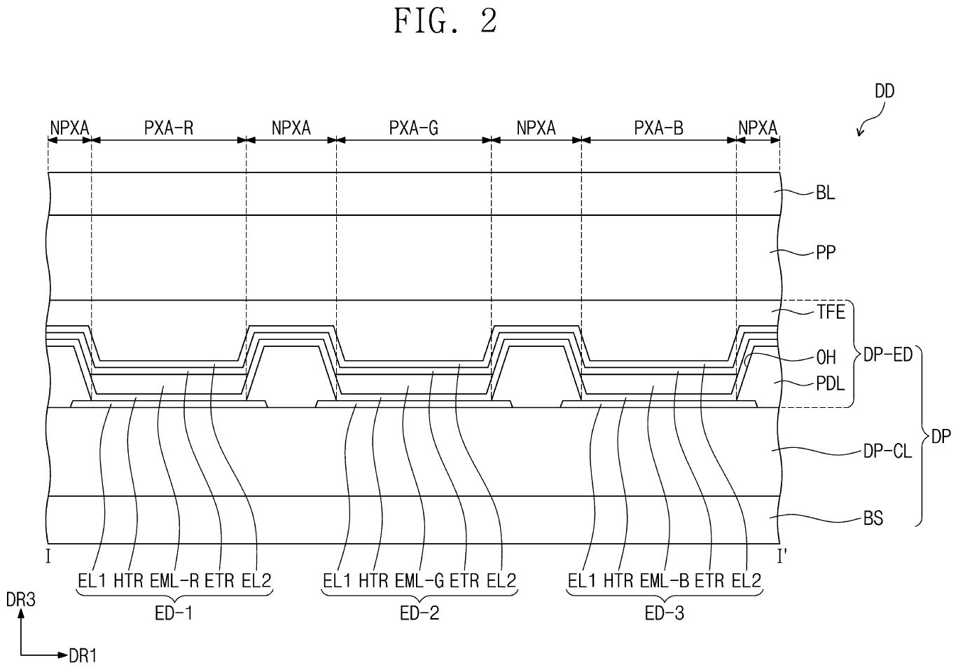

FIG. 1 is a plan view illustrating one or more embodiments of a display apparatus DD. FIG. 2 is a cross-sectional view of the display apparatus DD of one or more embodiments. FIG. 2 is a cross-sectional view illustrating a part taken along line I-I′ of FIG. 1.

The display apparatus DD may include a display panel DP and an optical layer PP provided on the display panel DP. The display panel DP includes light emitting elements ED-1, ED-2, and ED-3. The display apparatus DD may include a plurality of light emitting elements ED-1, ED-2, and ED-3. The optical layer PP may be provided on the display panel DP to control reflected light in the display panel DP due to external light. The optical layer PP may include, for example, a polarization layer or a color filter layer. In some embodiments, unlike the configuration illustrated in the drawing, the optical layer PP may not be provided from the display apparatus DD of one or more embodiments.

A base substrate BL may be provided on the optical layer PP. The base substrate BL may be a member which provides a base surface on which the optical layer PP is provided. The base substrate BL may be a glass substrate, a metal substrate, a plastic substrate, and/or the like. However, the embodiments of the present disclosure is not limited thereto, and the base substrate BL may be an inorganic layer, an organic layer, or a composite material layer. In some embodiments, unlike the configuration illustrated, in one or more embodiments, the base substrate BL may not be provided.

The display apparatus DD according to one or more embodiments may further include a filling layer. The filling layer may be provided between a display device layer DP-ED and the base substrate BL. The filling layer may be an organic material layer. The filling layer may include at least one selected from among an acrylic-based resin, a silicone-based resin, and/or an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 provided between portions of the pixel defining film PDL, and an encapsulation layer TFE provided on the light emitting elements ED-1, ED-2, and ED-3.

The base layer BS may be a member which provides a base surface on which the display device layer DP-ED is disposed. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display device layer DP-ED.

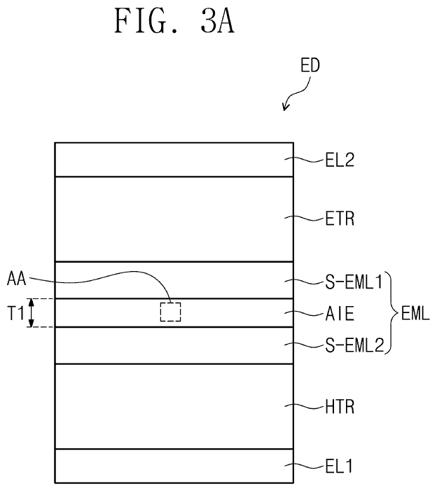

Each of the light emitting elements ED-1, ED-2, and ED-3 may have a structure of each light emitting element ED of embodiments according to FIGS. 3A, 4 to 6, which will be described later. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are provided in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display apparatus DD according to one or more embodiments, the plurality of light emitting elements ED-1, ED-2 and ED-3 may be to emit light (e.g., configured to emit) beams having wavelengths different from each other. For example, in one or more embodiments, the display apparatus DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display apparatus DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit (e.g., configured to emit) light beams in substantially the same wavelength range or at least one light emitting element may be to emit (e.g., configured to emit) a light beam in a wavelength range different from the others. For example, the first to third light emitting elements ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged with each other along the second directional axis DR2. In some embodiments, the (one) red light emitting region PXA-R, the (one) green light emitting region PXA-G, and the (one) blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be configured in a pentile (PENTILE®) arrangement form or a diamond (Diamond Pixel®) arrangement form, (PENTILE® and Diamond Pixel® each is a registered trademark owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

### Light Emitting Element

Hereinafter, FIGS. 3A and 4 to 6 are cross-sectional views schematically illustrating a light emitting element according to one or more embodiments. FIG. 3B is an enlarged view of a light emitting auxiliary layer illustrated in FIG. 3A. FIG. 3C is an enlarged view of the light emitting auxiliary layer illustrated in FIG. 3A. FIGS. 3B and 3C are each an enlarged view of a part corresponding to AA illustrated in FIG. 3A.

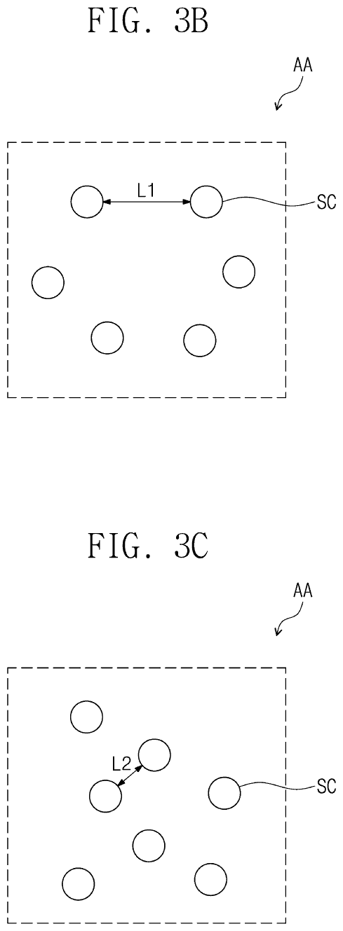

A light emitting element ED illustrated in FIG. 3A, according to one or more embodiments, may include a first electrode EL1, a hole transport region HTR, a light emitting layer EML, an electron transport region ETR, and a second electrode EL2, which are sequentially stacked. Compared with FIG. 3A, FIG. 4 illustrates a cross-sectional view of a light emitting element ED according to one or more embodiments in which the hole transport region HTR includes a hole injection layer HIL and a hole transport layer HTL, and the electron transport region ETR includes an electron injection layer EIL and an electron transport layer ETL.

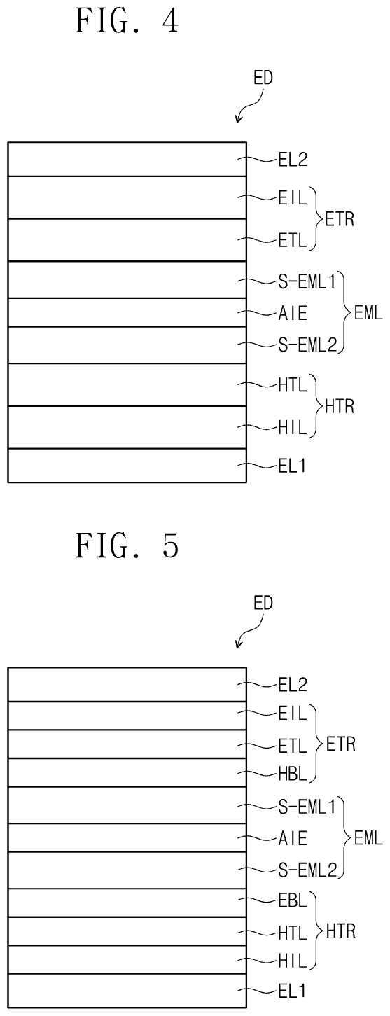

In some embodiments, compared with FIG. 3A, FIG. 5 illustrates a cross-sectional view of a light emitting element ED according to one or more embodiments in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL.

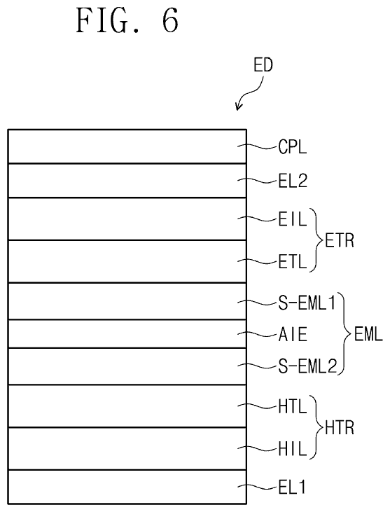

Compared with FIG. 3A, FIG. 6 illustrates a cross-sectional view of a light emitting element ED according to one or more embodiments including a capping layer CPL provided on a second electrode EL2.

In some embodiments, descriptions for light emitting elements ED illustrated in FIGS. 3A, and 4 to 6 may be identically or similarly applied to first to third light emitting elements ED-1, ED-2, and ED-3 illustrated in FIG. 2. In some embodiments, descriptions for a first sub light emitting layer S-EML1, a second sub light emitting layer S-EML2, and a light emitting layer EML may be applied to at least one among the first to third light emitting elements ED-1, ED-2, and ED-3 (see FIG. 2). For example, descriptions for the first sub light emitting layer S-EML1, the second sub light emitting layer S-EML2, and a light emitting auxiliary layer AIE may be applied to the second light emitting element ED-2 (see FIG. 2), and not applied to the others. However, this is for illustrative purposes only, and descriptions for a first sub light emitting layer S-EML1, a second sub light emitting layer S-EML2, and a light emitting auxiliary layer AIE may be applied to any of first to third light emitting elements ED-1, ED-2, and ED-3 (see FIG. 2).

When the descriptions for the first sub light emitting layer S-EML1, the second sub light emitting layer S-EML2, and the light emitting auxiliary layer AIE are applied only to the second light emitting element ED-2 (FIG. 2), the others, that is, the first light emitting element ED-1 (FIG. 2) and the third light emitting element ED-3 (FIG. 2) may each include a light emitting layer having a single layer. The light emitting layer having a single layer may include at least one compound among the first to fourth compounds, as described elsewhere herein.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the described materials, and a transparent conductive film formed of ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the described metal materials, combinations of at least two metal materials of the described metal materials, oxides of the described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

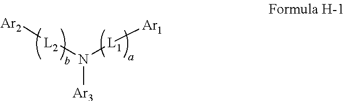

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound. In some embodiments, the compound represented by Formula H-2 above may be a diamine compound in which at least one among Ar₁ to Ar₃ includes the amine group as a substituent. In some embodiments, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds in Compound Group H. However, the compounds listed in Compound Group H are examples, and the compounds represented by Formula H-1 are not limited to those represented by Compound Group H:

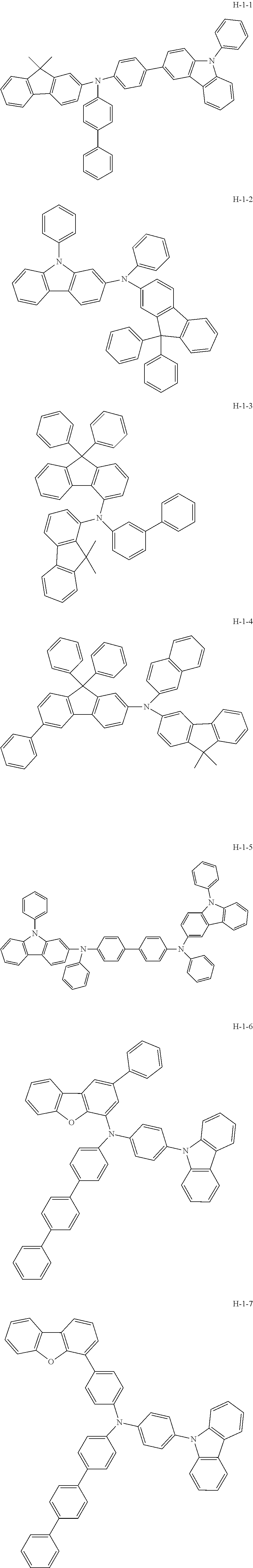

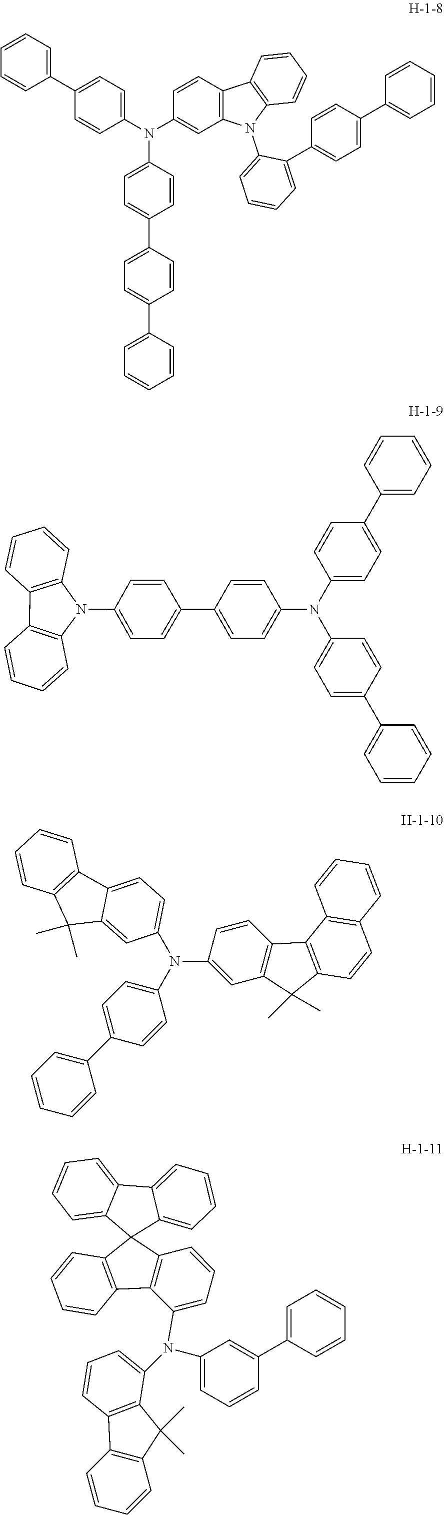

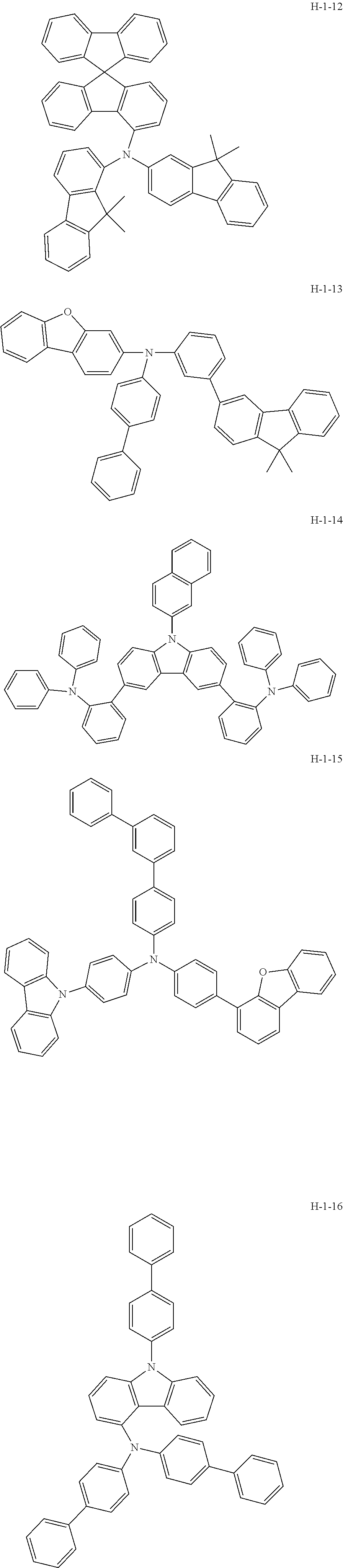

The hole transport region HTR may include a phthalocyanine compound such as copper phthalocyanine; N¹, N¹′-([1,1′-biphenyl]-4,4′-diyl) bis (N¹-phenyl-N⁴,N⁴-di-m-tolylbenzene-1,4-diamine) (DNTPD), 4,4′,4″-[tris (3-methylphenyl) phenylamino] triphenylamine (m-MTDATA), 4,4′,4″-tris (N,N-diphenylamino) triphenylamine (TDATA), 4,4′,4″-tris [N (2-naphthyl)-N-phenylamino]-triphenylamine (2-TNATA), poly (3,4-ethylenedioxythiophene)/poly (4-styrenesulfonate) (PEDOT/PSS), polyaniline/dodecylbenzenesulfonic acid (PANI/DBSA), polyaniline/camphor sulfonic acid (PANI/CSA), polyaniline/poly (4-styrenesulfonate) (PANI/PSS), N,N′-di (naphthalene-1-yl)-N,N′-diphenyl-benzidine (NPB), triphenylamine-containing polyetherketone (TPAPEK), 4-isopropyl-4′-methyldiphenyliodonium [tetrakis (pentafluorophenyl) borate], dipyrazino [2,3-f: 2′,3′-h] quinoxaline-2,3,6,7,10,11-hexacarbonitrile (HATCN), and/or the like.

The hole transport region HTR may include a carbazole-based derivative such as N-phenyl carbazole or polyvinyl carbazole, a fluorene-based derivative, a triphenylamine-based derivative such as N,N′-bis (3-methylphenyl)-N,N′-diphenyl-[1,1-biphenyl]-4,4′-diamine (TPD) or 4,4′,4″-tris (N-carbazolyl) triphenylamine (TCTA), N,N′-di (naphthalene-1-yl)-N,N′-diphenyl-benzidine (NPB), 4,4′-cyclohexylidene bis [N,N-bis (4-methylphenyl]benzenamine] (TAPC), 4,4′-bis [N,N′-(3-tolyl) amino]-3,3′-dimethylbiphenyl (HMTPD), 1,3-bis (N-carbazolyl) benzene (mCP), and/or the like.

In some embodiments, the hole transport region HTR may include 9-(4-tert-butylphenyl)-3,6-bis (triphenylsilyl)-9H-carbazole (CzSi), 9-phenyl-9H-3,9′-bicarbazole (CCP), 1,3-bis (1,8-dimethyl-9H-carbazol-9-yl) benzene (mDCP), and/or the like.

The hole transport region HTR may include the described compounds of the hole transport region in at least one selected from among a hole injection layer HIL, a hole transport layer HTL, and/or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the described ranges, satisfactory hole transport properties may be achieved without a substantial increase in driving voltage.

The hole transport region HTR may further include a charge generating material to increase conductivity in addition to the described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as Cul or Rbl, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino [2,3-f: 2′,3′-h] quinoxaline-2,3,6,7,10,11-hexacarbonitrile (HATCN) or 4-[[2,3-bis [cyano-(4-cyano-2,3,5,6-tetrafluorophenyl) methylidene] cyclopropylidene]-cyanomethyl]-2,3,5,6-tetrafluorobenzonitrile (NDP9), and/or the like, but the embodiment of the present disclosure is not limited thereto.

As described above, the hole transport region HTR may further include at least one of a buffer layer (not illustrated) or an electron blocking layer EBL in addition to a hole injection layer HIL and a hole transport layer HTL. The buffer layer (not illustrated) may compensate a resonance distance according to the wavelength of the light emitted from the light emitting layer EML and thus a light emission efficiency may be increased. As a material included in the buffer layer (illustrated), a material that may be included in the hole transport region HTR may be utilized. The electron blocking layer EBL may be a layer that serves to prevent or reduce an electron injection from the electron transport region ETR to the hole transport region HTR.

The light emitting layer EML is provided on the hole transport region HTR. The light emitting layer EML may have, for example, a thickness of about 100 Å to about 1000 Å, or about 100 Å to about 300 Å. The light emitting layer EML may have a single layer formed of a single material, a single layer formed of a plurality of different materials, or a multilayer structure having a plurality of layers formed of a plurality of different materials.

The light emitting layer EML according to one or more embodiments may include a first sub light emitting layer S-EML1, a second sub light emitting layer S-EML2, and a light emitting auxiliary layer AIE. The first sub light emitting layer S-EML1 may be provided on the hole transport region HTR. The second sub light emitting layer S-EML2 may be provided on the first sub light emitting layer S-EML1. The light emitting auxiliary layer AIE may be provided between the first sub light emitting layer S-EML1, and the second sub light emitting layer S-EML2.

The light emitting auxiliary layer AIE may be directly provided on the first sub light emitting layer S-EML1. The second sub light emitting layer S-EML2 may be directly provided on the light emitting auxiliary layer AIE. For example, in one or more embodiments, the light emitting layer EML may have a structure in which no other components are provided between the first sub light emitting layer S-EML1, the light emitting auxiliary layer AIE, and the second sub light emitting layer S-EML2.

Referring to FIGS. 3A and 3B, in one or more embodiments, the light emitting auxiliary layer AIE may include a plurality of auxiliary compounds SC. The auxiliary compounds SC may be emitters. In one or more embodiments, the light emitting auxiliary layer AIE may include the auxiliary compounds SC, at least one of which is an emitter, and may include non additional host material. For example, in one or more embodiments, the light emitting auxiliary layer AIE may include only an auxiliary compounds SC.

The light emitting auxiliary layer AIE of one or more embodiments may be supplied with excitons formed in the first sub light emitting layer S-EML1 and the second sub light emitting layer S-EML2. The auxiliary compounds SC of one or more embodiments may be to emit (e.g., configured to emit) light by receiving energy from excitons supplied from the first sub light emitting layer S-EML1 and the second sub light emitting layer S-EML2. The light emitting auxiliary layer AIE may be to emit (e.g., configured to emit) thermally activated delayed fluorescence.

The light emitting auxiliary layer AIE may be to emit (e.g., configured to emit) green light. For example, the light emitting auxiliary layer AIE may be to emit (e.g., configured to emit) light having a center wavelength of about 500 nm to about 560 nm. However, this is for illustrative purposes only, and one or more embodiments of the present disclosure is not limited thereto. The light emitting auxiliary layer AIE may be to emit (e.g., configured to emit) blue light or red light.

Generally, when the light emitting layer is doped with high-concentration (in case of including a high concentration of dopants), excessive excitons may be formed in the light emitting layer, and thus some excitons may be accumulated without being consumed. Some of the accumulated excitons may stay longer time in an excited triplet state having a lowest energy level (T1). The excitons which stay longer in the excited triplet state (T1) having the lowest energy level may be quenched by triplet-triplet annihilation (TTA).

The light emitting element ED according to one or more embodiments includes the light emitting auxiliary layer AIE including a plurality of auxiliary compounds SC between the first sub light emitting layer S-EML1 and the second sub light emitting layer S-EML2. The light emitting auxiliary layer AIE may receive some of the excitons formed by the first sub light emitting layer S-EML1 and the second sub light emitting layer S-EML2. Accordingly, in the light emitting element ED according to one or more embodiments, an amount of the excitons accumulated in the first sub light emitting layer S-EML1 and the second sub light emitting layer S-EML2 decreases, and thus quenching caused by the triplet-triplet annihilation may be reduced. As a result, a light emission efficiency and an element lifespan of the light emitting element ED may be improved.

The light emitting auxiliary layer AIE may have a thickness T1 of greater than 0 nm and less than or equal to 3 nm. When the thickness of the light emitting auxiliary layer AIE is greater than 3 nm, there is a disadvantage in that the transfer efficiency of excitons to the light emitting auxiliary layer from the first sub light emitting auxiliary layer S-EML1 and the second sub light emitting auxiliary layer S-EML2 is lowered. When the transfer efficiency of excitons to the light emitting auxiliary layer is lowered, the number of excitons accumulated in the first sub light emitting layer S-EML1 and the second sub light emitting layer S-EML2 increases, and thus the quenching caused by the triplet-triplet annihilation may increase. Accordingly, the light emission efficiency and the element lifespan of the light emitting element ED may be degraded. For example, the light emitting element ED according to one or more embodiments includes the light emitting auxiliary layer AIE of which the thickness T1 falls within a range of greater than about 0 nm and less than or equal to 3 nm, thereby exhibiting an excellent or suitable light emission efficiency and long-lifespan characteristics.

The auxiliary compounds SC included in the light emitting auxiliary layer AIE may have a first state, in which an average separation distance is a first distance L1, and a second state, in which an average separation distance is a second distance L2. The second distance L2 may be smaller than the first distance L1. As utilized herein, the first state is defined as a dispersion state, and the second state is defined as an aggregation state. The auxiliary compounds SC may exhibit a higher external quantum efficiency in the second state than in the first state. The auxiliary compounds SC may exhibit a higher external quantum efficiency in the second state than in the first state. For example, the auxiliary compounds SC may each exhibit aggregation induced emission (AIE) characteristics.

The compounds exhibiting the aggregation induced emission (AIE) characteristics have a chemical structure having rotational or vibrational degrees of freedom, and thus, in a low-concentration solution, molecules consume energy through rotational motion or vibrational motion rather than emitting energy as light. However, when the concentration of materials increases to cause the molecules to be aggregated or crystallized, molecular movement is restricted and thus a light emitting material has a high light emission efficiency. For example, when the auxiliary compounds SC of one or more embodiments are aggregated or crystalized, a high light emission efficiency may be exhibited.

When electricity is applied to the auxiliary compounds SC, the auxiliary compounds SC may be aggregated with each other. In one or more embodiments, when electricity is applied to the auxiliary compounds SC, the auxiliary compounds SC may change from the first state to the second state. For example, when electricity is supplied by applying a voltage equal to or greater than a driving voltage, the separation distance between the auxiliary compounds SC may be further reduced and thus the auxiliary compounds SC may change to an aggregated state. Accordingly, when a voltage equal to or greater than a driving voltage is applied to the light emitting element ED, light may be emitted from the light emitting auxiliary layer AIE. As the separation distance between the auxiliary compounds SC is smaller by supplying electricity to the auxiliary compounds, that is, as the auxiliary compounds SC change from the first state to the second state, the amount of light emitted from the light emitting auxiliary layer AIE including the auxiliary compounds SC may increase, result in an increase in external quantum efficiency.

The auxiliary compounds SC may each be a polycyclic compound including a substituted or unsubstituted carbazole group, or substituted or unsubstituted triazine group. For example, the auxiliary compound SC may include at least one of 4,4-CzSPz, DMAC-TRZ, CP-BP-PXZ, CP-BP-DMAC, CP-BP-PTZ, or PTSOPO. However, this is for illustrative purposes only, and one or more embodiments of the present disclosure is not limited thereto.

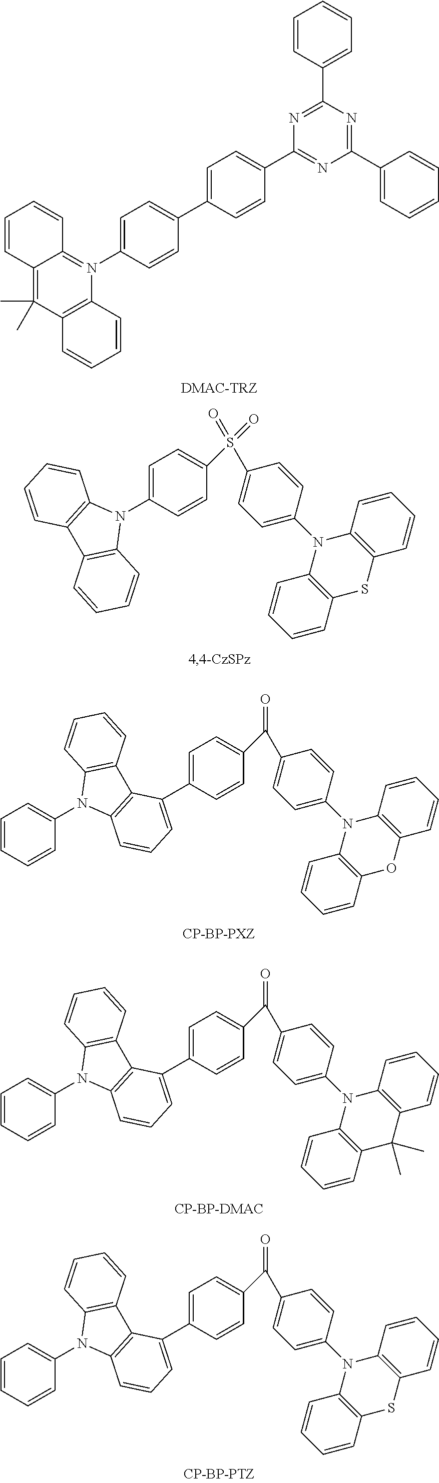

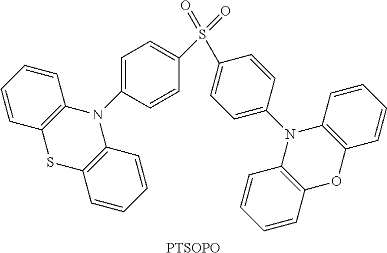

In some embodiments, the light emitting layer AIE may be an undoped layer. For example, the light emitting layer AIE may include an auxiliary compound SC as an emitter, and include no dopant compound (e.g., exclude any dopant compound) except for the auxiliary compound SC. The light emitting auxiliary layer AIE in an undoped state may have an external quantum efficiency (EQE) of about 15% to 25%. The light emitting auxiliary layer AIE according to one or more embodiments may include the auxiliary compounds exhibiting aggregation induced emission (AIE) characteristics, and may thus exhibit excellent or suitable external quantum efficiency even in an undoped state. The light emitting element ED according to one or more embodiments may include a light emitting auxiliary layer AIE exhibiting an excellent or suitable external quantum efficiency in an undoped state, thereby exhibiting excellent or suitable emission efficiency.

The first sub light emitting layer S-EML1 and the second sub light emitting layer S-EML2 may each include a first compound. The first compound may have a lowest energy level of a first excited singlet state and a lowest energy level of a first excited triplet state. A difference between the lowest energy level of the first excited singlet state and the lowest energy level of the first excited triplet state may have a first energy gap.

The auxiliary compound SC may have a lowest energy level of a second excited singlet state and a lowest energy level of a second excited triplet state. A difference between the lowest energy level of the second excited singlet state and the lowest energy level of the second excited triplet state may have a second energy gap. The second energy gap may be smaller than the first energy gap. As a result, energy may be smoothly transferred from each of the first sub light emitting layer S-EML1 and the second sub light emitting layer S-EML2 to the light emitting auxiliary layer AIE.

The first sub light emitting layer S-EML1 and the second sub light emitting layer S-EML2 may each emit thermally activated delayed fluorescence. The first sub light emitting layer S-EML1 and the second sub light emitting layer S-EML2 may each emit green light. The first sub light emitting layer S-EML1 and the second sub light emitting layer S-EML2 may each emit light having a center wavelength of about 500 nm to about 560 nm. However, this is for illustrative purposes only, and one or more embodiments of the present disclosure is not limited thereto. The first sub light emitting layer S-EML1 and the second sub light emitting layer S-EML2 may each emit blue light or red light.

In one or more embodiments, the first sub light emitting layer S-EML1 and the second sub light emitting layer S-EML2 may each include a first compound. The first compound may be a dopant compound. The first compound is a thermally activated delayed fluorescence dopant compound. The first compound may be represented by Formula F-c.

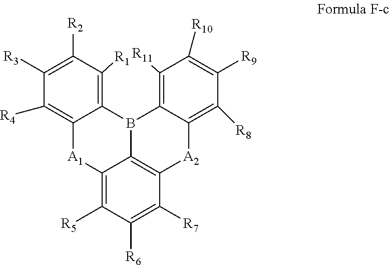

wherein, in Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be, a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A1 and A2 may each independently bonded to substituents of an adjacent ring to form a fused ring. For example, when A1 and A2 may each independently be NRₘ, A₁ may be bonded to R₄ or R₅ to form a ring. In some embodiments, A₂ may be bonded to R₇ or R₈ to form a ring.

The first compound may be represented by any one among compounds in Compound Group 1.

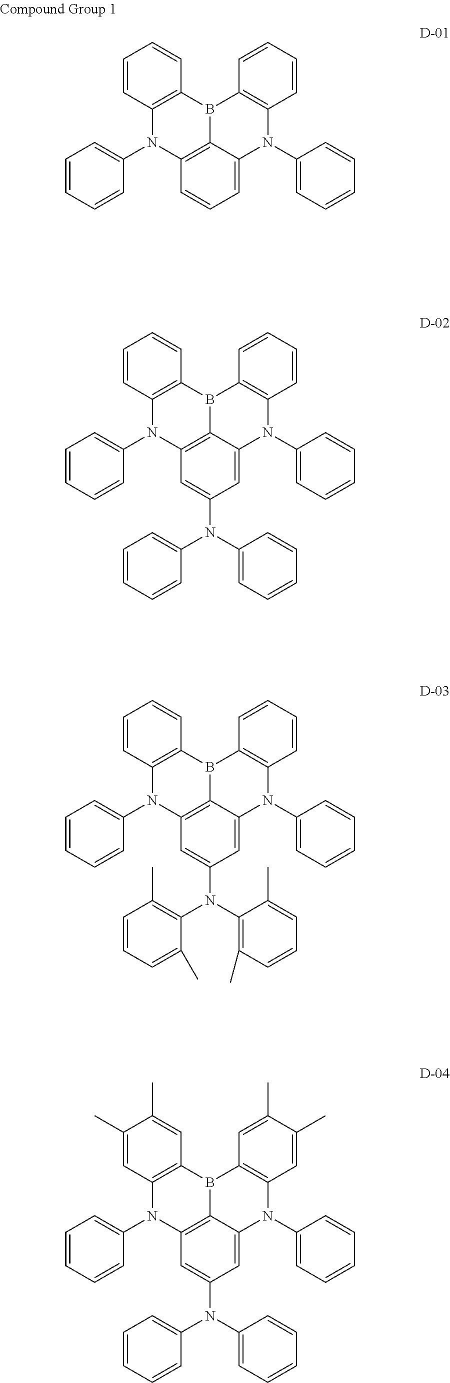 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; Cc1cccc(C)c1N(c1cc2c3c(c1)N(c1ccccc1)c1ccccc1B3c1ccccc1N2c1ccccc1)c1c(C)cccc1C ; Cc1cc2c(cc1C)N(c1ccccc1)c1cc(N(c3ccccc3)c3ccccc3)cc3c1B2c1cc(C)c(C)cc1N3c1ccccc1]

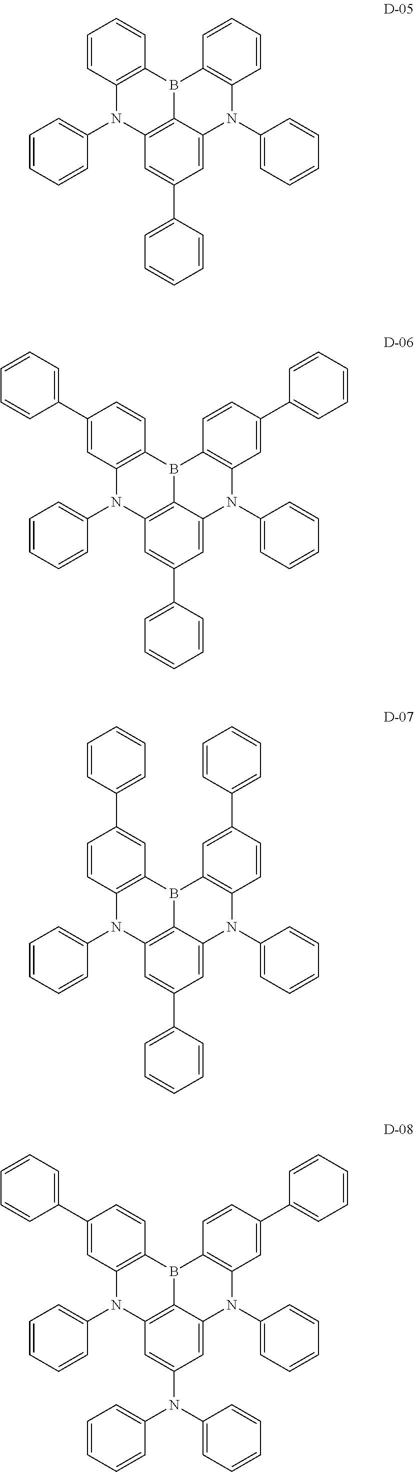 [SMILES: c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1]

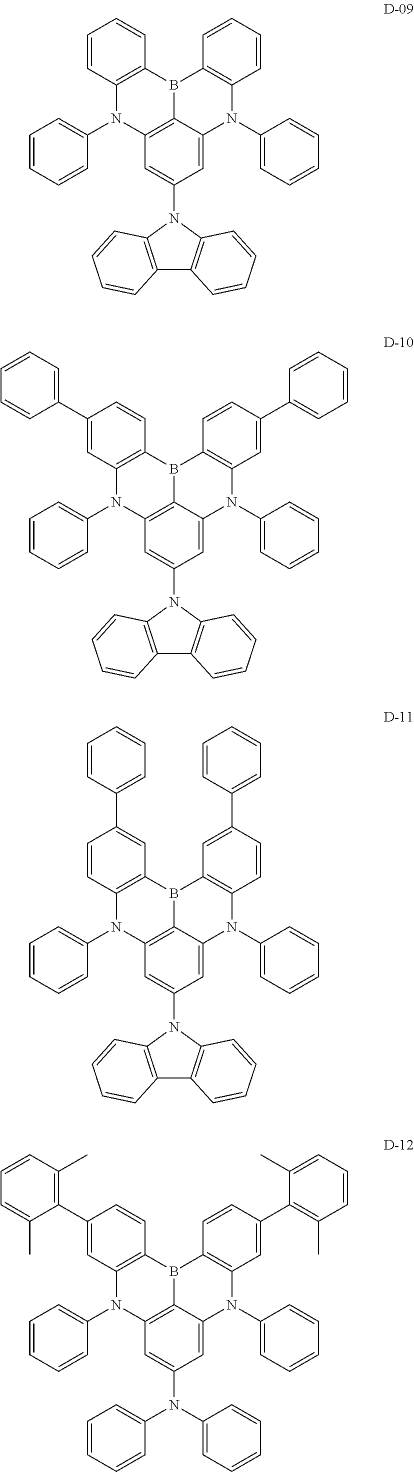 [SMILES: c1ccc(N2c3ccccc3B3c4ccccc4N(c4ccccc4)c4cc(-n5c6ccccc6c6ccccc65)cc2c43)cc1 ; c1ccc(-c2ccc3c(c2)N(c2ccccc2)c2cc(-n4c5ccccc5c5ccccc54)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; Cc1cccc(C)c1-c1ccc2c(c1)N(c1ccccc1)c1cc(N(c3ccccc3)c3ccccc3)cc3c1B2c1ccc(-c2c(C)cccc2C)cc1N3c1ccccc1]

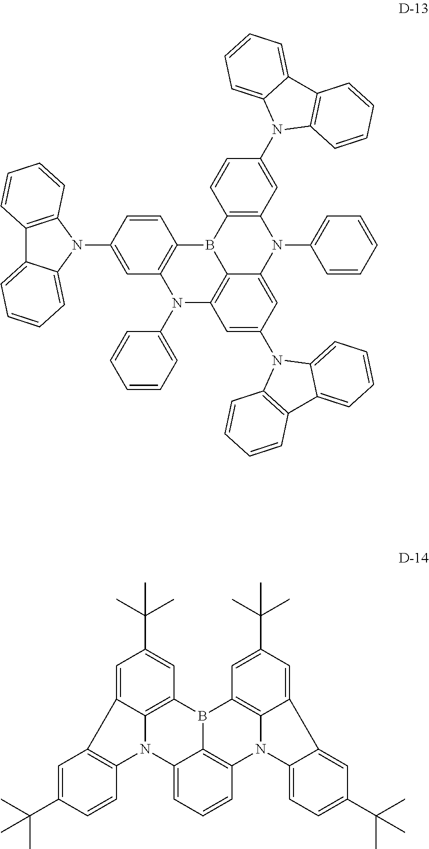 [SMILES: c1ccc(N2c3cc(-n4c5ccccc5c5ccccc54)ccc3B3c4ccc(-n5c6ccccc6c6ccccc65)cc4N(c4ccccc4)c4cc(-n5c6ccccc6c6ccccc65)cc2c43)cc1 ; CC(C)(C)c1ccc2c(c1)c1cc(C(C)(C)C)cc3c1n2-c1cccc2c1B3c1cc(C(C)(C)C)cc3c4cc(C(C)(C)C)ccc4n-2c13]

In some embodiments, the first sub light emitting layer S-EML1 and the second sub light emitting layer S-EML2 may each further include at least one of a second compound, a third compound or a fourth compound.

In one or more embodiments, the second compound may be utilized as a hole transporting host material in each of the first sub light emitting layer S-EML1 and the second sub light emitting layer S-EML2. The second compound may be represented by Formula HT-1.

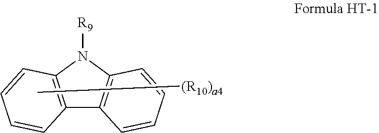

wherein, in Formula HT-1, a4 may be an integer of 0 to 8. When a4 is an integer 2 or more, a plurality of R₁₀ may be the same as each other or at least one thereof may be different from the others. R₉ and R₁₀ may each independently be a hydrogen atom, a deuterium atom, a substituted or unsubstituted aryl group having 6 to 60 ring-forming carbon atoms, or a substituted or unsubstituted heteroary group having 2 to 60 ring-forming carbon atoms. For example, R₉ may be a substituted phenyl group, an unsubstituted dibenzofuran group, or a substituted fluorenyl group. R₁₀ may be a substituted or unsubstituted carbazole group.

The second compound may be represented by at least one among compounds of Compound Group 2. In Compound Group 2, “D” is a deuterium atom.

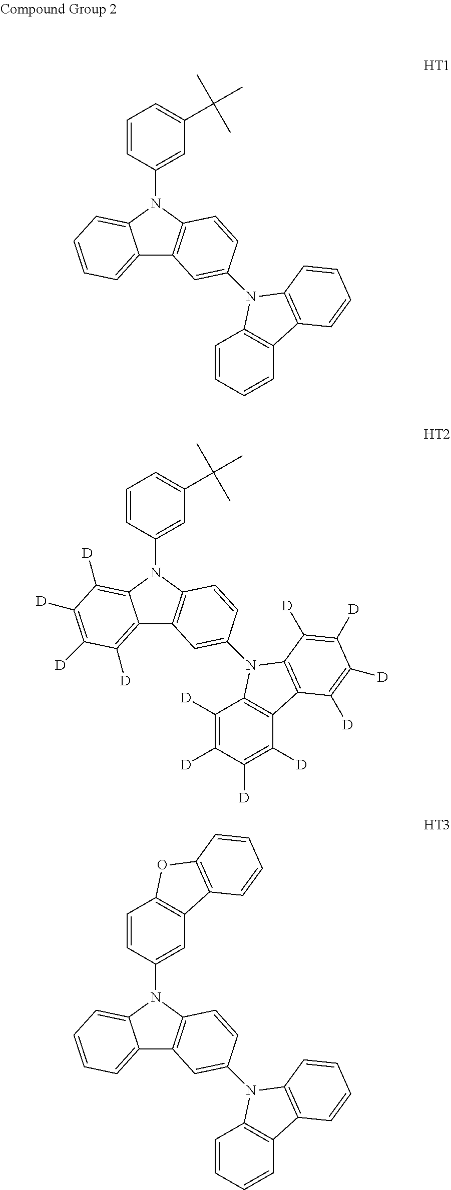

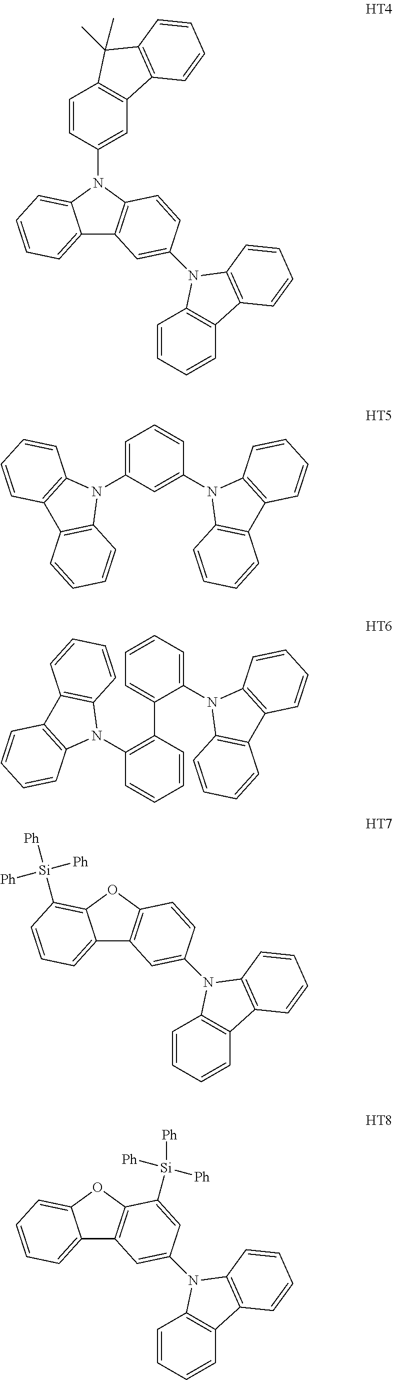 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

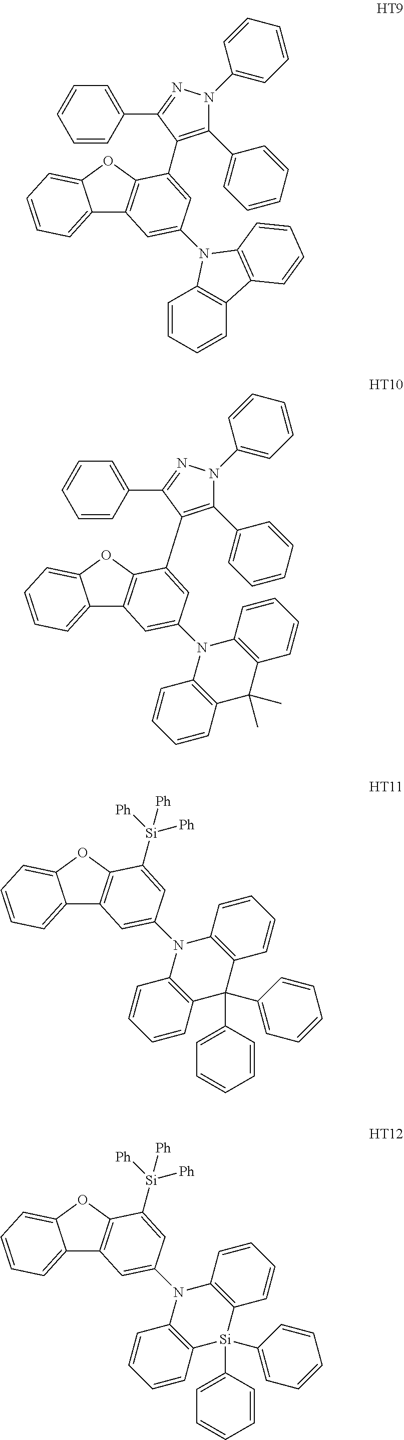 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

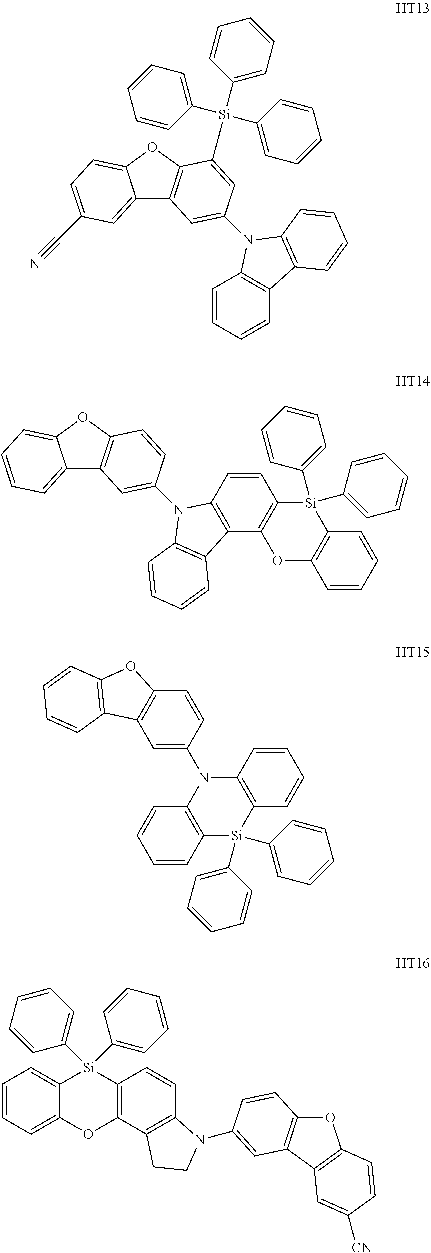 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(N4CCc5c4ccc4c5Oc5ccccc5[Si]4(c4ccccc4)c4ccccc4)cc3c2c1]

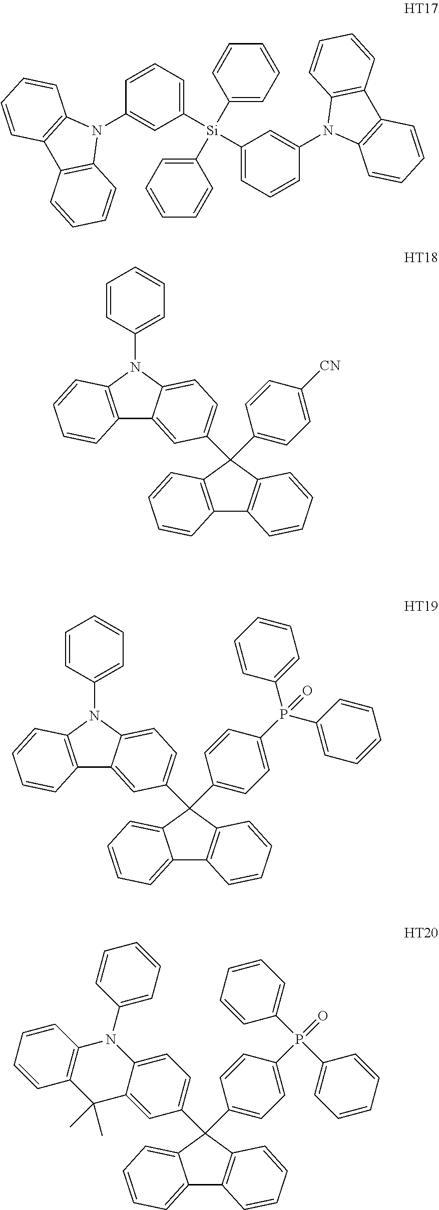 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

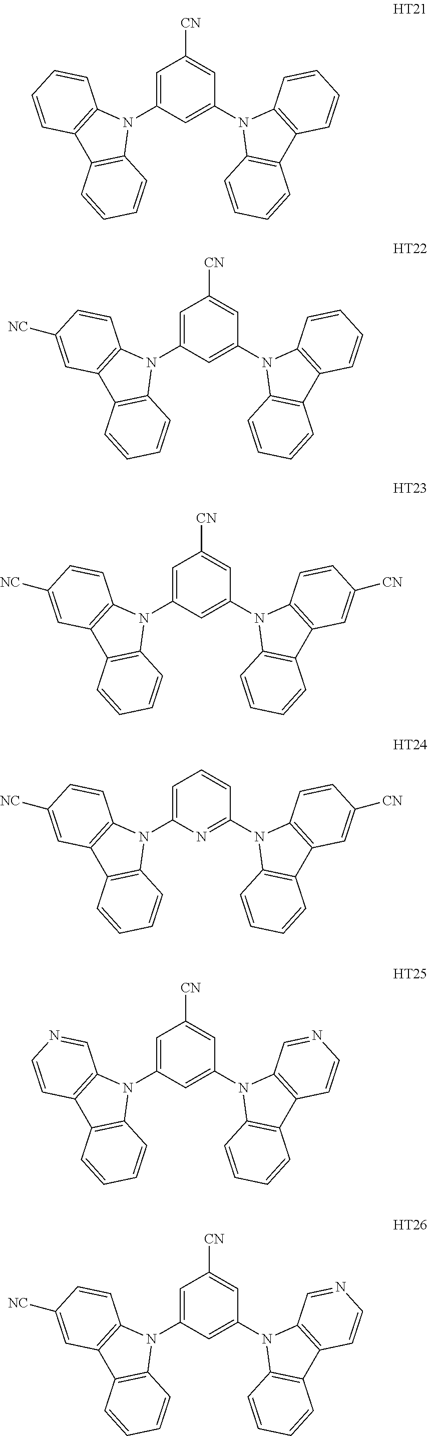 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

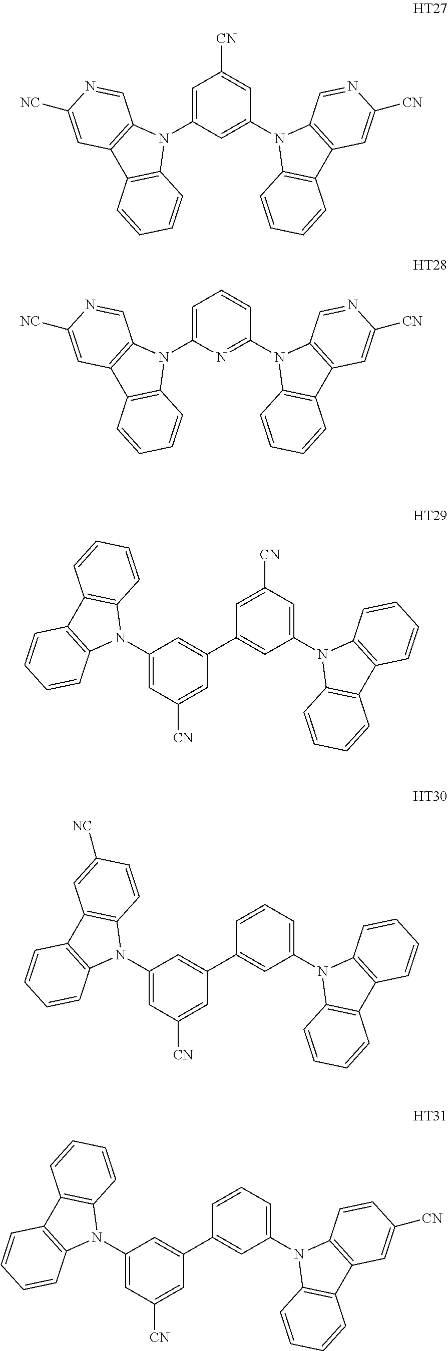 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

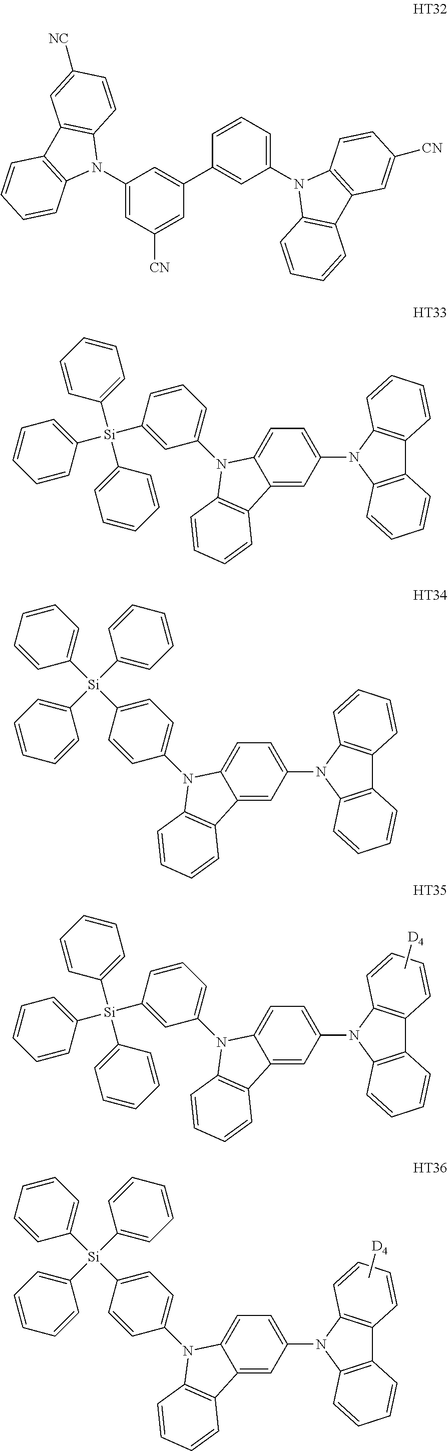

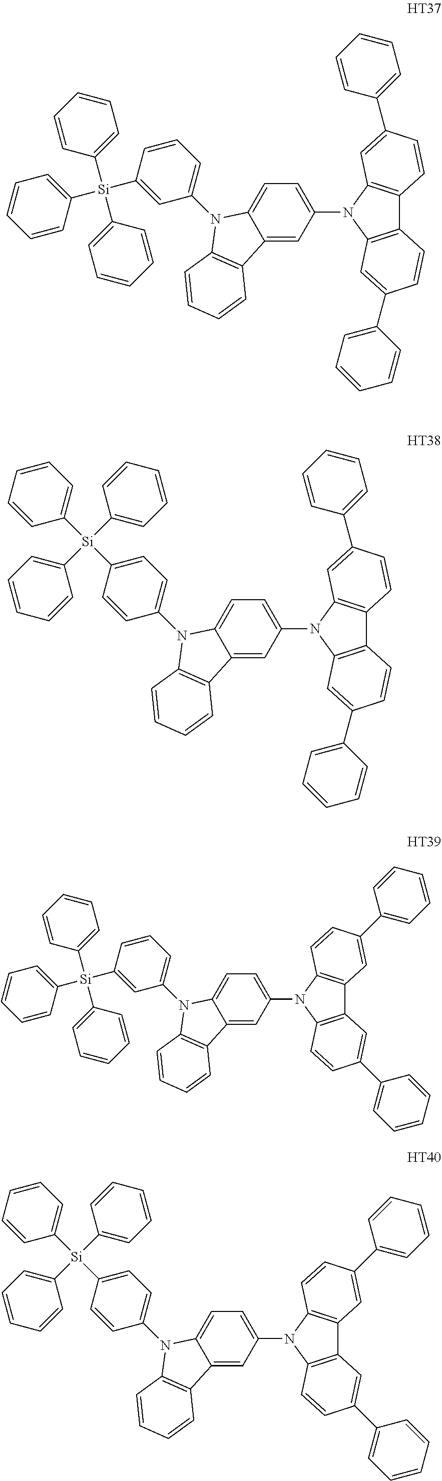 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

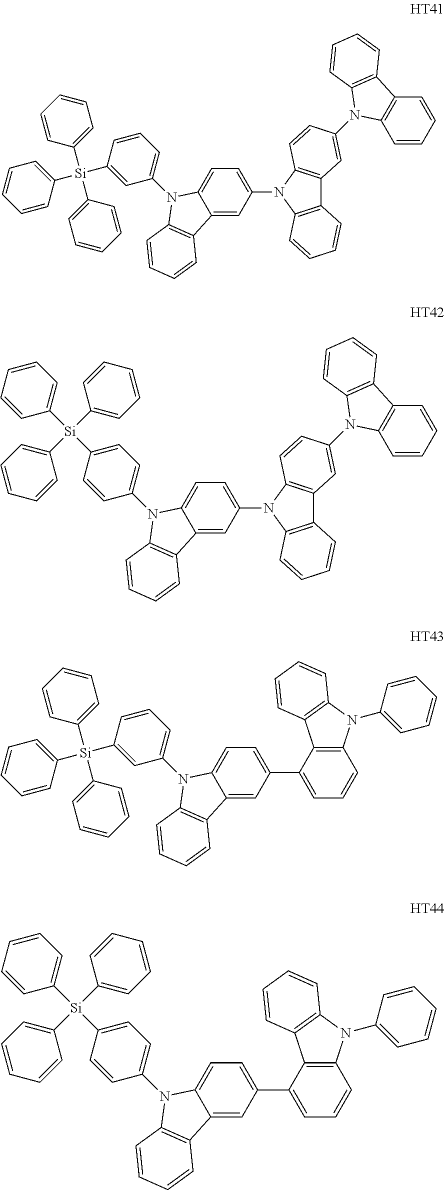 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

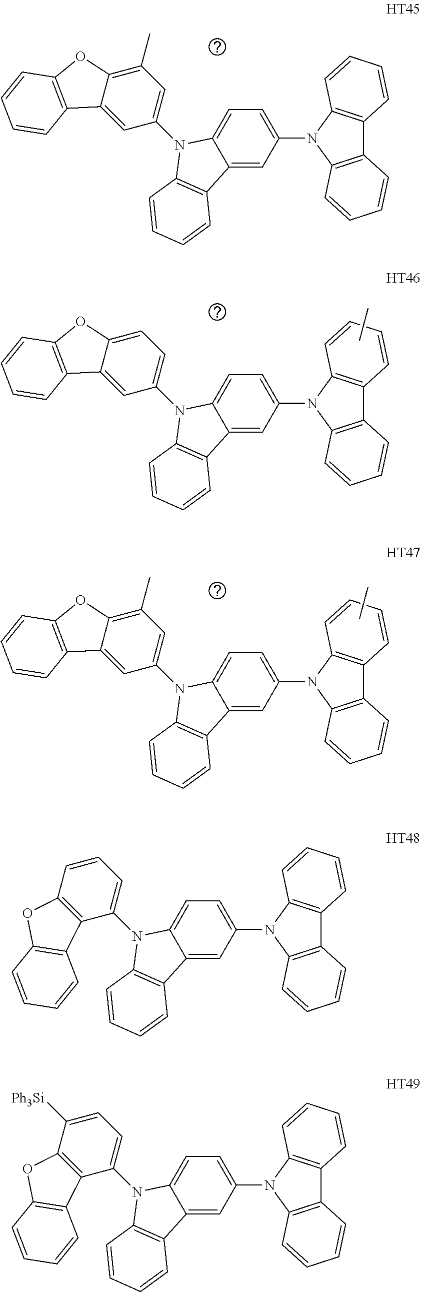

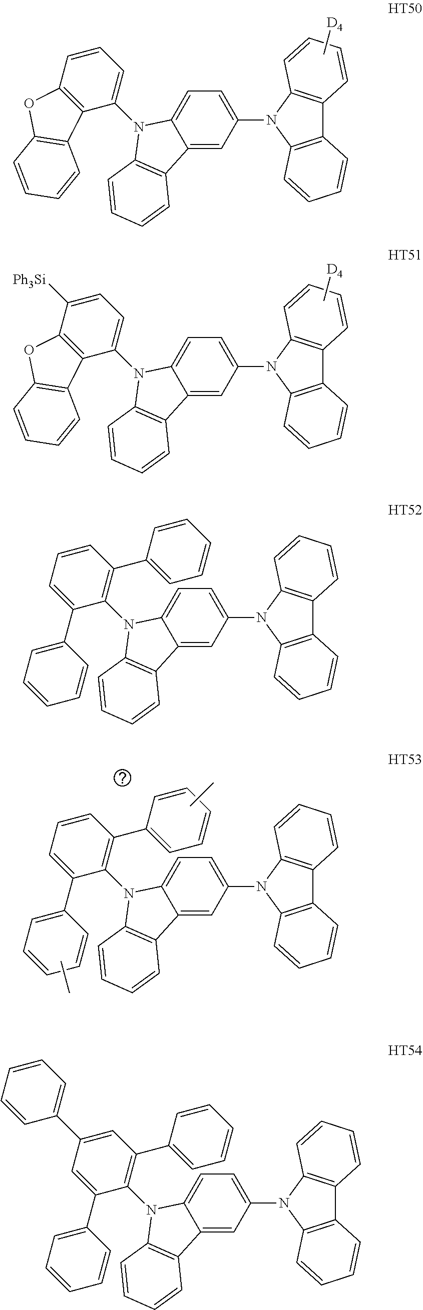

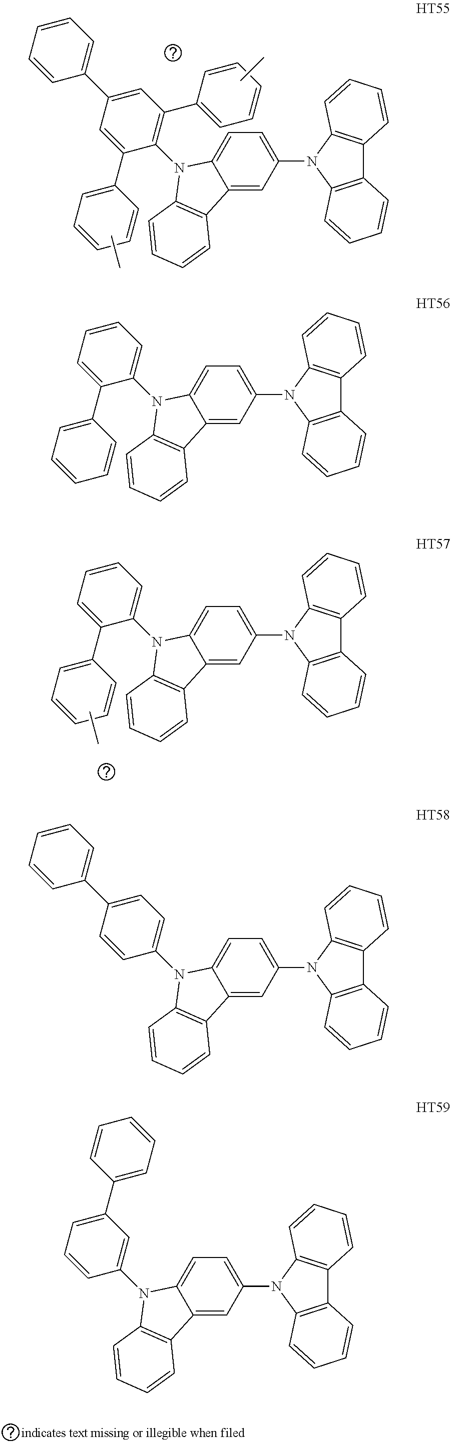

In one or more embodiments, the first sub light emitting layer S-EML1 and the second sub light emitting layer S-EML2 may each include a third compound represented by Formula ET-1. For example, the third compound may be utilized as an electron transporting host material in each of the first sub light emitting layer S-EML1 and the second sub light emitting layer S-EML2.

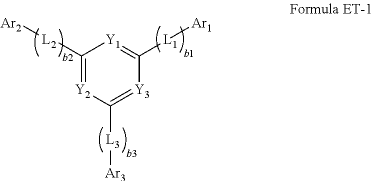

wherein, in Formula ET-1, at least one among Y₁ to Y₃ is N, the rest (i.e., each of the remaining Y₁ to Y₃ that are not N) are CRₐ, and Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

b1 to b3 may each independently be an integer of 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may be a substituted or unsubstituted phenyl group or a substituted or unsubstituted carbazole group.

The third compound may be represented by any one among compounds among Compound Group 3. A light emitting element ED according to one or more embodiments may include any one among compounds in Compound Group 3. In Compound Group 3, “D” is a deuterium atom.

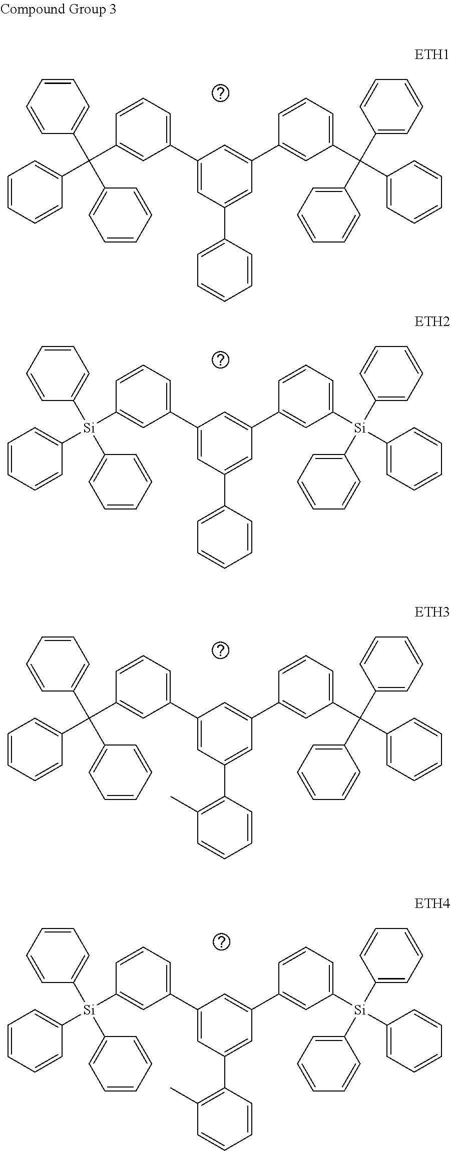

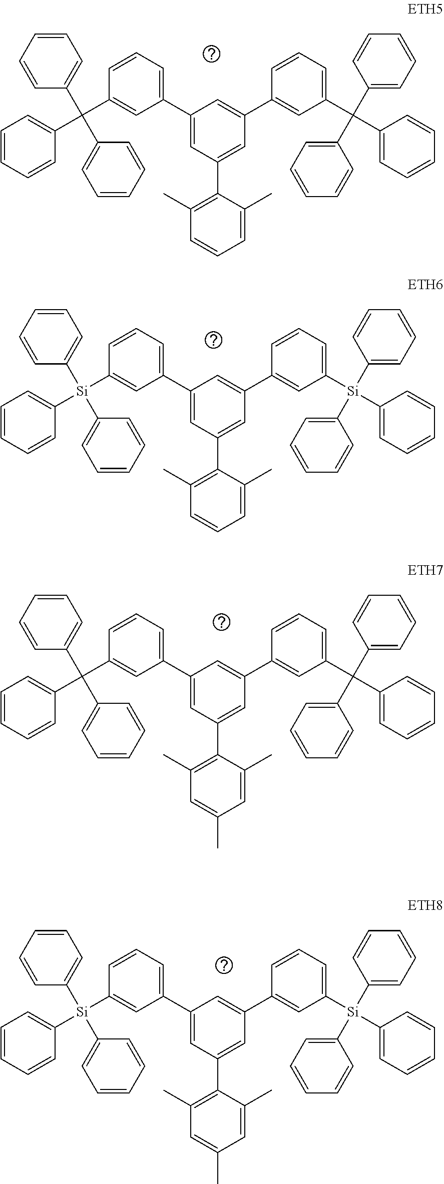

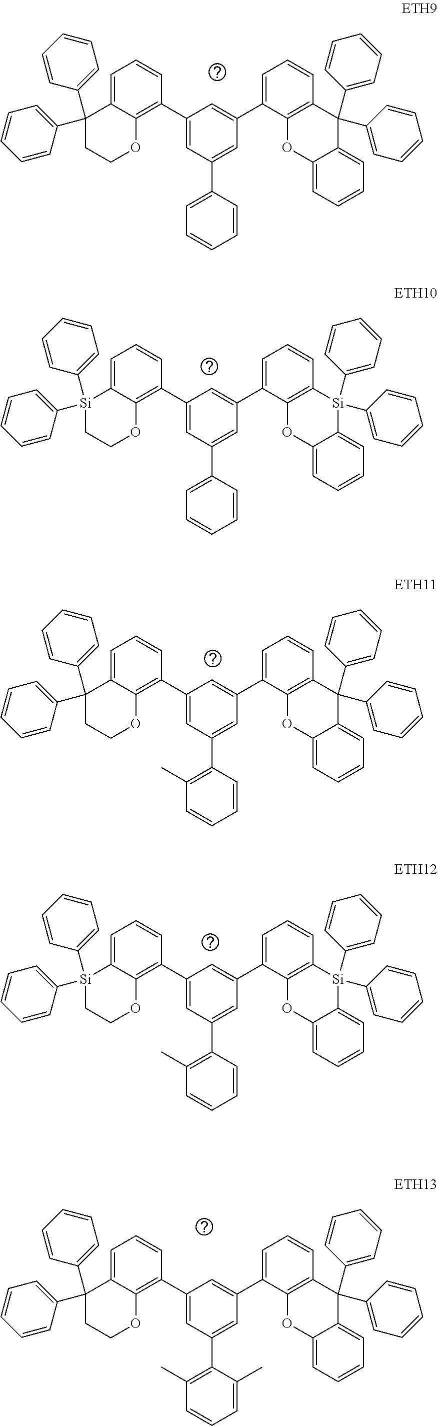 [SMILES: c1ccc(-c2cc(-c3cccc4c3OCCC4(c3ccccc3)c3ccccc3)cc(-c3cccc4c3Oc3ccccc3C4(c3ccccc3)c3ccccc3)c2)cc1 ; c1ccc(-c2cc(-c3cccc4c3OCC[Si]4(c3ccccc3)c3ccccc3)cc(-c3cccc4c3Oc3ccccc3[Si]4(c3ccccc3)c3ccccc3)c2)cc1 ; Cc1ccccc1-c1cc(-c2cccc3c2OCCC3(c2ccccc2)c2ccccc2)cc(-c2cccc3c2Oc2ccccc2C3(c2ccccc2)c2ccccc2)c1 ; Cc1ccccc1-c1cc(-c2cccc3c2OCC[Si]3(c2ccccc2)c2ccccc2)cc(-c2cccc3c2Oc2ccccc2[Si]3(c2ccccc2)c2ccccc2)c1 ; Cc1cccc(C)c1-c1cc(-c2cccc3c2OCCC3(c2ccccc2)c2ccccc2)cc(-c2cccc3c2Oc2ccccc2C3(c2ccccc2)c2ccccc2)c1]

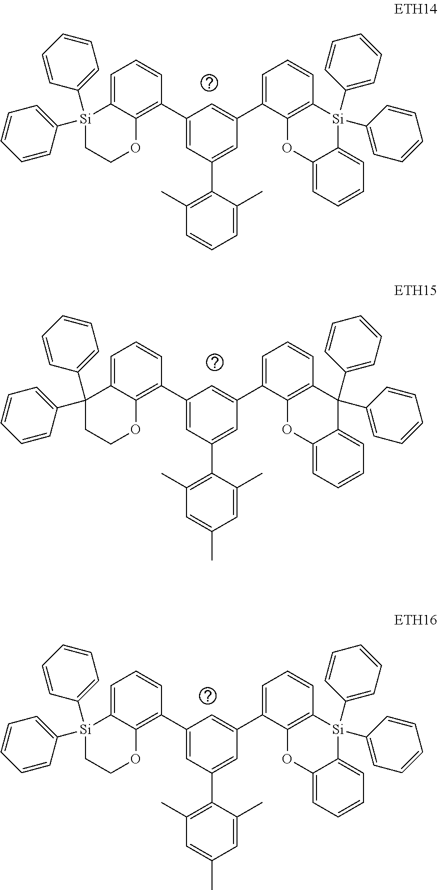 [SMILES: Cc1cccc(C)c1-c1cc(-c2cccc3c2OCC[Si]3(c2ccccc2)c2ccccc2)cc(-c2cccc3c2Oc2ccccc2[Si]3(c2ccccc2)c2ccccc2)c1 ; Cc1cc(C)c(-c2cc(-c3cccc4c3OCCC4(c3ccccc3)c3ccccc3)cc(-c3cccc4c3Oc3ccccc3C4(c3ccccc3)c3ccccc3)c2)c(C)c1 ; Cc1cc(C)c(-c2cc(-c3cccc4c3OCC[Si]4(c3ccccc3)c3ccccc3)cc(-c3cccc4c3Oc3ccccc3[Si]4(c3ccccc3)c3ccccc3)c2)c(C)c1]

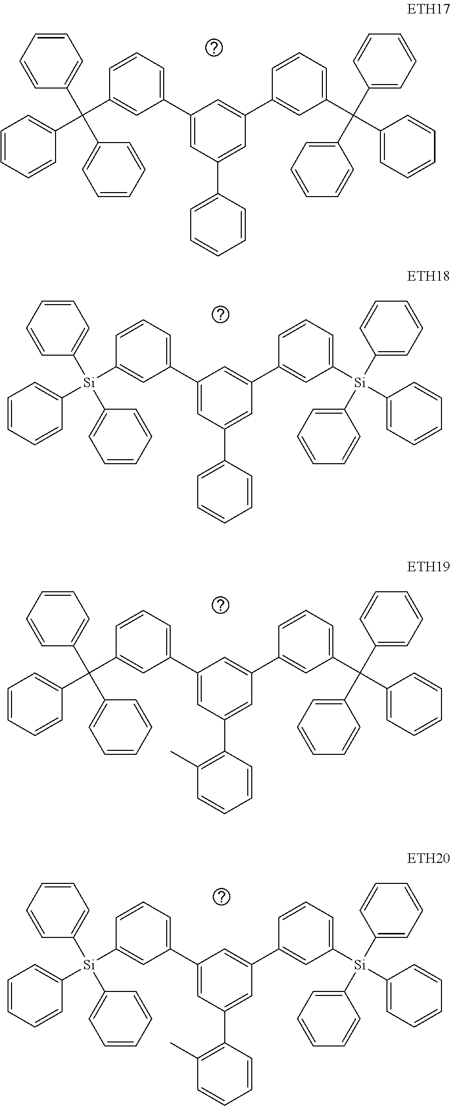

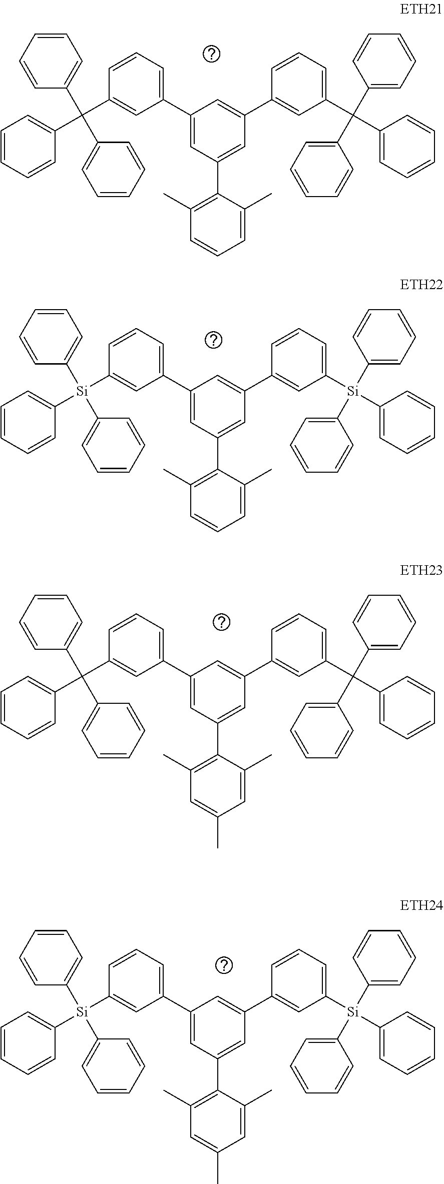

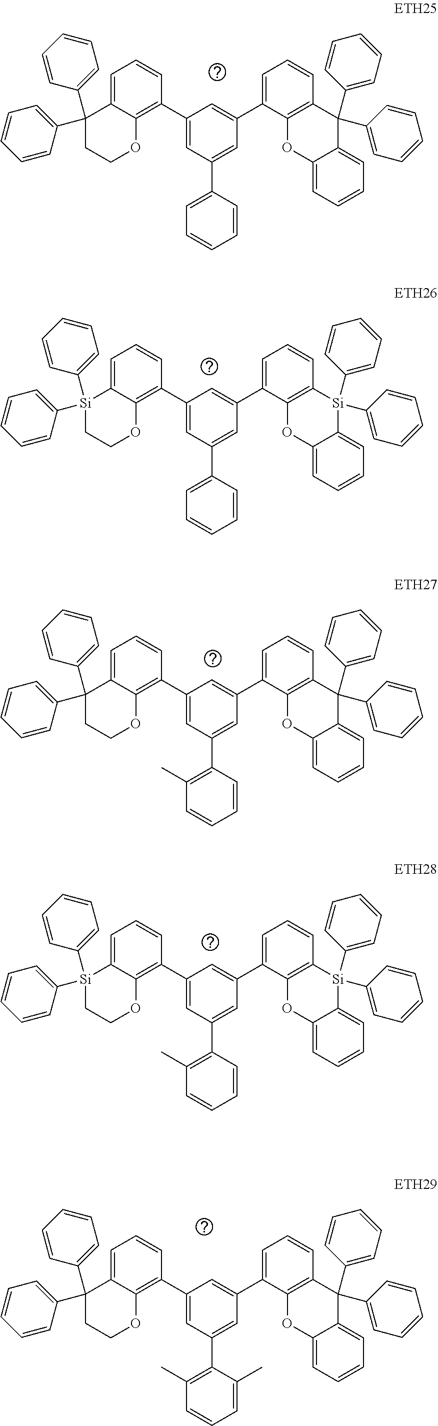 [SMILES: c1ccc(-c2cc(-c3cccc4c3OCCC4(c3ccccc3)c3ccccc3)cc(-c3cccc4c3Oc3ccccc3C4(c3ccccc3)c3ccccc3)c2)cc1 ; c1ccc(-c2cc(-c3cccc4c3OCC[Si]4(c3ccccc3)c3ccccc3)cc(-c3cccc4c3Oc3ccccc3[Si]4(c3ccccc3)c3ccccc3)c2)cc1 ; Cc1ccccc1-c1cc(-c2cccc3c2OCCC3(c2ccccc2)c2ccccc2)cc(-c2cccc3c2Oc2ccccc2C3(c2ccccc2)c2ccccc2)c1 ; Cc1ccccc1-c1cc(-c2cccc3c2OCC[Si]3(c2ccccc2)c2ccccc2)cc(-c2cccc3c2Oc2ccccc2[Si]3(c2ccccc2)c2ccccc2)c1 ; Cc1cccc(C)c1-c1cc(-c2cccc3c2OCCC3(c2ccccc2)c2ccccc2)cc(-c2cccc3c2Oc2ccccc2C3(c2ccccc2)c2ccccc2)c1]

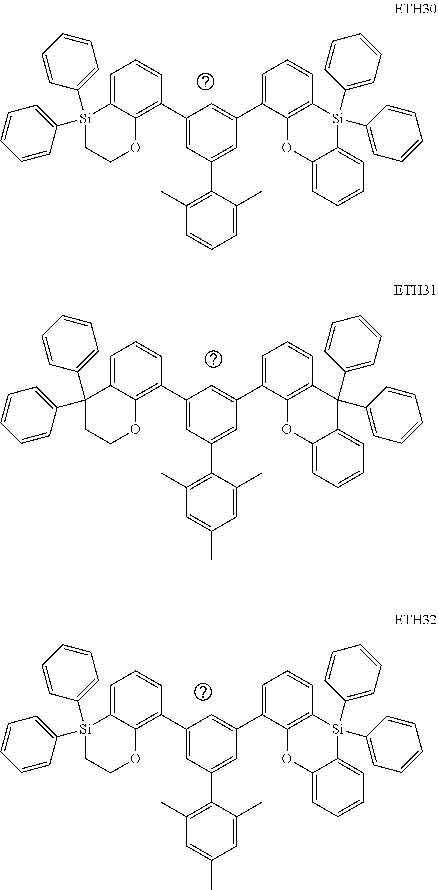 [SMILES: Cc1cccc(C)c1-c1cc(-c2cccc3c2OCC[Si]3(c2ccccc2)c2ccccc2)cc(-c2cccc3c2Oc2ccccc2[Si]3(c2ccccc2)c2ccccc2)c1 ; Cc1cc(C)c(-c2cc(-c3cccc4c3OCCC4(c3ccccc3)c3ccccc3)cc(-c3cccc4c3Oc3ccccc3C4(c3ccccc3)c3ccccc3)c2)c(C)c1 ; Cc1cc(C)c(-c2cc(-c3cccc4c3OCC[Si]4(c3ccccc3)c3ccccc3)cc(-c3cccc4c3Oc3ccccc3[Si]4(c3ccccc3)c3ccccc3)c2)c(C)c1]

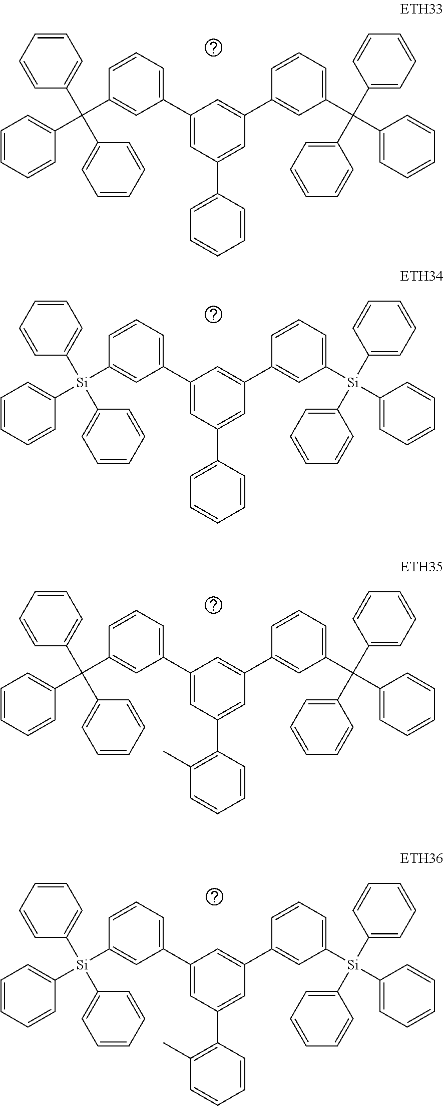

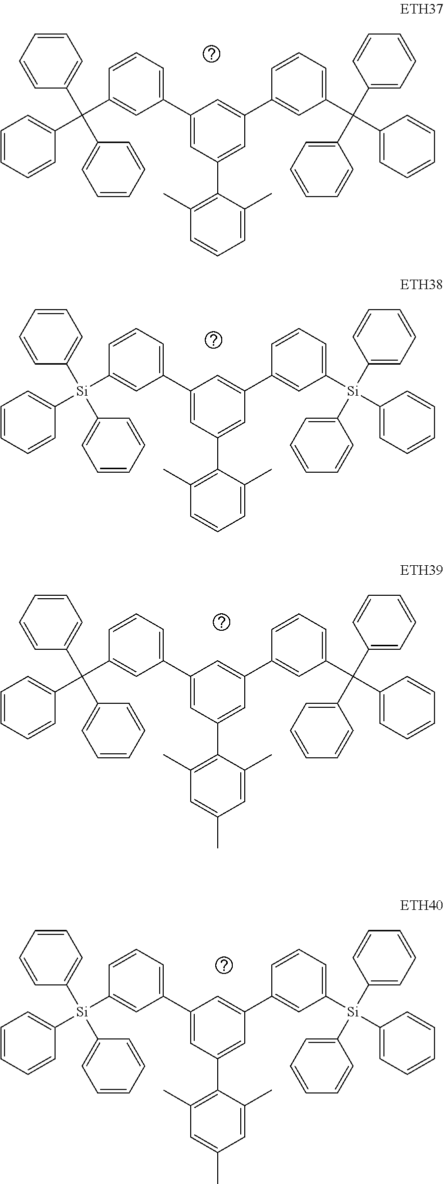

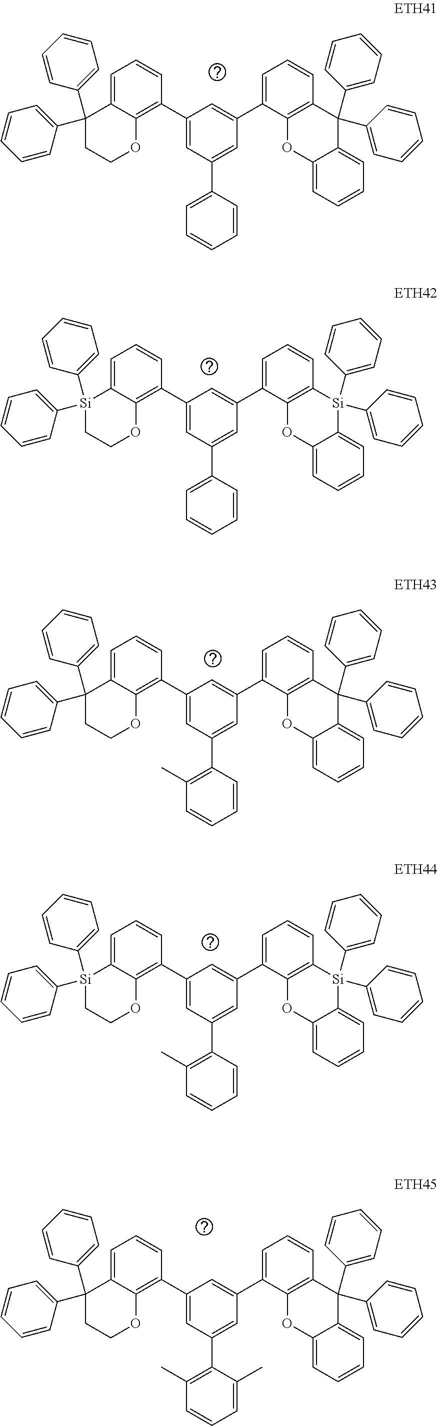 [SMILES: c1ccc(-c2cc(-c3cccc4c3OCCC4(c3ccccc3)c3ccccc3)cc(-c3cccc4c3Oc3ccccc3C4(c3ccccc3)c3ccccc3)c2)cc1 ; c1ccc(-c2cc(-c3cccc4c3OCC[Si]4(c3ccccc3)c3ccccc3)cc(-c3cccc4c3Oc3ccccc3[Si]4(c3ccccc3)c3ccccc3)c2)cc1 ; Cc1ccccc1-c1cc(-c2cccc3c2OCCC3(c2ccccc2)c2ccccc2)cc(-c2cccc3c2Oc2ccccc2C3(c2ccccc2)c2ccccc2)c1 ; Cc1ccccc1-c1cc(-c2cccc3c2OCC[Si]3(c2ccccc2)c2ccccc2)cc(-c2cccc3c2Oc2ccccc2[Si]3(c2ccccc2)c2ccccc2)c1 ; Cc1cccc(C)c1-c1cc(-c2cccc3c2OCCC3(c2ccccc2)c2ccccc2)cc(-c2cccc3c2Oc2ccccc2C3(c2ccccc2)c2ccccc2)c1]

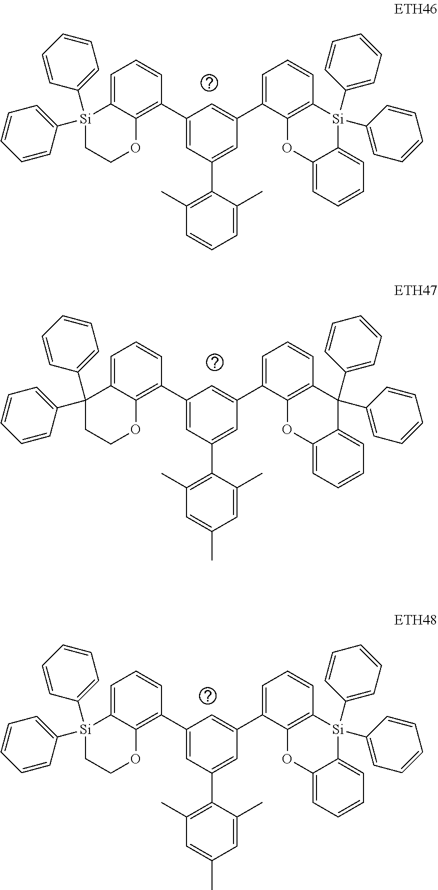 [SMILES: Cc1cccc(C)c1-c1cc(-c2cccc3c2OCC[Si]3(c2ccccc2)c2ccccc2)cc(-c2cccc3c2Oc2ccccc2[Si]3(c2ccccc2)c2ccccc2)c1 ; Cc1cc(C)c(-c2cc(-c3cccc4c3OCCC4(c3ccccc3)c3ccccc3)cc(-c3cccc4c3Oc3ccccc3C4(c3ccccc3)c3ccccc3)c2)c(C)c1 ; Cc1cc(C)c(-c2cc(-c3cccc4c3OCC[Si]4(c3ccccc3)c3ccccc3)cc(-c3cccc4c3Oc3ccccc3[Si]4(c3ccccc3)c3ccccc3)c2)c(C)c1]

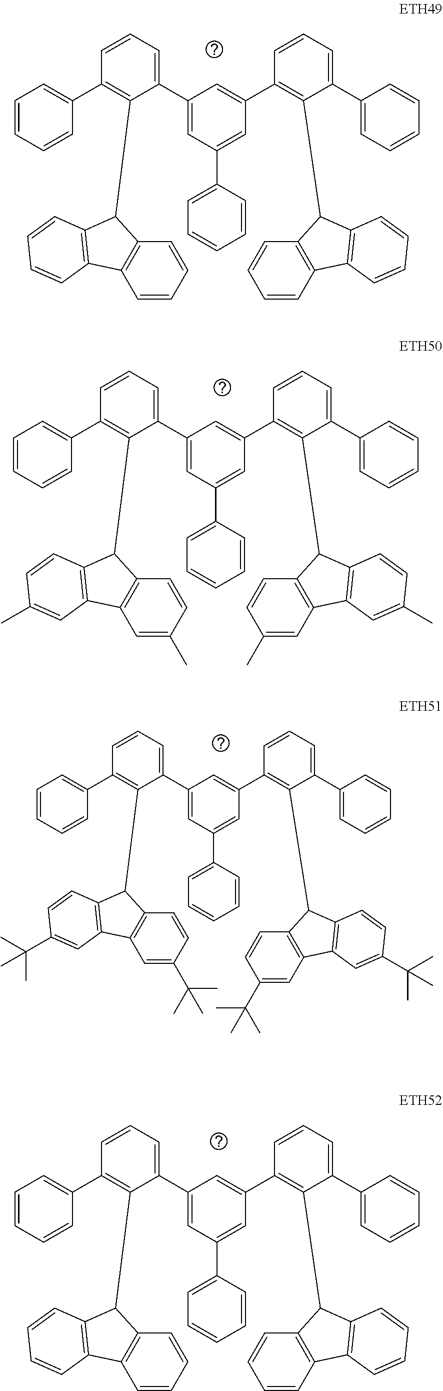

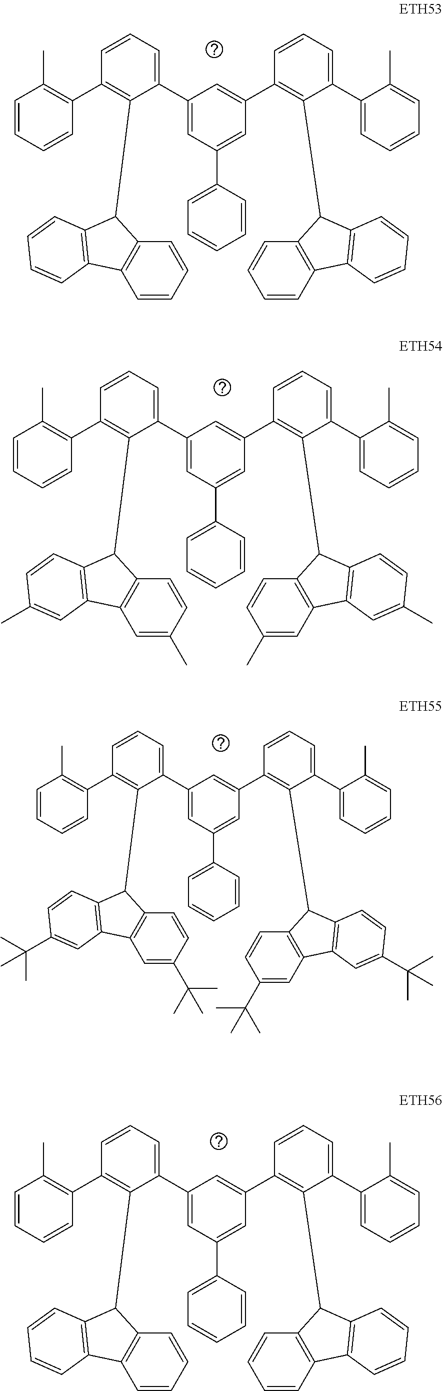

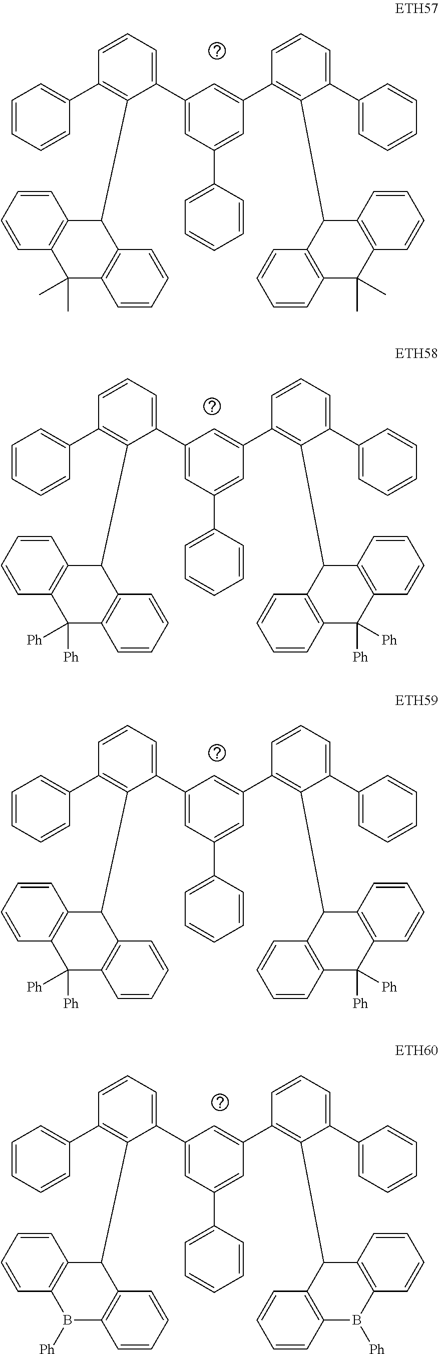

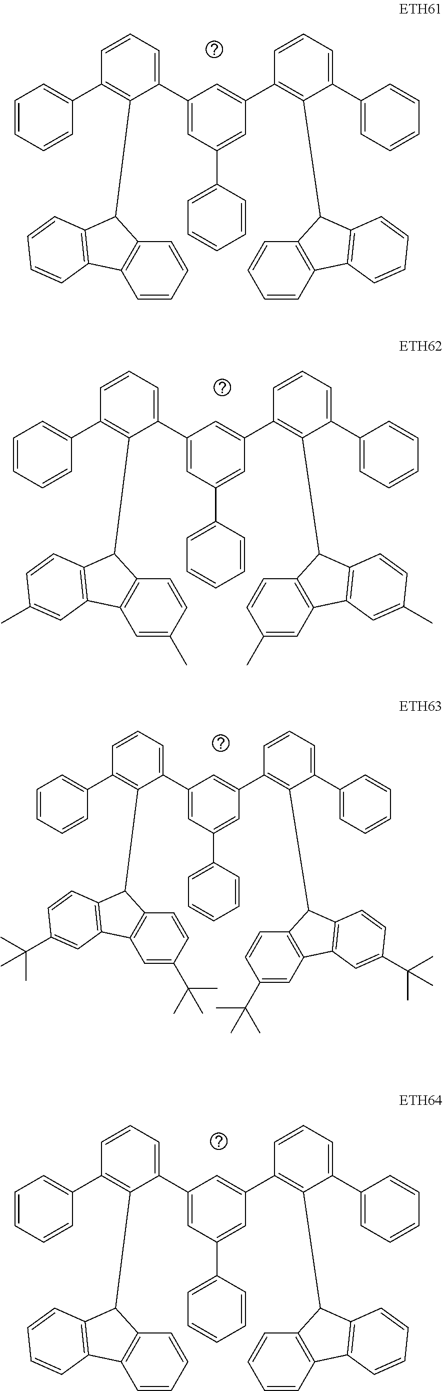

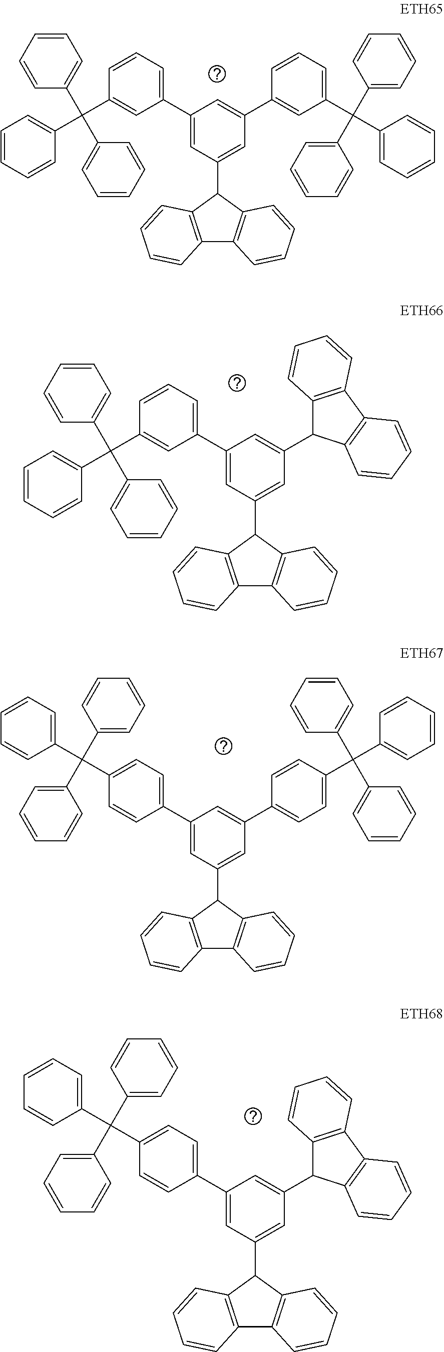

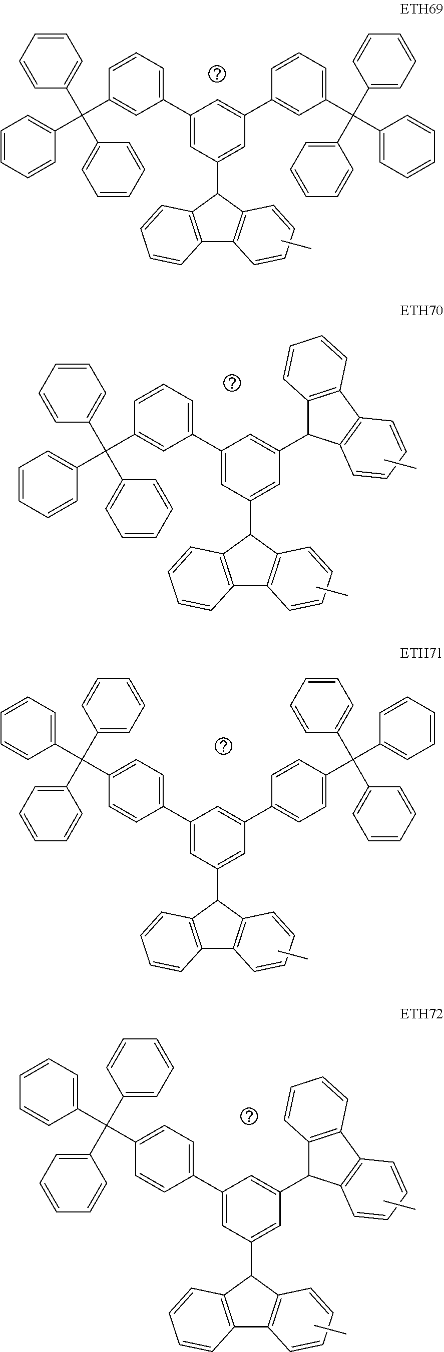

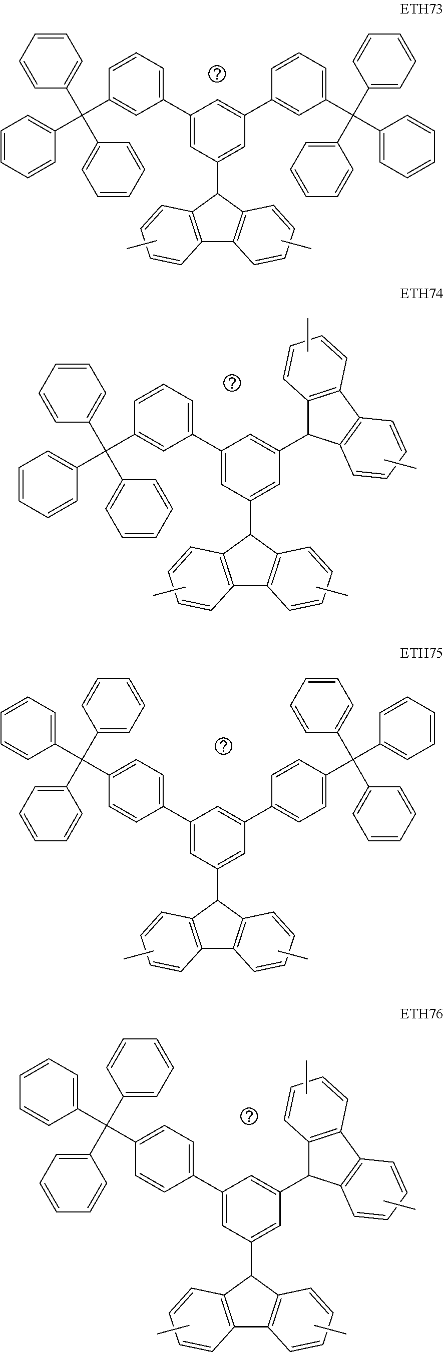

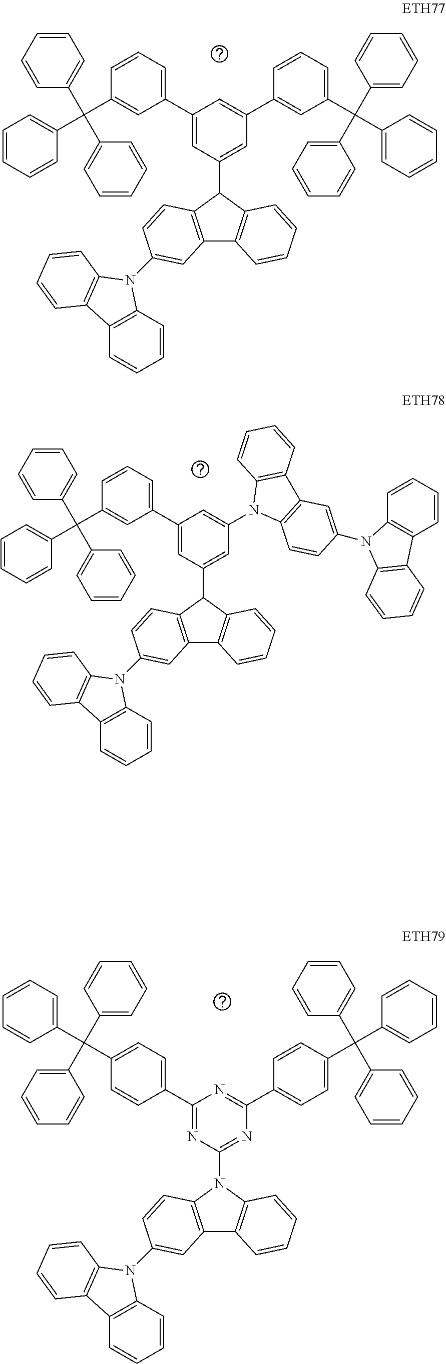 [SMILES: c1ccc(C(c2ccccc2)(c2ccccc2)c2cccc(-c3cc(-c4cccc(C(c5ccccc5)(c5ccccc5)c5ccccc5)c4)cc(C4c5ccccc5-c5cc(-n6c7ccccc7c7ccccc76)ccc54)c3)c2)cc1 ; c1ccc(C(c2ccccc2)(c2ccccc2)c2cccc(-c3cc(C4c5ccccc5-c5cc(-n6c7ccccc7c7ccccc76)ccc54)cc(-n4c5ccccc5c5cc(-n6c7ccccc7c7ccccc76)ccc54)c3)c2)cc1 ; c1ccc(C(c2ccccc2)(c2ccccc2)c2ccc(-c3nc(-c4ccc(C(c5ccccc5)(c5ccccc5)c5ccccc5)cc4)nc(-n4c5ccccc5c5cc(-n6c7ccccc7c7ccccc76)ccc54)n3)cc2)cc1]

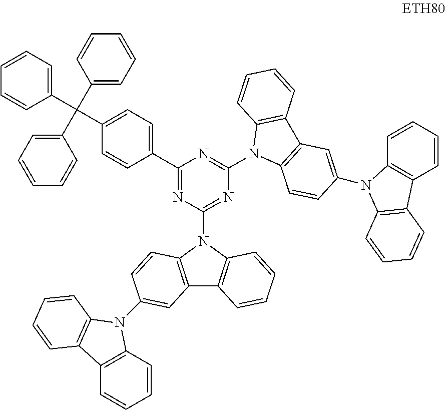 [SMILES: c1ccc(C(c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

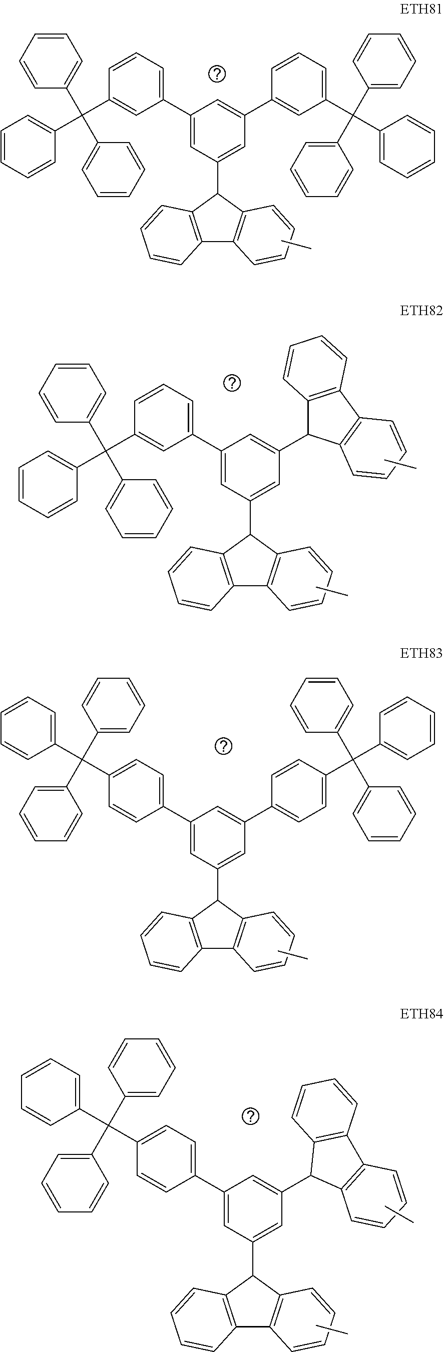

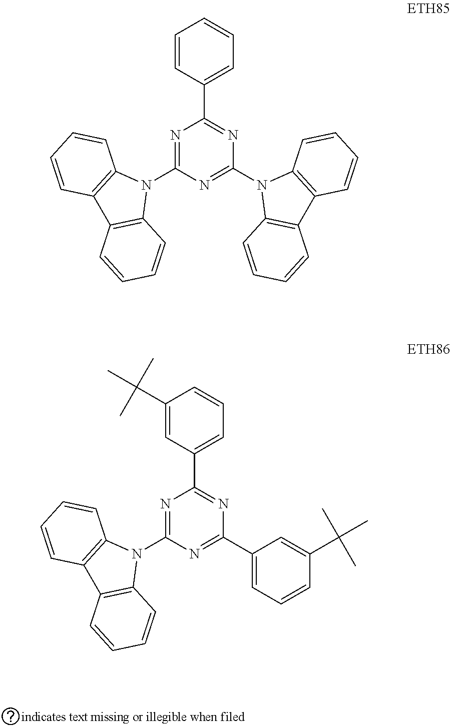 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

The first sub light emitting layer S-EML1 and the second sub light emitting S-EML2 may each include a second compound and a third compound, and the second compound and the third compound may form an exciplex. In each of the first sub light emitting layer S-EML1 and the second sub light emitting layer S-EML2, the exciplex may be formed by a hole transporting host and an electron transporting host. In this case, a triplet state energy of the exciplex formed by the hole transporting host and the electron transporting host may correspond to a difference between a lowest unoccupied molecular orbital (LUMO) energy level of the electron transporting host and a highest occupied molecular orbital (HOMO) of the hole transporting host.

For example, an absolute value of the triplet state energy level (T1) of the exciplex formed by the hole transporting host and the electron transporting host may be about 2.4 electron volt (eV) to about 3.0 eV. In some embodiments, a triplet state energy of the exciplex may be a smaller value than an energy gap of each host material. The exciplex may have a triplet state energy of 3.0 eV or less, which is an energy gap between the hole transporting host and the electron transporting host.

In one or more embodiments, each of the first sub light emitting layer S-EML1 and the second sub light emitting layer S-EML2 may further include a fourth compound in addition to the first to third compounds. The fourth compound may be utilized as a phosphorescent sensitizer in each of the first sub light emitting layer S-EML1 and the second sub light emitting layer S-EML2. Energy transfer from the fourth compound to the first compound may cause light to be emitted.

For example, the first sub light emitting layer S-EML1 and the second sub light emitting layer S-EML2 may each include platinum (Pt) as a central metal atom, and include, as the fourth compound, an organometallic complex including ligands bonded to the central metal atom. In the light emitting element ED according to one or more embodiments, the first sub light emitting layer S-EML1 and the second sub light emitting layer S-EML2 may each include a compound represented by Formula D-1 as the fourth compound.

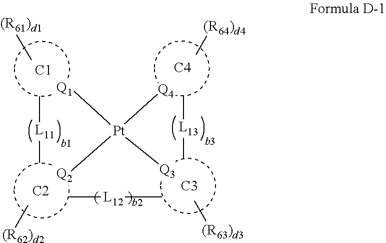

wherein, in Formula D-1, Q₁ to Q₄ may each independently be C or N.

In, Formula D-1, C1 to C4 may each independently be a substituted or unsubstituted hydrocarbon ring having 5 to 30 ring-forming carbon atoms or a substituted or unsubstituted hetero ring having 2 to 30 ring-forming carbon atoms.

In Formula D-1, L₁₁ to L₁₃ may each independently be a direct linkage,

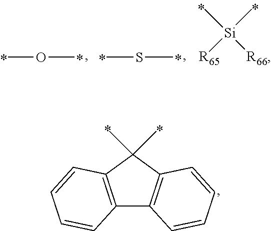

a substituted or unsubstituted divalent alkyl group having 1 to 20 carbon atoms, a substituted or unsubstituted arylene group having 6 to 30 carbon atoms, or a substituted or unsubstituted heteroarylene group having 2 to 30 ring-forming carbon atoms. In L₁₁ to L₁₃, “—*” may refer to a site connected with C1 to C4.

In Formula D-1, b1 to b3 may each independently be 0 or 1. When b1 is 0, C1 and C2 may not be connected with each other. When b2 is 0, C2 and C3 may not be connected with each other. When b3 is 0, C3 and C4 may not be connected with each other.

In Formula D-1 R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may be unsubstituted with R₆₁ to R₆₄. The case in which d1 to d4 are each 4 and R₆₁ to R₆₄ are each a hydrogen atom may be the same as the case in which d1 to d4 are each 0. When d1 to d4 are each an integer of 2 or more, R₆₁ to R₆₄ provided in plural may each be the same as, or at least one of the pluralities of R₆₁ to R₆₄ may be different from the others.

In Formula D-1, C1 to C4 may each independently be a substituted or unsubstituted hydrocarbon ring or a substituted or unsubstituted hetero ring, which are represented by any one among C-1 to C-4.

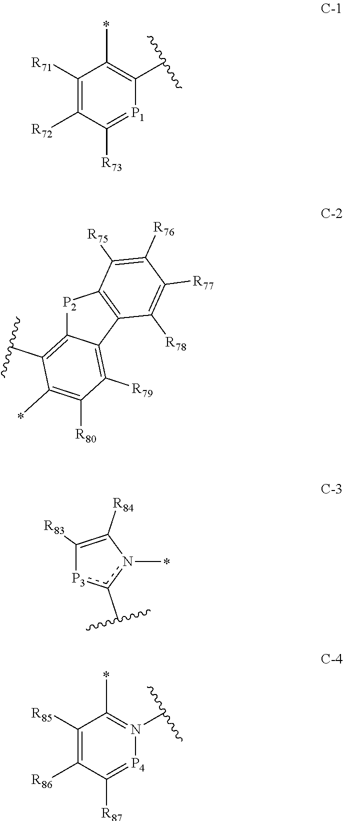

where, in C-1 to C-4, P₁ may be C—* or CR₇₄, P₂ may be N—*, or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In some embodiments, in C-1 to C-4, “ [symbol] ” may be a portion connected to Pt, which is a central metal atom, “—*” may correspond to a portion connected to a neighboring ring (C1 to C4) or a linker (L₁₁ to L₁₃).

The first sub light emitting layer S-EML1 and the second sub light emitting layer S-EML2, according to one or more embodiments, may each include a first compound, which is a fused polycyclic compound, and at least one among the second to fourth compounds. For example, the first sub light emitting layer S-EML1 and the second light emitting layer S-EML2 may each include the first compound, the second compound, and the third compound. In each of the first sub light emitting layer S-EML1 and the second sub light emitting layer S-EML2, the second compound and the third compound may form an exciplex, and energy transfer from the exciplex to the first compound may cause light to be emitted.

In some embodiments, the first sub light emitting layer S-EML1 and the second sub light emitting layer S-EML2 may each include a first compound, a second compound, a third compound, and a fourth compound. In each of the first sub light emitting layer S-EML1 and the second sub light emitting layer S-EML2, the second compound and the third compound may form exciplexes and energy transfer from the exciplexes to the fourth compound and the first compound may cause light to be emitted. In one or more embodiments, the fourth compound may be a sensitizer. In the light emitting element ED according to one or more embodiments, the fourth compound included in each of the first sub light emitting layer S-EML1 and the second sub light emitting layer S-EML2 may function as a sensitizer and serve to transfer energy from a host to the first compound, which is a light emitting dopant. For example, the fourth compound, which serves as an auxiliary dopant, may accelerate energy transfer to the first compound which is the light emitting dopant, thereby increasing the emission ratio of the first compound. Therefore, the first sub light emitting layer S-EML1 and the second sub light emitting layer S-EML2 according to one or more embodiments may each have an improved light emission efficiency. In some embodiments, when the energy transfer to the first compound increases, excitons formed in each of the first sub light emitting layer S-EML1 and the second sub light emitting layer S-EML2 rapidly cause light to be emitted without accumulating inside, thereby mitigating deterioration of the element. Therefore, the light emitting element ED according to one or more embodiments may have a long lifespan.

The light emitting element ED according to one or more embodiments may include all of the first compound, the second compound, the third compound, and the fourth compound, and thus the first sub light emitting layer S-EML1 and the second sub light emitting layer S-EML2 may each include a combination of two host materials and two dopant materials. In the light emitting element ED according to one or more embodiments, the first sub light emitting layer S-EML1 and the second sub light emitting layer S-EML2 may each concurrently (e.g., simultaneously) include the second compound and the third compound which are different two hosts, the first compound which emits thermally activated delayed fluorescence and the fourth compound which includes an organometallic complex, thereby exhibiting excellent or suitable light emission efficiency characteristics.

In one or more embodiments, the fourth compound represented by Formula D-1 may be represented by at least one among compounds listed in Compound Group 4. The first sub light emitting layer S-EML1 and the second sub light emitting layer S-EML2 may each include, as a sensitizer material, at least one among compounds listed in Compound Group 4.

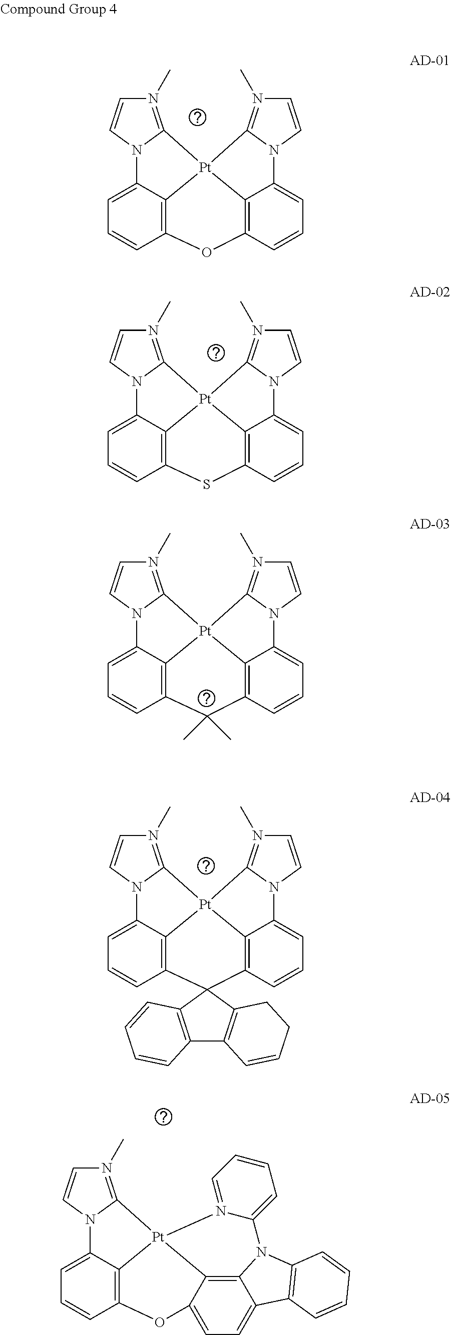

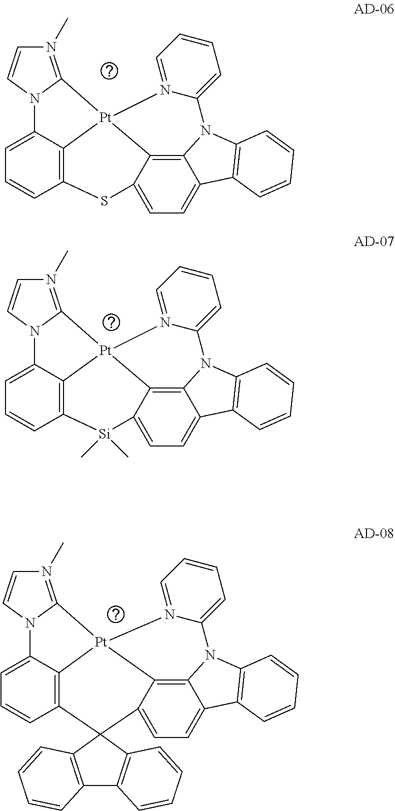

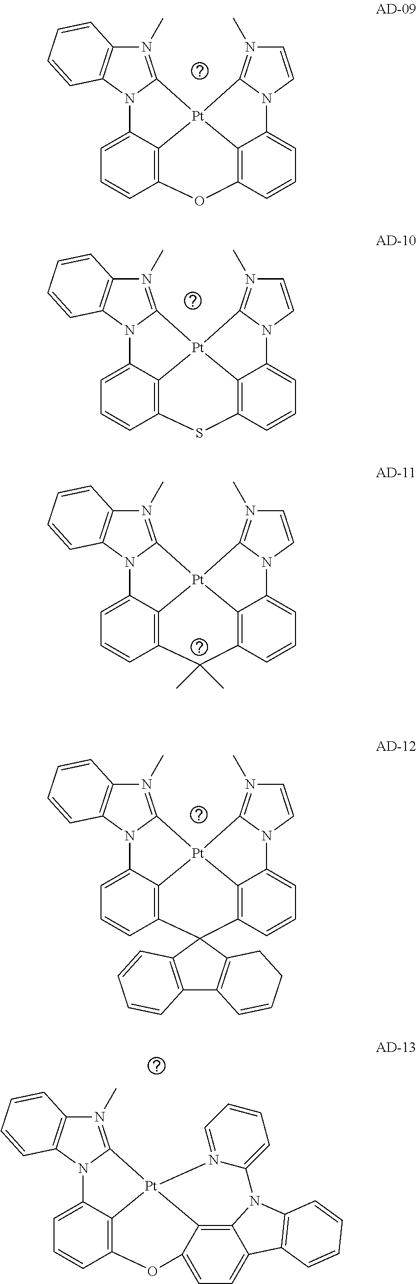

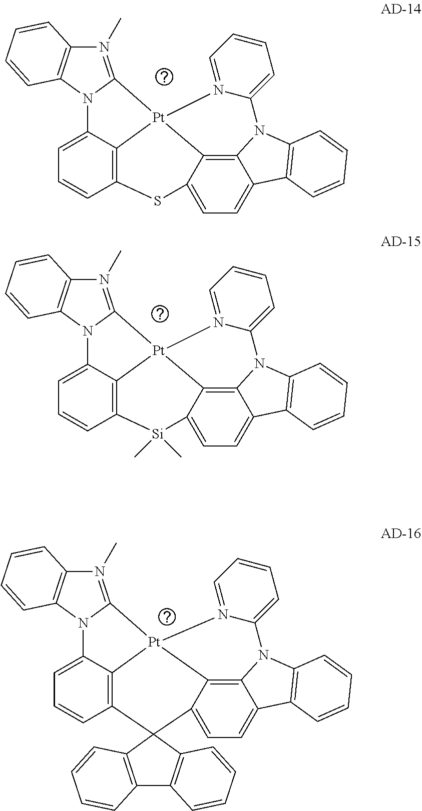

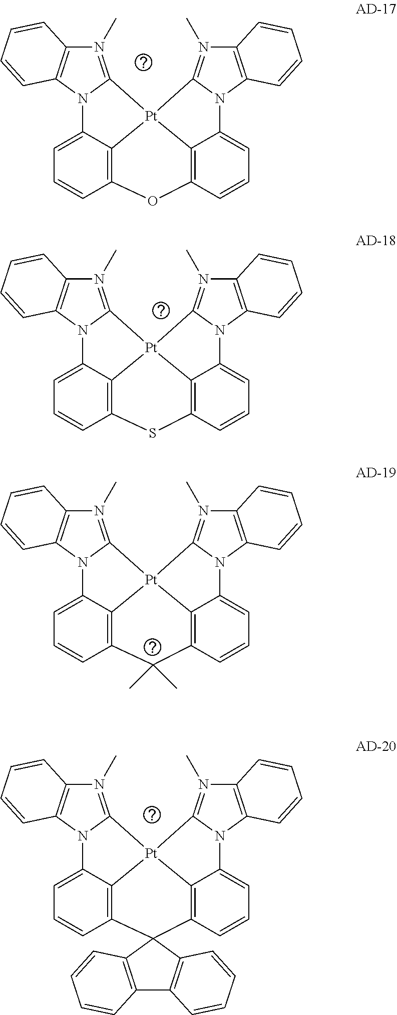

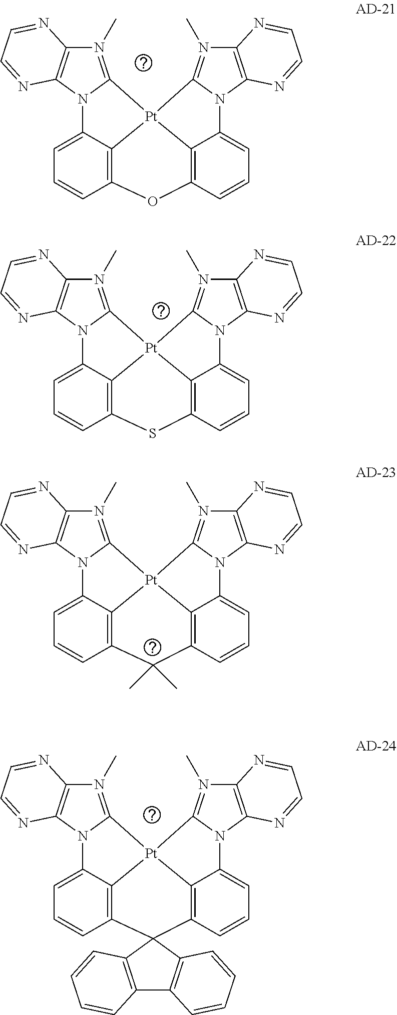

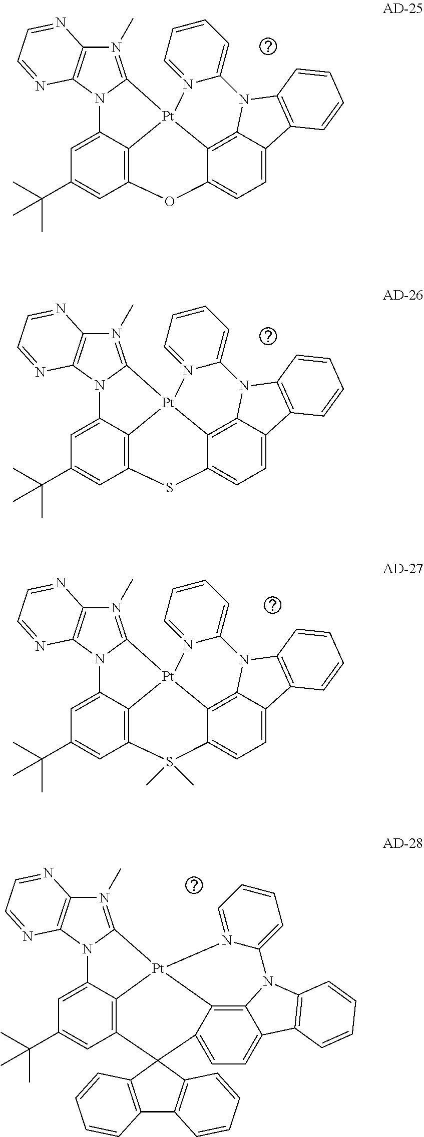

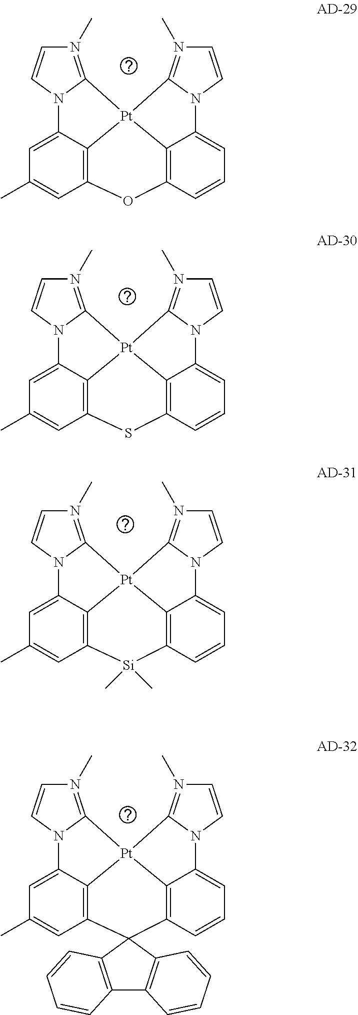

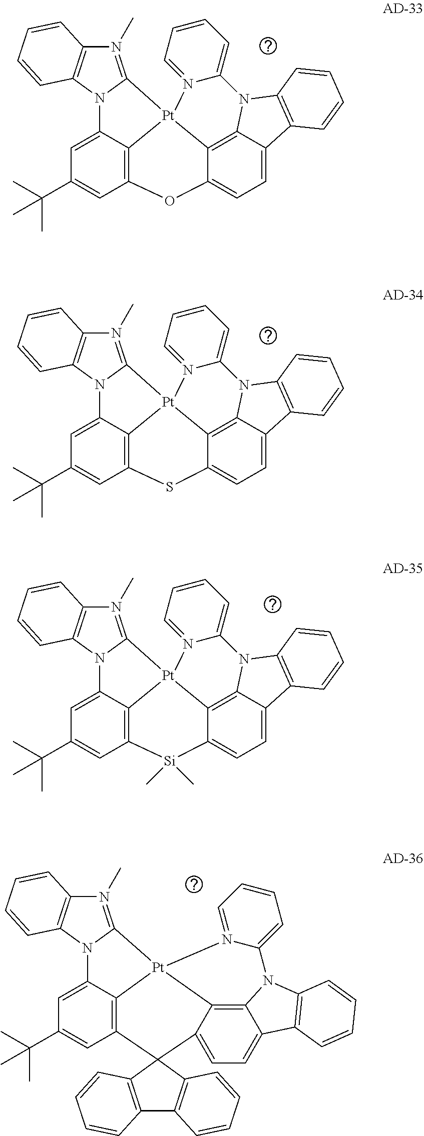

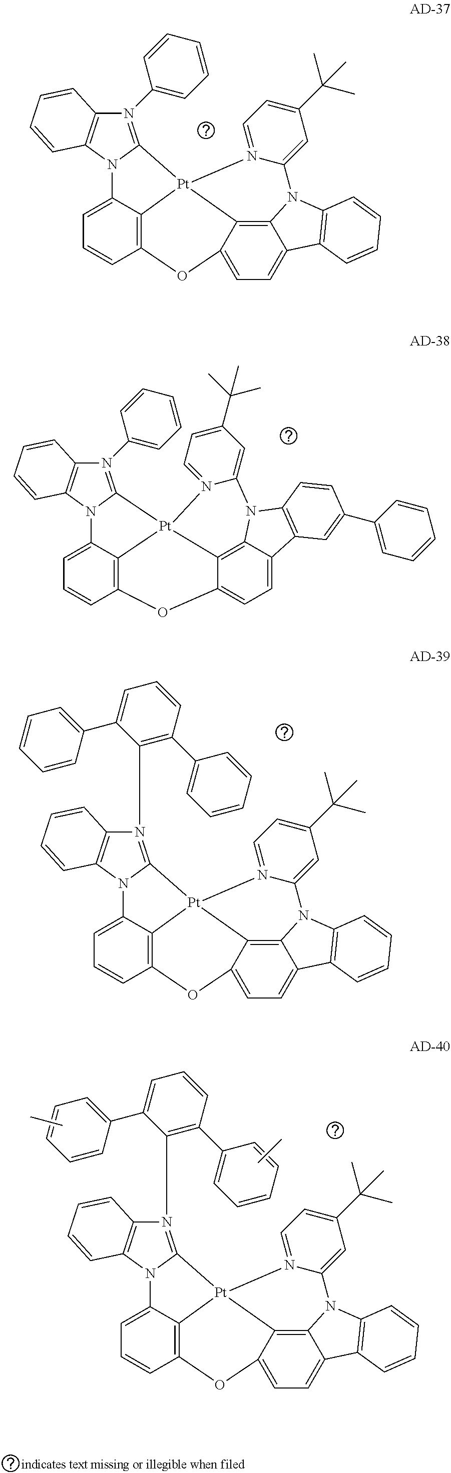

In specific compounds presented in Compound Group 4, “D” refers to a deuterium atom.

In a light emitting element ED according to one or more embodiments, when the first sub light emitting layer S-EML1 and the second sub light emitting layer S-EML2 each include all of the mentioned first compound, the second compound and the third compound, an amount of the first compound may be about 0.1 wt % to about 5 wt % with respect to a total weight of the first compound, the second compound and the third compound. However, one or more embodiments of the present disclosure is not limited thereto. When the amount of the first compound falls within the mentioned ratio range, energy transfer from the second compound and the third compound to the first compound may increase, and thus light emission efficiency and an element lifespan may increase.

In each of the first sub light emitting layer S-EML1 and the second sub light emitting layer S-EML2, amounts of the second compound and the third compound may be a remaining weight excluding the weight of the first compound. For example, in each of the first sub light emitting layer S-EML1 and the second sub light emitting layer S-EML2, the amounts of the second compound and the third compound may be about 65 wt % to about 95 wt % with respect to the total weight of the first compound, the second compound, and the third compound.

A weight ratio of the second compound to the third compound may be about 3:7 to about 7:3 with respect to the total weight of the second compound and the third compound.

When the amounts of the second compound and the third compound falls within the mentioned ratio range, charge balance characteristics in each of the first sub light emitting layer S-EML1 and the second sub light emitting layer S-EML2 may be improved, and thus the light emission efficiency and the element lifespan may increase. When the amounts of the second compound and the third compound are out of an mentioned ratio range, the charge balances in each of the first sub light emitting layer S-EML1 and the second sub light emitting layer S-EML2 may be lost, and thus the light emission efficiency may be lowered and the elements may easily deteriorate.

When the first sub light emitting layer S-EML1 and the second sub light emitting layer S-EML2 each include the fourth compound, an amount of the fourth compound in each of the first sub light emitting layer S-EML1 and the second sub light emitting layer S-EML2 may be about 10 wt % to about 30 wt % with respect to a total weight of the first compound, the second compound, the third compound, and the fourth compound. However, one or more embodiments of the present disclosure is not limited thereto. When the amount of the fourth compound falls within the mentioned amount range, energy transfer from a host to the first compound, which is a light emitting dopant, may increase, thus the emission ratio may be improved, and therefore, each light emission efficiency of the first sub light emitting layer S-EML1 and the second sub light emitting layer S-EML2 may increase. When the amounts of the first compound, the second compound, the third compound, and the fourth compound, included in each of the first sub light emitting layer S-EML1 and the second sub light emitting layer S-EML2, fall within the mentioned amount ratio range, an excellent or suitable light emission efficiency and a long-lifespan may be achieved.

In a light emitting element ED according to one or more embodiments, the first sub light emitting layer S-EML1 and the second sub light emitting layer S-EML2 may each further include suitable host and dopant in the art in addition to the mentioned host and dopant. In some embodiments, when a second light emitting element ED-2 (see FIG. 2) includes a first sub light emitting layer S-EML1 and a second sub light emitting layer S-EML2, and a first light emitting element ED-1 (see FIG. 2) and a third light emitting element ED-3 (see FIG. 2) each include a light emitting layer having a single layer, each light emitting layer in the first light emitting element ED-1 (see FIG. 2) and the third light emitting element ED-3 (see FIG. 2) may further include suitable host and dopant in the art in addition to the mentioned first to fourth compounds. Hereinafter, descriptions of the suitable host and dopant included in the first sub light emitting layer S-EML1 and the second sub light emitting layer S-EML2 may be equally applied to the single light emitting layer in each of the first light emitting element ED-1 (see FIG. 2) and the third light emitting element ED-3 (see FIG. 2).

For example, in a light emitting element ED according to one or more embodiments, a first sub light emitting layer S-EML1 and a second sub light emitting layer S-EML2 may further include an anthracene derivative, a pyrene derivative, a fluoranthene derivative, a chrysene derivative, a dihydrobenzanthracene derivative, or a triphenylene derivative. For example, the first sub light emitting layer S-EML1 and the second sub light emitting layer S-EML2 may further include an anthracene derivative or a pyrene derivative.

In a light emitting element ED according to one or more embodiments, illustrated in FIGS. 3A, and 4 to 6, a first sub light emitting layer S-EML1 and a second sub light emitting layer S-EML2 may include a host and a dopant, and a light emitting layer EML may further include a compound represented by Formula E-1. The compound represented by Formula E-1 may be utilized as a fluorescent host material.

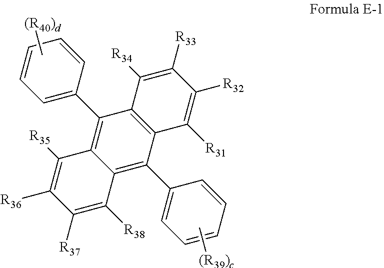

Where, in Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In some embodiments, R₃₁ to R₄₀ may be bonded to an adjacent group to form a saturated hydrocarbon ring, an unsaturated hydrocarbon ring, a saturated hetero ring, or an unsaturated hetero ring.

In Formula E-1, c and d may each independently be an integer of 0 to 5.

Formula E-1 may be represented by any one among Compounds E1 to E19.

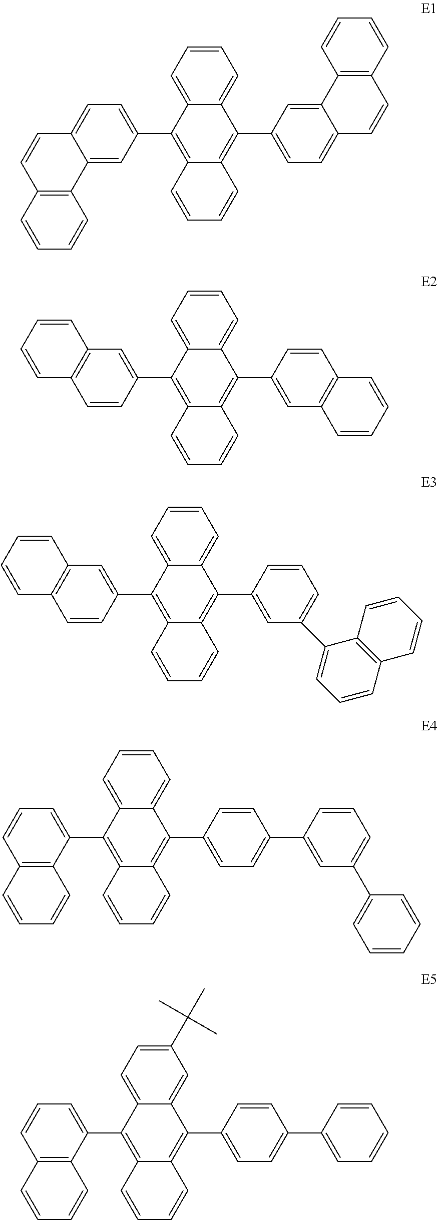

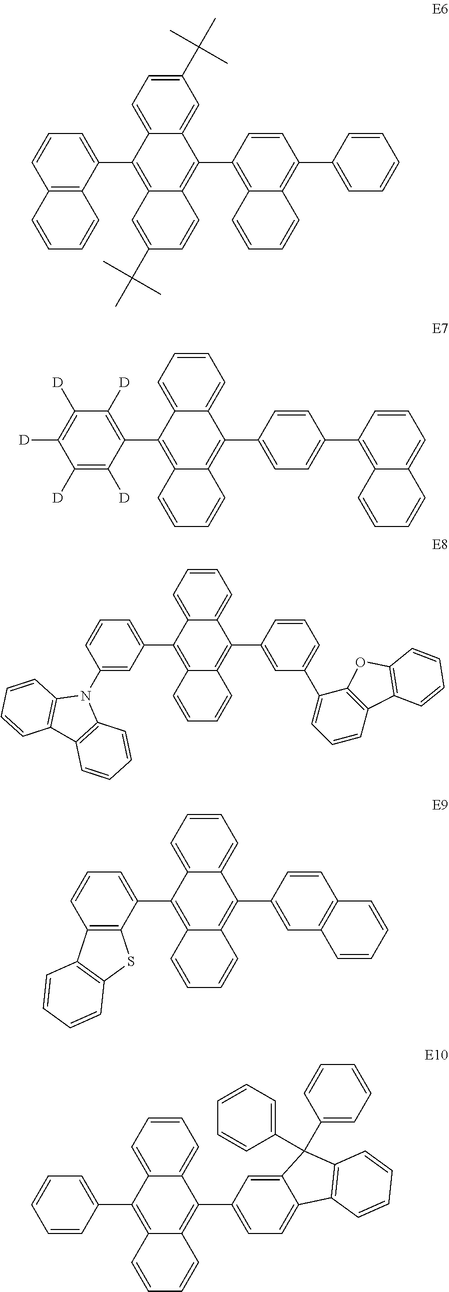

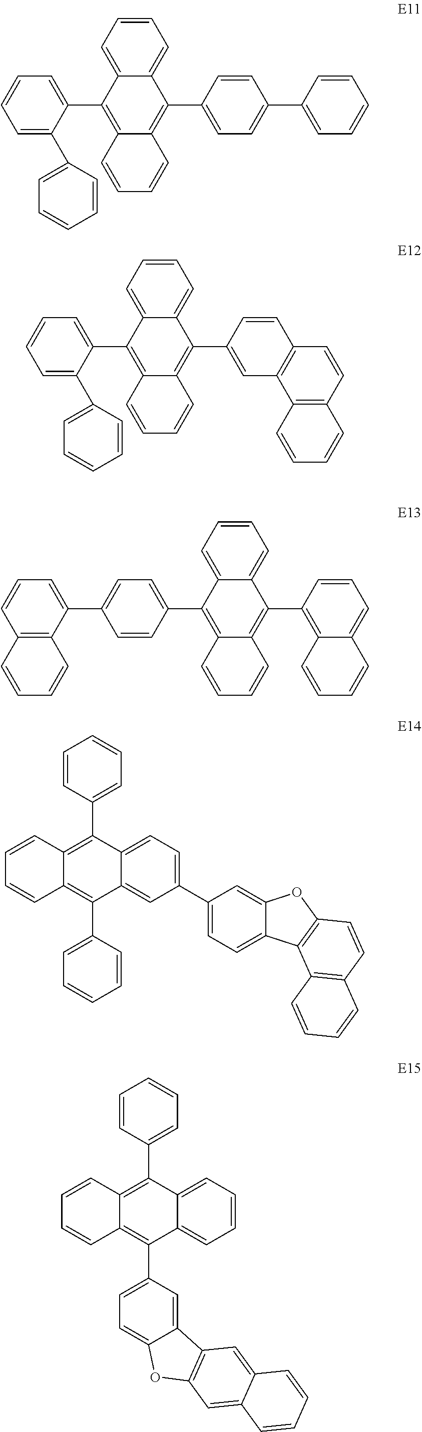

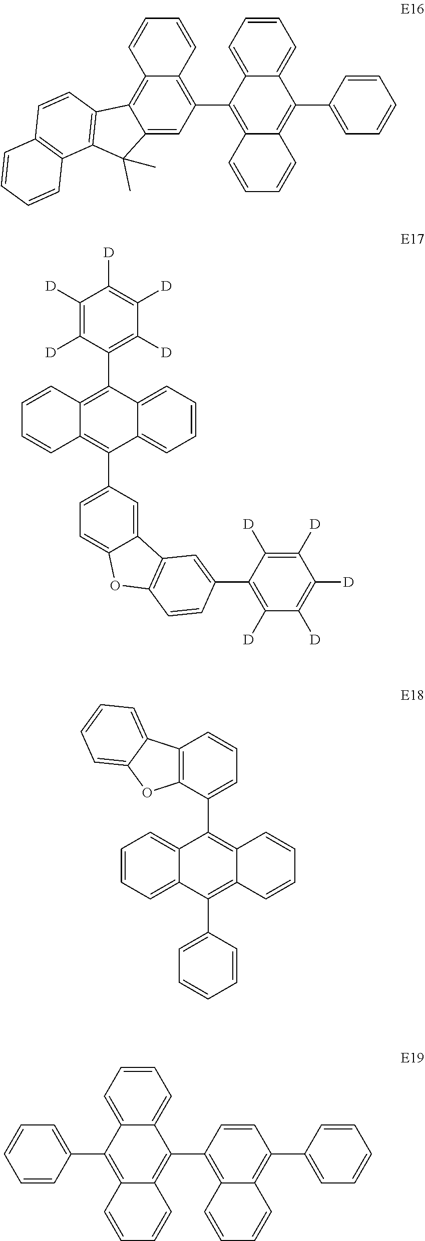

In one or more embodiments, the first sub light emitting layer S-EML1 and the second sub light emitting layer S-EML2 may each further include a compound represented by Formulas E-2a, or E-2b. The compound represented by Formulas E-2a, or E-2b may be utilized as a phosphorescent host material.

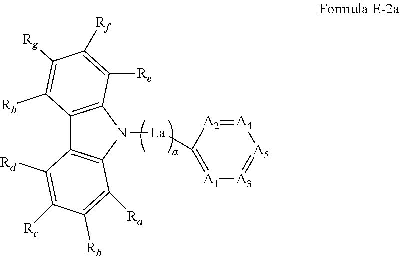

In Formula E-2a, a may be an integer of 0 to 10, La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of La may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, or a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. Rₐ to Rᵢ may be bonded to an adjacent group to form a hydrocarbon ring or a hetero ring containing N, O, S, and/or the like, as a ring-forming atom.

In some embodiments, in Formula E-2a, two or three selected from among A₁ to A₅ may be N, and the rest (i.e., each of the remaining A₁ to A₅ that are not N) may be CRᵢ.

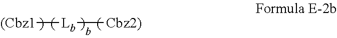

where, in Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b may be an integer of 0 to 10, and when b is an integer of 2 or more, a plurality of L_{b} may each independently be a substituted or unsubstituted arylene group having 6 to 30 ring-forming carbon atoms, or a substituted or unsubstituted heteroarylene group having 2 to 30 ring-forming carbon atoms.

The compounds represented by Formulas E-2a or E-2b may be represented by any one among compounds in Compound Group E-2. However, the compounds listed in Compound Group E-2 are for illustrative purposes, the compound represented by Formulas E-2a or E-2b is not limited to the compounds listed in Compound Group E-2.

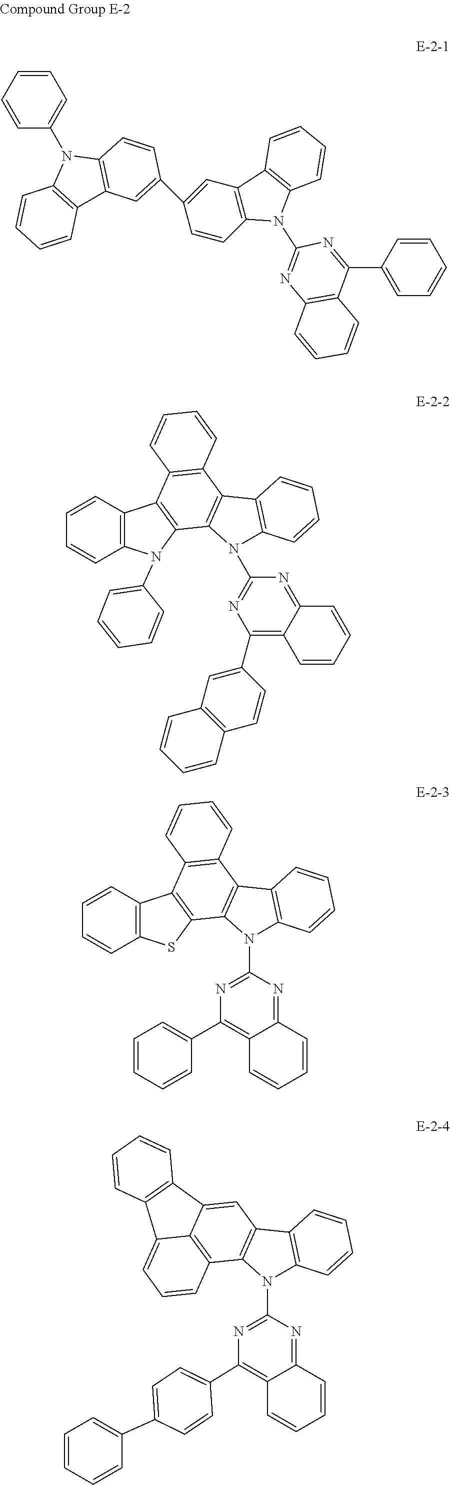

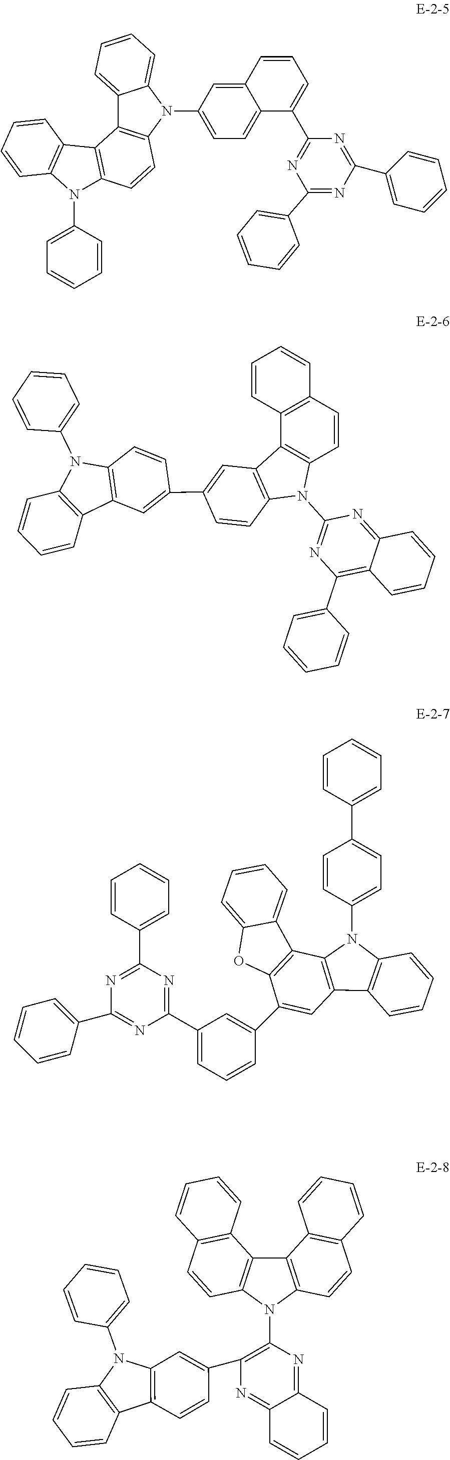 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

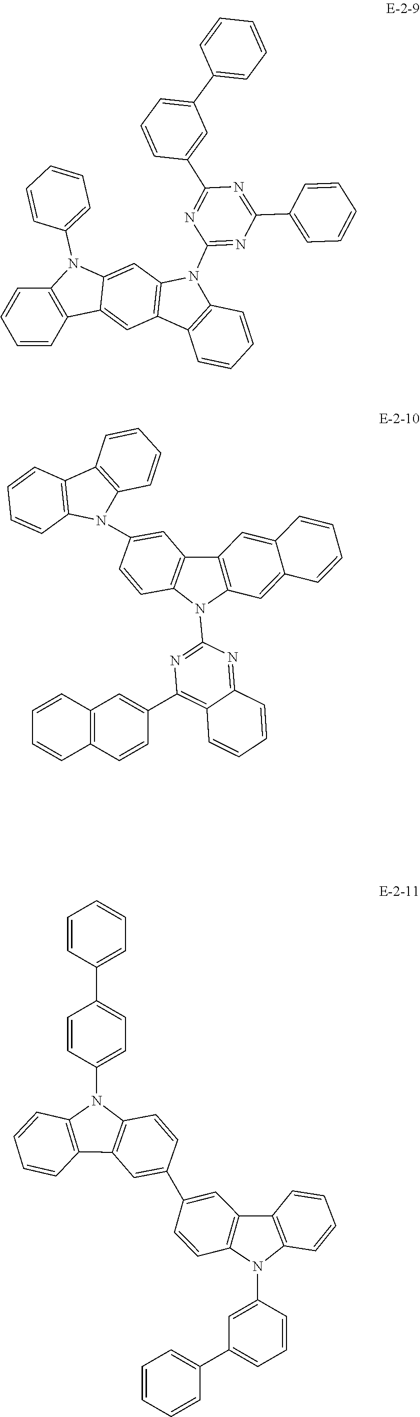 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

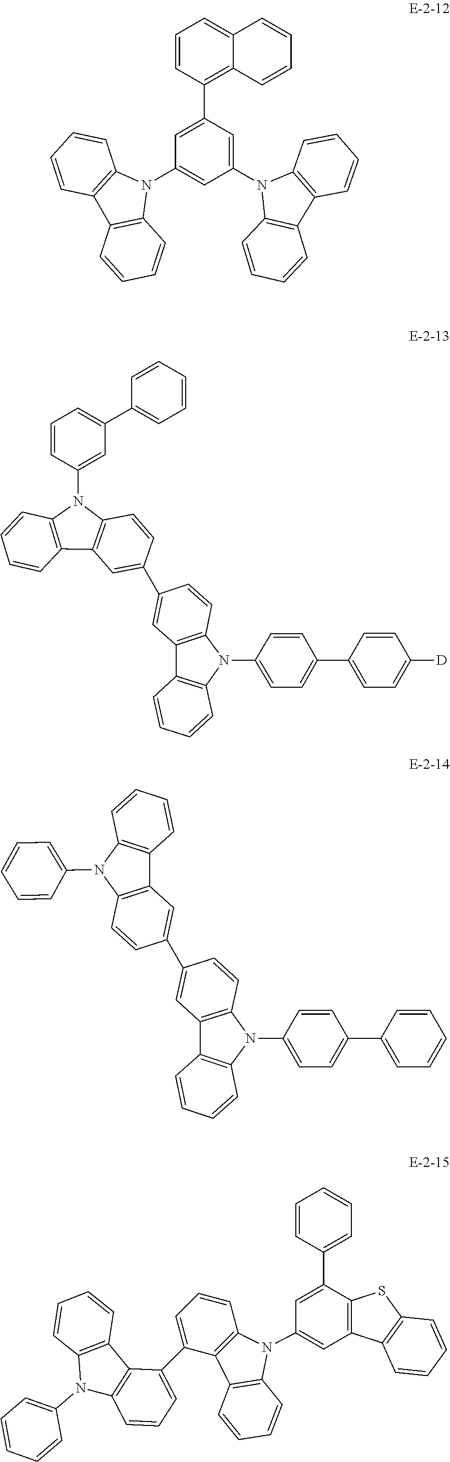 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

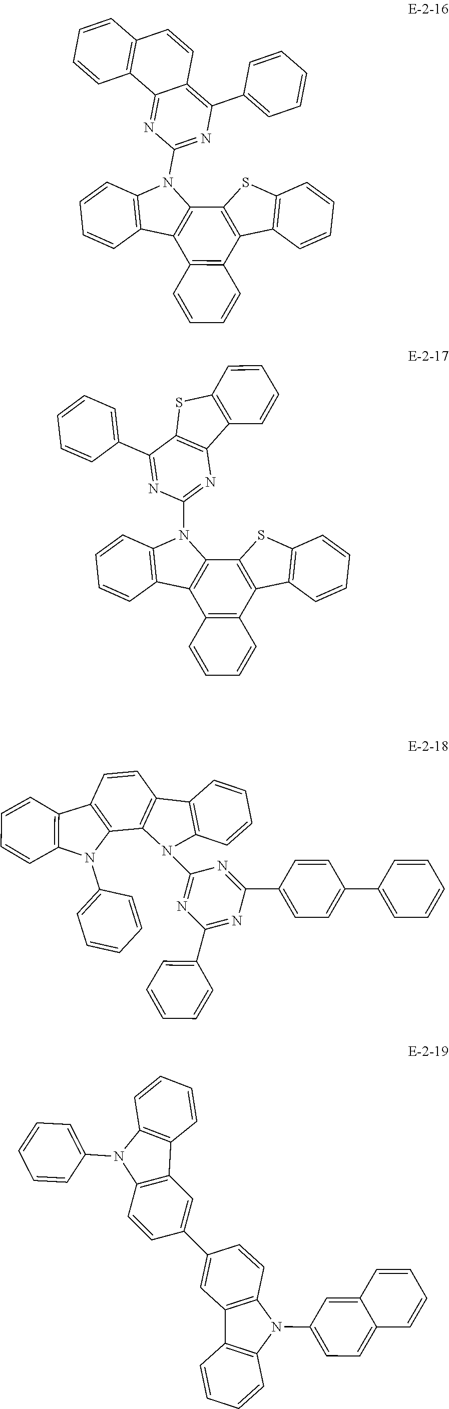

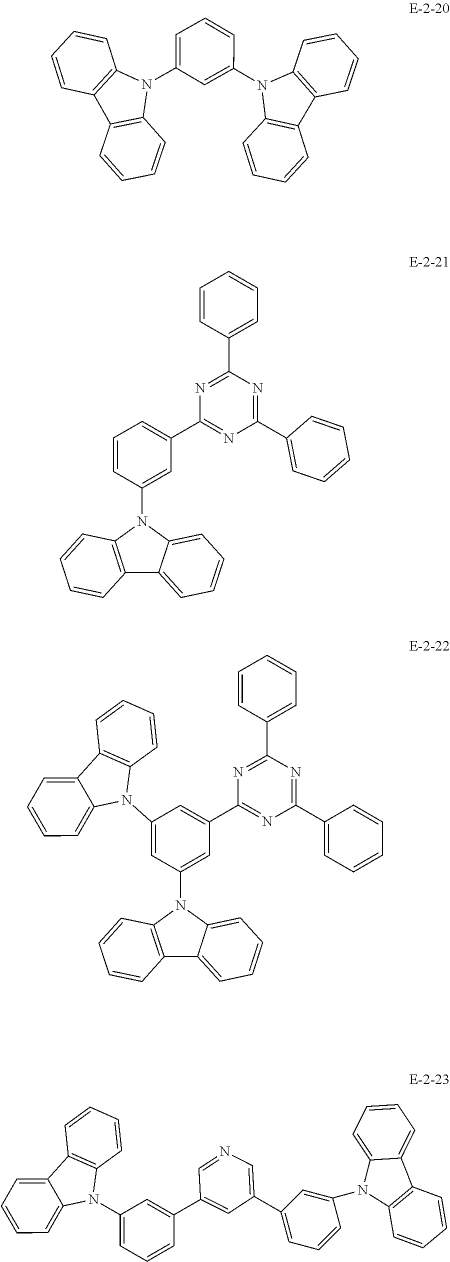 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

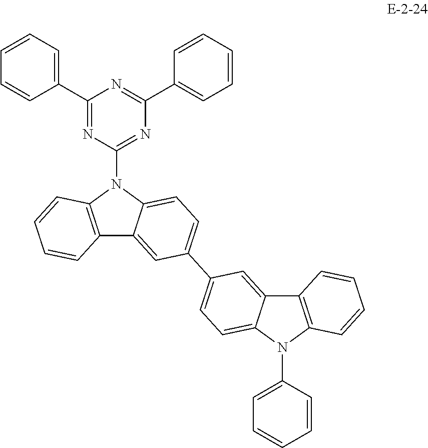 [SMILES: c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the first sub light emitting layer S-EML1 and the second sub light emitting layer S-EML2 may further include common materials suitable in the art as a host material. For example, the light emitting layer EML may include, as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis [2-(diphenylphosphino) phenyl] ether oxide (DPEPO), 4,4′-bis (N-carbazolyl)-1,1′-biphenyl (CBP), 1,3-bis (carbazol-9-yl) benzene (mCP), 2,8-Bis (diphenylphosphoryl) dibenzo[b,d] furan (PPF), 4,4′,4″-tris (carbazol-9-yl)-triphenylamine (TCTA), or 1,3,5-tris (1-phenyl-1H-benzo[d]imidazole-2-yl) benzene (TPBi). However, one or more embodiments of the present disclosure is not limited thereto, and, for example, examples of the host material may include tris (8-hydroxyquinolino) aluminum (Alq₃), 9,10-di (naphthalene-2-yl) anthracene (ADN), 2-tert-butyl-9,10-di (naphth-2-yl) anthracene (TBADN), distyrylarylene (DSA), 4,4′-bis (9-carbazolyl)-2,2′-dimethyl-biphenyl (CDBP), 2-Methyl-9,10-bis (naphthalen-2-yl) anthracene (MADN), hexaphenyl cyclotriphosphazene (CP1), 1,4-bis (triphenylsilyl) benzene (UGH2), hexaphenylcyclotrisiloxane (DPSiO₃), octaphenylcyclotetra siloxane (DPSiO₄), and/or the like.

The first sub light emitting layer S-EML1 and the second sub light emitting layer S-EML2 may each include a compound represented by Formulas M-a. The compound represented by Formulas M-a may be utilized as a phosphorescent dopant material.

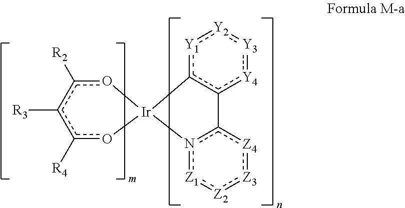

wherein, in Formula M-a, Y₁ to Y₄ and Z₁ to Z₄ may each independently CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m is 0 or 1, and n is 2 or 3. In Formula M-a, when m is 0, n is 3, and when m is 1, and n is 2.

The compound represented by Formula M-a may be utilized as a phosphorescent dopant.

The compound represented by Formula M-a may be represented by any one among Compounds M-a1 to M-a25. However, Compounds M-a1 to M-a25 are for illustrative purposes, and the compound represented by Formula M-a is not limited to the compounds listed in Compounds M-a1 to M-a25.

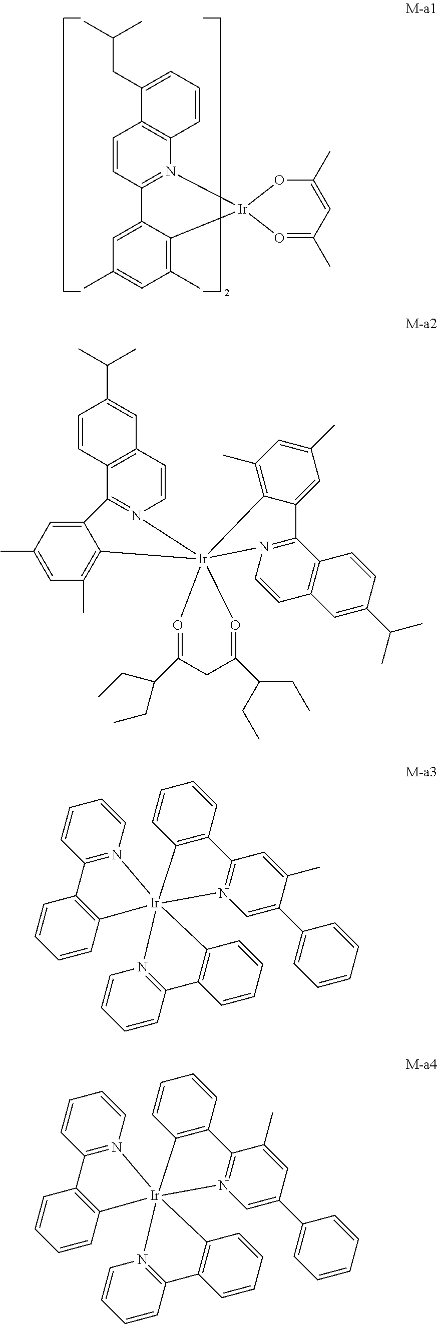

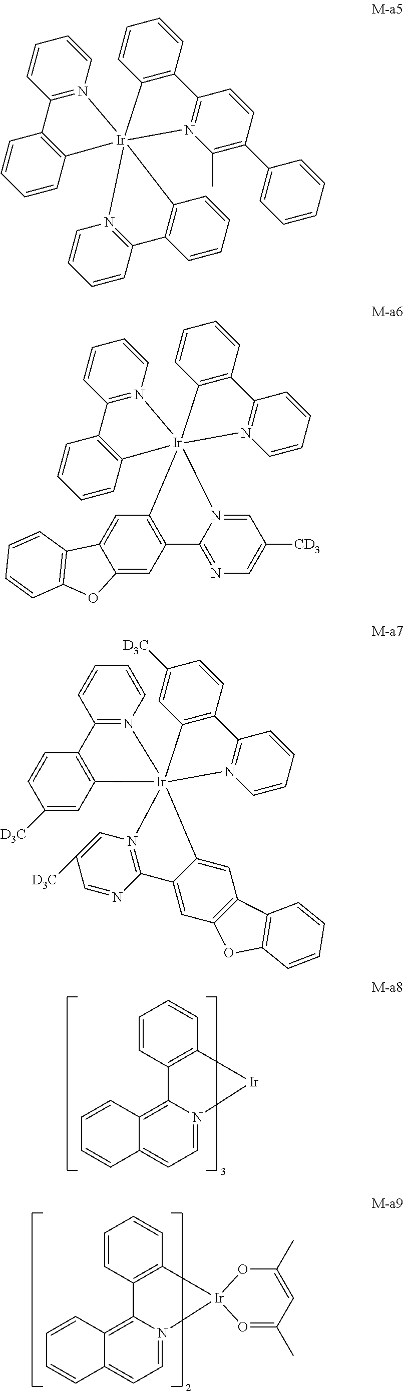

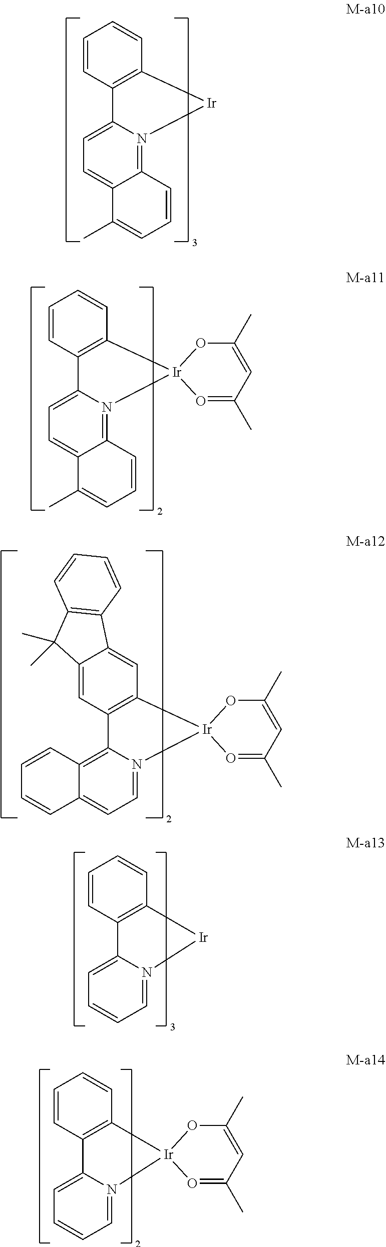

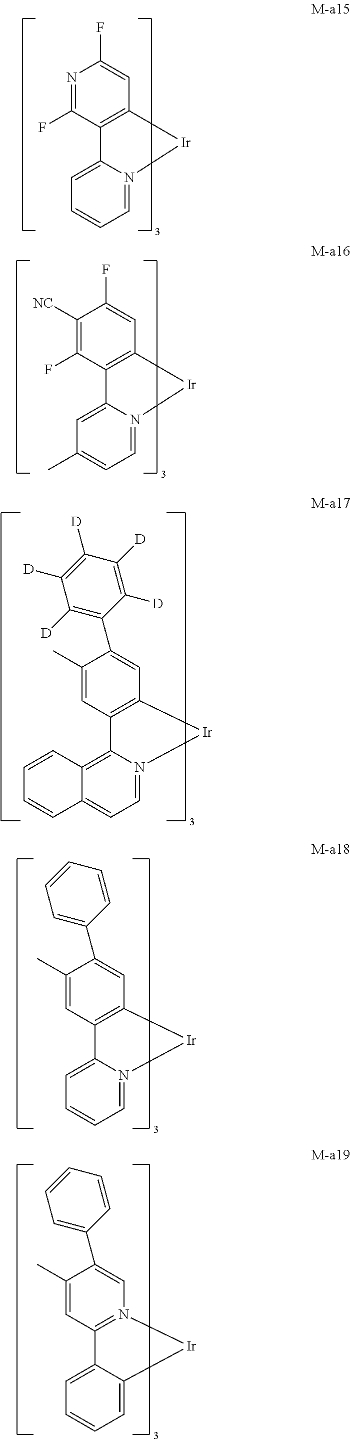

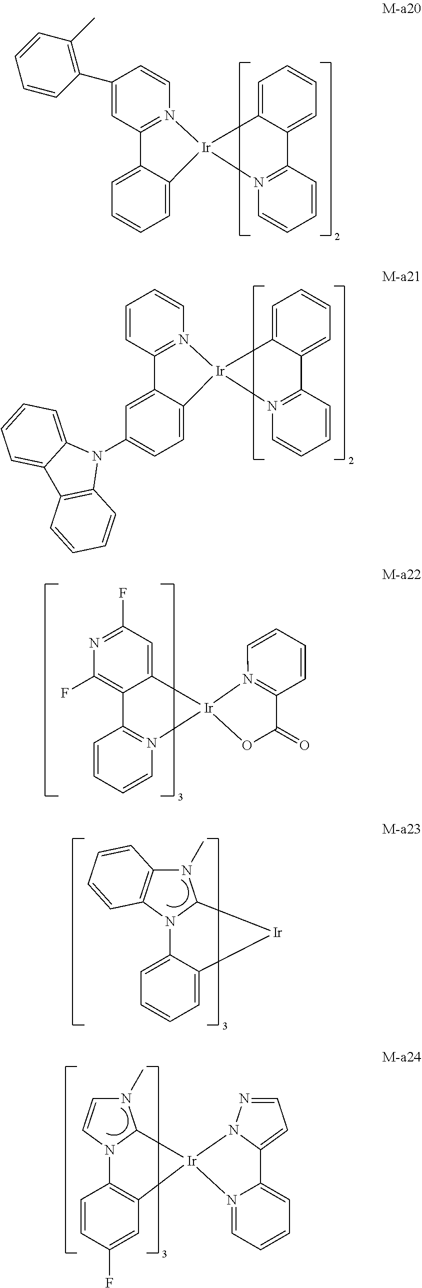

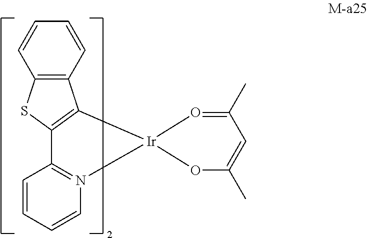

Compounds M-a1 and M-a2 may be utilized as a red dopant material, and Compounds M-a3 to M-a7 may be utilized as a green dopant material.

The first sub light emitting layer S-EML1 and the second sub light emitting layer S-EML2 may each further include a compound represented by any one among Formulas F-a, and F-b. The compound represented by Formulas F-a, or F-b may be utilized as a phosphorescent dopant material.

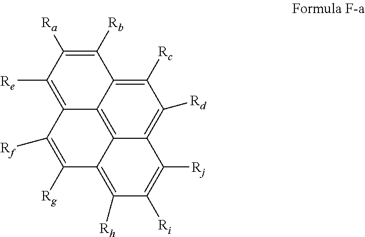

wherein, in Formula F-a, two selected from among Rₐ to Rⱼ may each independently be substituted with *—NAr₁Ar₂. The rest among Rₐ to Rⱼ, unsubstituted with *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one among Ar₁ and Ar₂ may be a heteroaryl group containing O or S as a ring-forming atom.

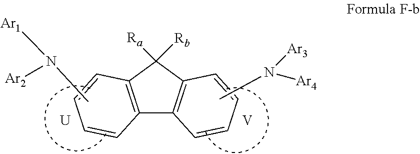

wherein, in Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted hetero ring having 2 to 30 ring-forming carbon atoms.

In Formula F-b, the numbers of rings represented by U and V may each independently be 0 or 1. For example, in Formula F-b, when the number of U or V is 1, one ring forms a fused ring at the designated part by U or V, and when the number of U or V is 0, no ring is present at the designated part by U or V. For example, when the number of U is 0 and the number of V is 1, or when the number of U is 1 and the number of V is 0, a fused ring having a fluorene core in Formula F-b may be a ring compound with four rings. In some embodiments, when the number of both (e.g., simultaneously) U and V is 0, the fused ring in Formula F-b may be a ring compound with three rings. In some embodiments, when the number of both (e.g., simultaneously) U and V is 1, a fused ring having the fluorene core of Formula F-b may be a ring compound with five rings.

In one or more embodiments, the first sub light emitting layer S-EML1 and the second sub light emitting layer S-EML2 may each include, as a suitable dopant material, a styryl derivative (e.g., 1,4-bis [2-(3-N-ethylcarbazoryl) vinyl] benzene (BCzVB), 4-(di-p-tolylamino)-4′-[(di-p-tolylamino) styryl] stilbene (DPAVB), N-(4-((E)-2-(6-((E)-4-(diphenylamino) styryl) naphthalen-2-yl) vinyl) phenyl)-N-phenylbenzenamine (N-BDAVBi)), 4,4′-bis [2-(4-(N,N-diphenylamino) phenyl) vinyl] biphenyl (DPAVBi), perylene and a derivative thereof (e.g., 2,5,8,11-Tetra-t-butylperylene (TBP)), pyrene and a derivative thereof (e.g., 1,1-dipyrene, 1,4-dipyrenylbenzene, 1,4-bis (N, N-Diphenylamino) pyrene), and/or the like The first sub light emitting layer S-EML1 and the second sub light emitting layer S-EML2 may each include a suitable phosphorescent dopant material. For example, examples of the phosphorescent dopant may include a metal complex containing iridium (Ir), platinum (Pt), osmium (Os), gold (Au), titanium (Ti), zirconium (Zr), hafnium (Hf), europium (Eu), terbium (Tb) or thulium (Tm), and/or the like For example, iridium (III) bis (4,6-difluorophenylpyridinato-N,C2′) picolinate (FIrpic), bis (2,4-difluorophenylpyridinato)-tetrakis (1-pyrazolyl) borate iridium (III) (Fir6), or platinum octaethyl porphyrin (PtOEP) may be utilized as a phosphorescent dopant. However, one or more embodiments of the present disclosure is not limited thereto.

The first sub light emitting layer S-EML1 and the second sub light emitting layer S-EML2 may each include a quantum dot material. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and/or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In some embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

An example of the shell of the quantum dots may include a metal or non-metal oxide, a semiconductor compound, or a combination thereof. For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

Each element included in a polynary compound such as the binary compound, or the ternary compound may be present in a particle with a substantially uniform or non-substantially uniform concentration distribution. For example, the formulae refer to the types (kinds) of elements included in the compounds, and the elemental ratio in the compound may be different.

The quantum dot may have a full width of half maximum (FWHM) of a light emitting wavelength spectrum of about 45 nm or less, about 40 nm or less, and more about 30 nm or less, and color purity or color reproducibility may be improved in the above range. In some embodiments, light emitted through such quantum dot is emitted in all directions so that a wide viewing angle may be improved.

In some embodiments, although the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplate particles, and/or the like may be utilized.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as above (utilizing different sizes of quantum dots or different elemental ratios in the quantum dot compound) is utilized, and thus the light emitting element, which emits light in one or more suitable wavelengths, may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

In each of the light emitting elements ED of embodiments illustrated in FIGS. 3a and 4 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2:

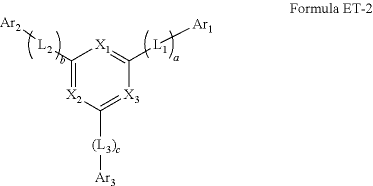

In Formula ET-2, at least one among X₁ to X₃ is N, and the rest (e.g., each of the remaining X₁ to X₃ that are not N) are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris (8-hydroxyquinolinato) aluminum (Alq₃), 1,3,5-tri [(3-pyridyl)-phen-3-yl] benzene, 2,4,6-tris (3′-(pyridin-3-yl) biphenyl-3-yl)-1,3,5-triazine, 2-(4-(N-phenylbenzoimidazol-1-yl) phenyl)-9,10-dinaphthylanthracene, 1,3,5-tri (1-phenyl-1H-benzo[d]imidazol-2-yl) benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis (2-methyl-8-quinolinolato-N1,O8)-(1,1′-biphenyl-4-olato) aluminum (BAlq), beryllium bis (benzoquinolin-10-olate) (Bebq₂), 9,10-di (naphthalene-2-yl) anthracene (ADN), 1,3-bis [3,5-di(pyridin-3-yl)phenyl]benzene (BmPyPhB), or a mixture thereof.

The electron transport region ETR may include at least one among Compound ET1 to Compound ET36:

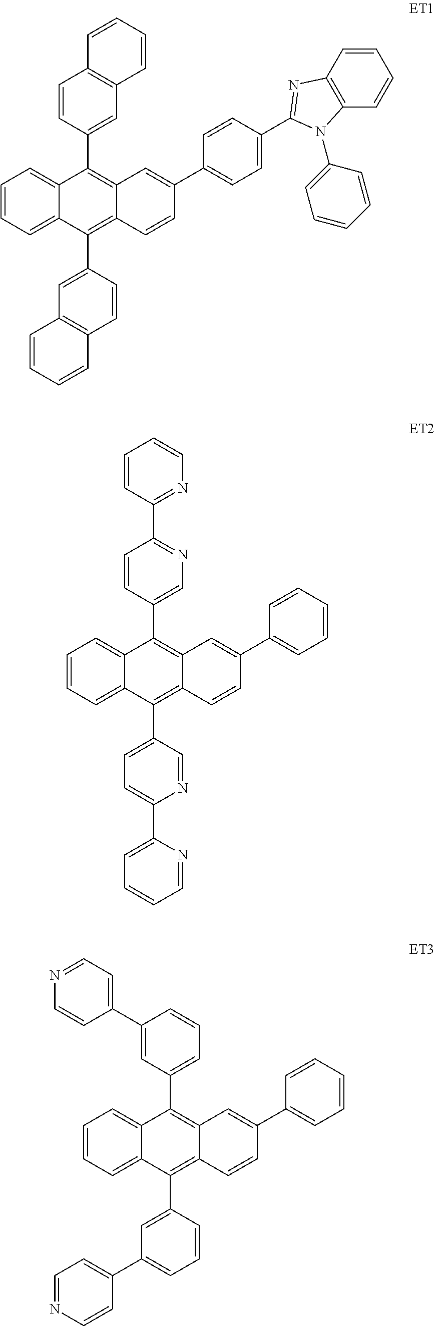 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

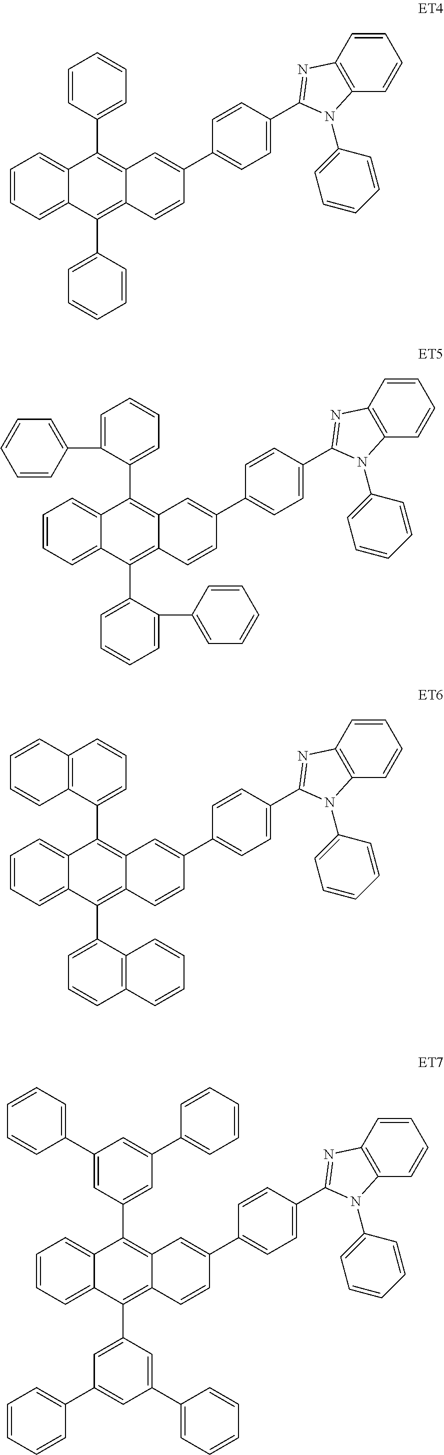 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

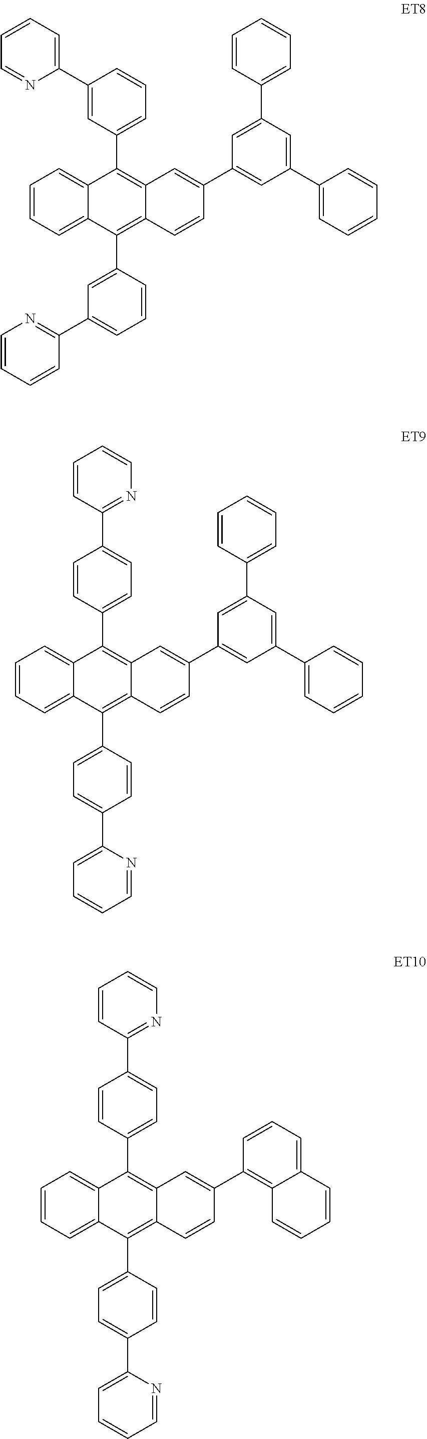 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

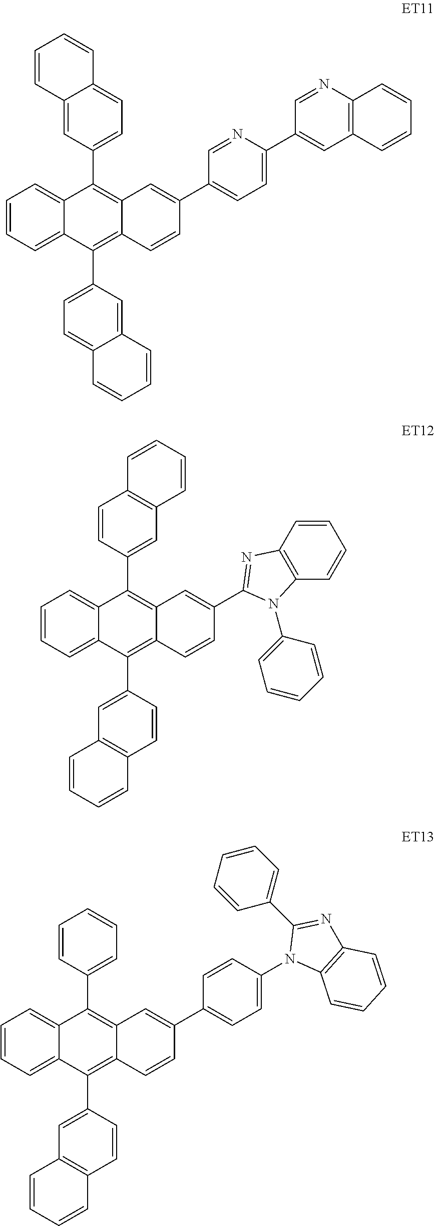 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

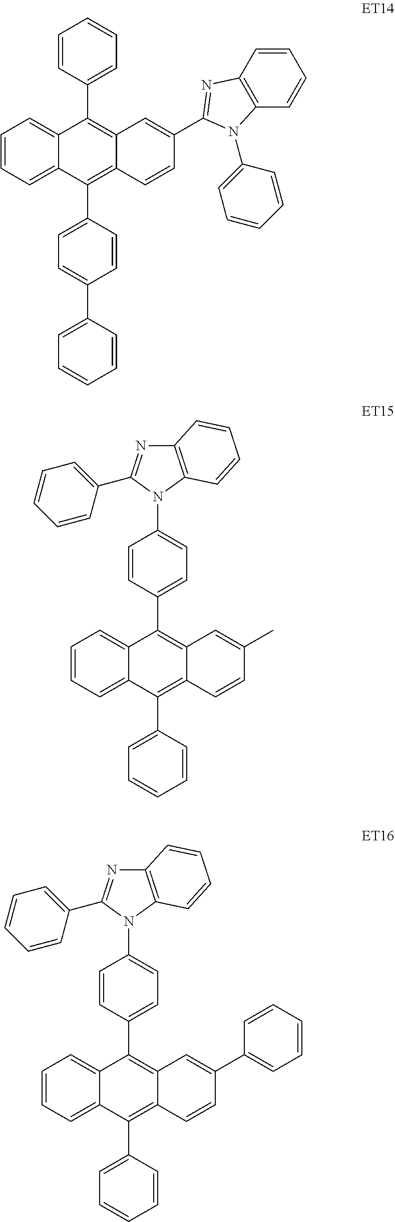 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

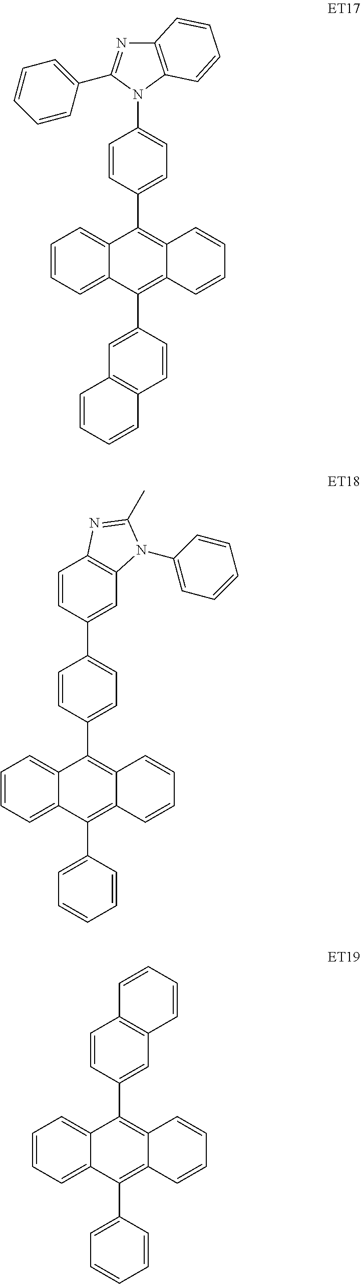

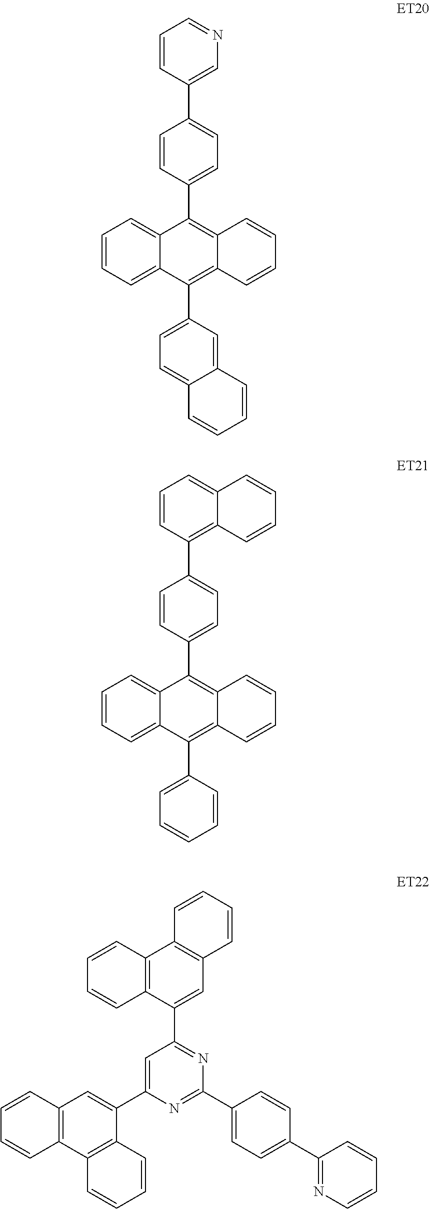

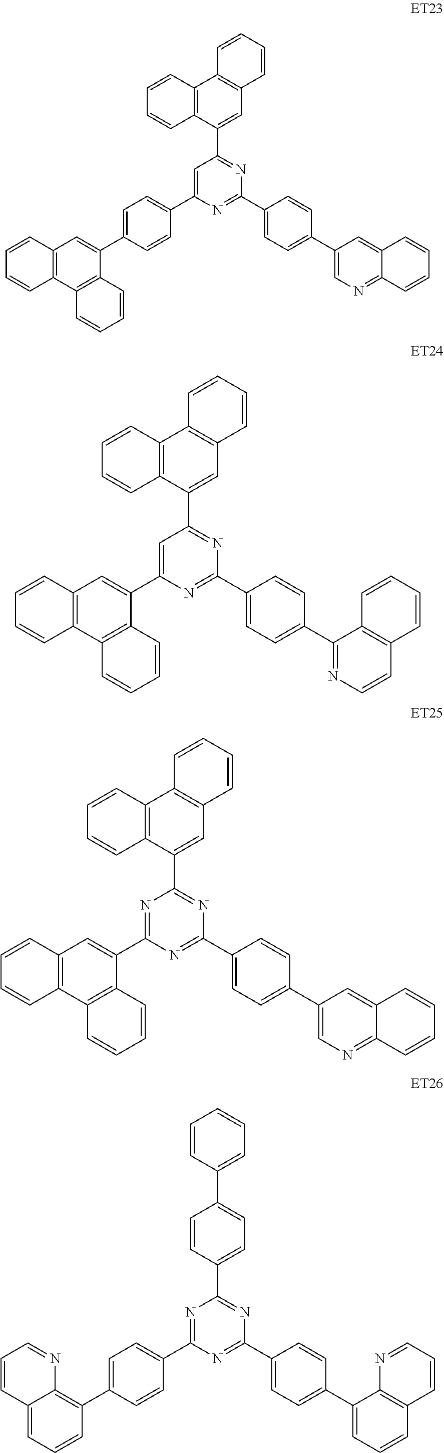 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

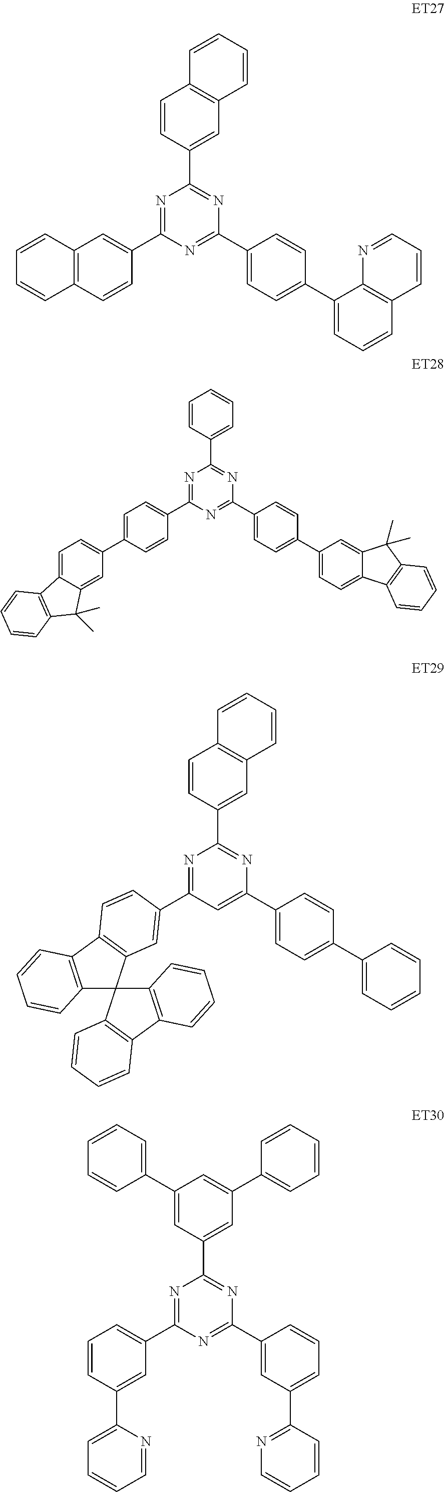

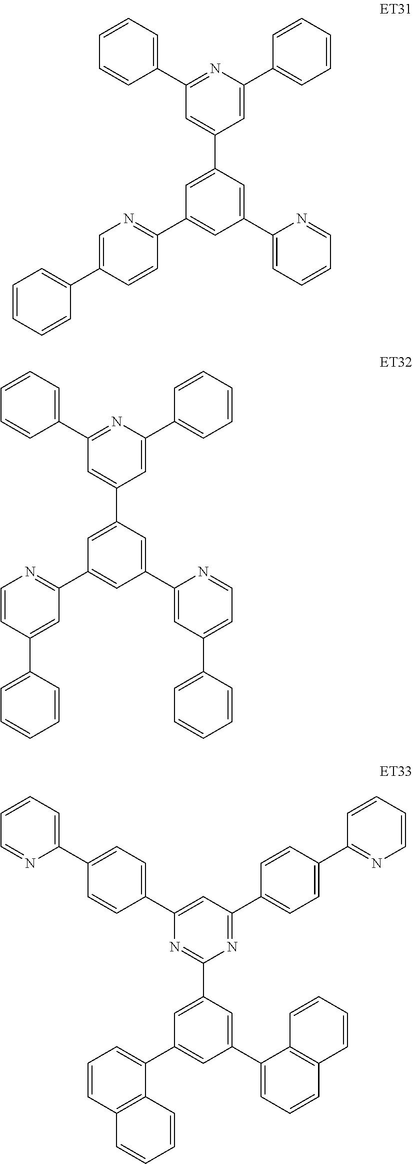

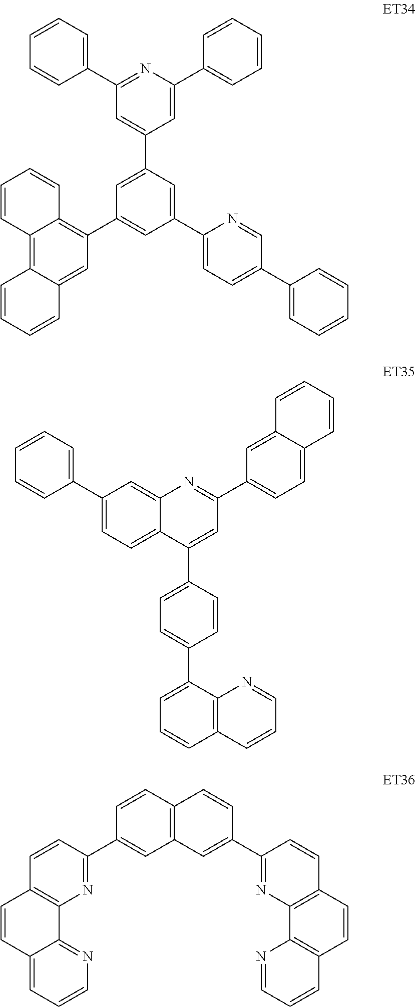

In some embodiments, the electron transport region ETR may include a metal halide such as LiF, NaCl, CsF, RbCl, RbI, CuI, and KI, a lanthanide metal such as Yb, and a co-deposited material of the metal halide and the lanthanide metal. For example, the electron transport region ETR may include KI:Yb, RbI:Yb, LiF:Yb, and/or the like, as a co-deposited material. In some embodiments, the electron transport region ETR may be formed utilizing a metal oxide such as Li₂O or BaO, or 8-hydroxyl-lithium quinolate (Liq), and/or the like, but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl (4-(triphenylsilyl) phenyl) phosphine oxide (TSPO1), or 4,7-diphenyl-1,10-phenanthroline (Bphen) in addition to the described materials, but the embodiment of the present disclosure is not limited thereto.

The electron transport region ETR may include the described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, and/or a compound or mixture thereof (e.g., AgMg, AgYb, or MgAg). In some embodiments, the second electrode EL2 may have a multilayer structure including a reflective film or a transflective film formed of the described materials, and a transparent conductive film formed of ITO, IZO, ZnO, ITZO, and/or the like. For example, the second electrode EL2 may include the described metal materials, combinations of at least two metal materials of the described metal materials, oxides of the described metal materials, and/or the like.

the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting element ED of one or more embodiments. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, and/or the like.

For example, when the capping layer CPL includes an organic material, the organic material may include a-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-tris (carbazol-9-yl) triphenylamine (TCTA), and/or the like, or an epoxy resin, or acrylate such as methacrylate. However, the embodiment of the present disclosure is not limited thereto, and the capping layer CPL may include at least one among Compounds P1 to P5:

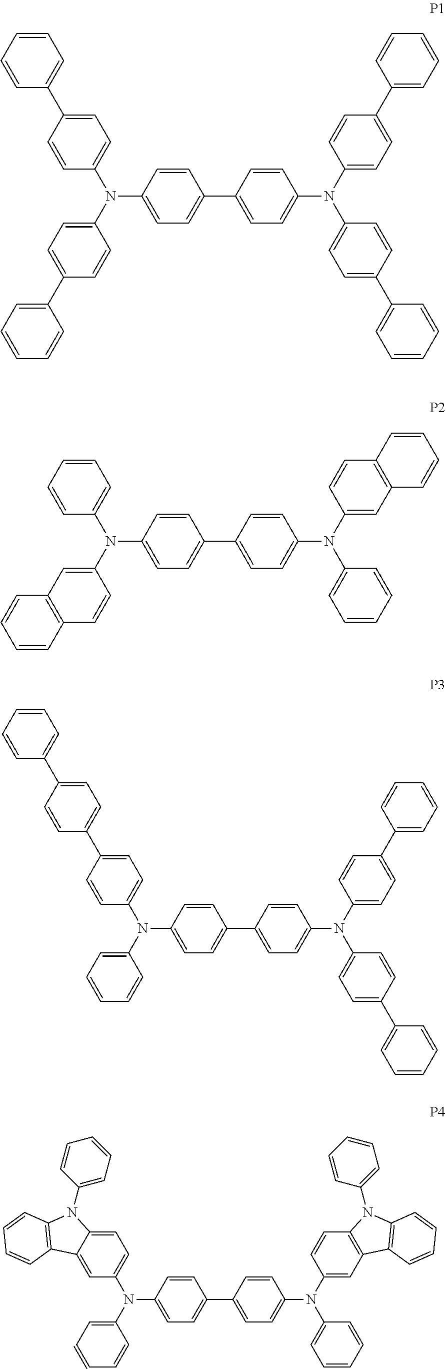 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

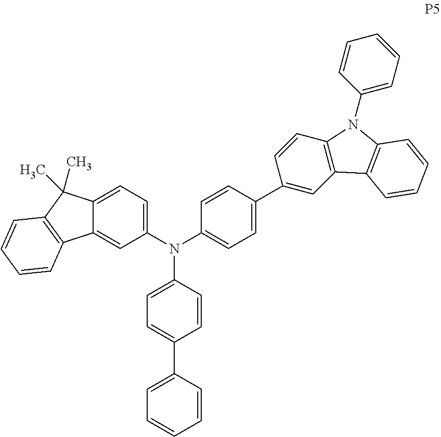 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

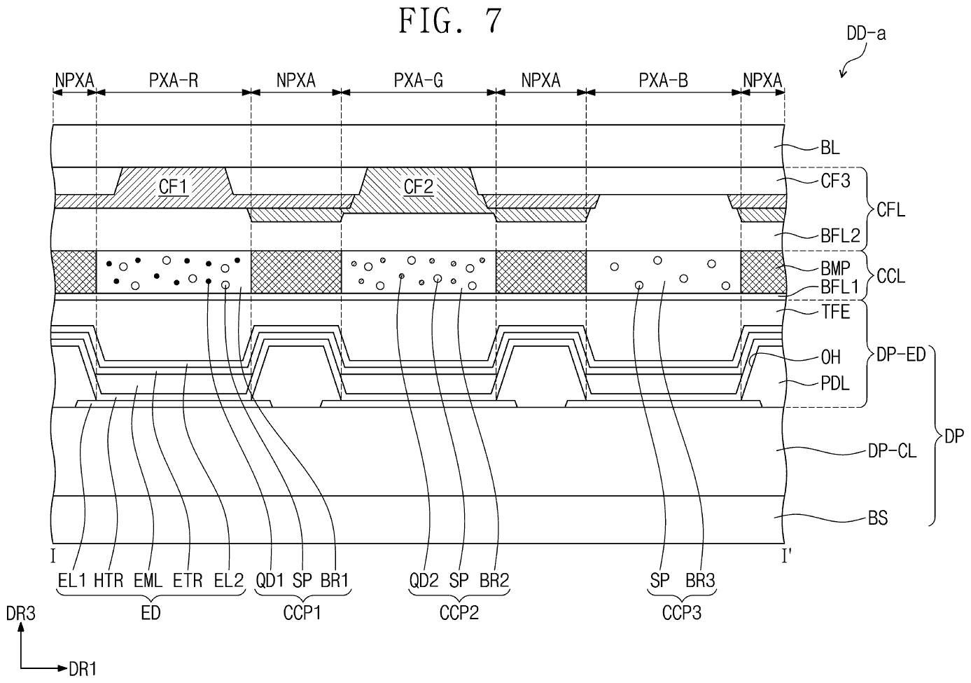

Each of FIGS. 7 to 10 is a cross-sectional view of a display apparatus according to one or more embodiments of the present disclosure. Hereinafter, in describing the display apparatuses of embodiments with reference to FIGS. 7 to 10, the duplicated features which have been described in FIGS. 1 to 6 are not described again, but their differences will be mainly described.

Referring to FIG. 7, the display apparatus DD-a according to one or more embodiments may include a display panel DP including a display device layer DP-ED, a light control layer CCL provided on the display panel DP, and a color filter layer CFL. In one or more embodiments illustrated in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the structures of the light emitting elements of FIGS. 3A to 6 as described above may be equally applied to the structure of the light emitting element ED illustrated in FIG. 7. A light emitting element ED illustrated in FIG. 7 may include, like the light emitting element according to the embodiments, a first sub light emitting layer, a second light emitting layer, and a light emitting auxiliary layer containing auxiliary compounds. Therefore, the light emitting element ED may exhibit long-lifespan characteristics.

Referring to FIG. 7, the emission layer EML may be provided in an opening OH defined in a pixel defining film PDL. For example, the emission layer EML which is divided by the pixel defining film PDL and provided corresponding to each light emitting regions PXA-R, PXA-G, and PXA-B may be to emit (e.g., configured to emit) light in substantially the same wavelength range. In the display apparatus DD-a of one or more embodiments, the emission layer EML may be to emit (e.g., configured to emit) blue light. In some embodiments, unlike the configuration illustrated, in one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be provided between the light control parts CCP1, CCP2 and CCP3 which are spaced apart from each other, but the embodiment of the present disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatter SP.

The scatter SP may be inorganic particles. For example, the scatter SP may include at least one of TiO₂, ZnO, Al₂O₃, SiO₂, or hollow sphere silica. The scatter SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In some embodiments, the barrier layers BFL1 and BFL2 may further include an organic film. The barrier layers BFL1 and BFL2 may be formed of a single layer or a plurality of layers.

In the display apparatus DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

Although not illustrated, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

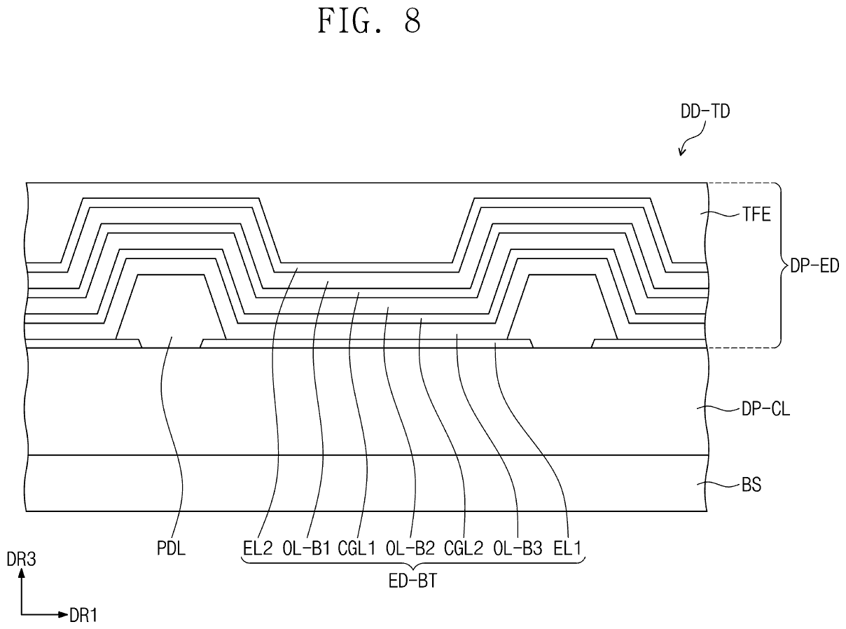

FIG. 8 is a cross-sectional view illustrating a part of a display device according to one or more embodiments. In a display device DD-TD according to one or more embodiments, a light emitting element ED-BT may include a plurality of light emitting structures OL-B1, OL-B2, and OL-B3. At least one among the plurality of the light emitting structures OL-B1, OL-B2, and OL-B3 may include a light emitting layer structure in the light emitting element ED according to one or more embodiments. Therefore, the light emitting element ED-BT may exhibit long-lifespan characteristics.

The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR provided with the emission layer EML (FIG. 7) located therebetween. For example, the light emitting element ED-BT included in the display apparatus DD-TD of one or more embodiments may be a light emitting element having a tandem structure and including a plurality of emission layers.

In one or more embodiments illustrated in FIG. 8, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may be to emit (e.g., configured to emit) white light. In one or more embodiments, at least one among the light emitting structures OL-B1, OL-B2, and OL-B3 may be to emit (e.g., configured to emit) green light, and at least one among the light emitting structures OL-B1, OL-B2, and OL-B3 include a light emitting layer including a first sub light emitting layer, a second sub light emitting layer, and a light emitting auxiliary layer containing auxiliary compounds.

A charge generating layer CGL may be provided between the neighboring light emitting structures OL-B1, OL-B2 and OL-B3. The charge generating layer CGL may include a p-type or kind charge generating layer and/or an n-type or kind charge generating layer.

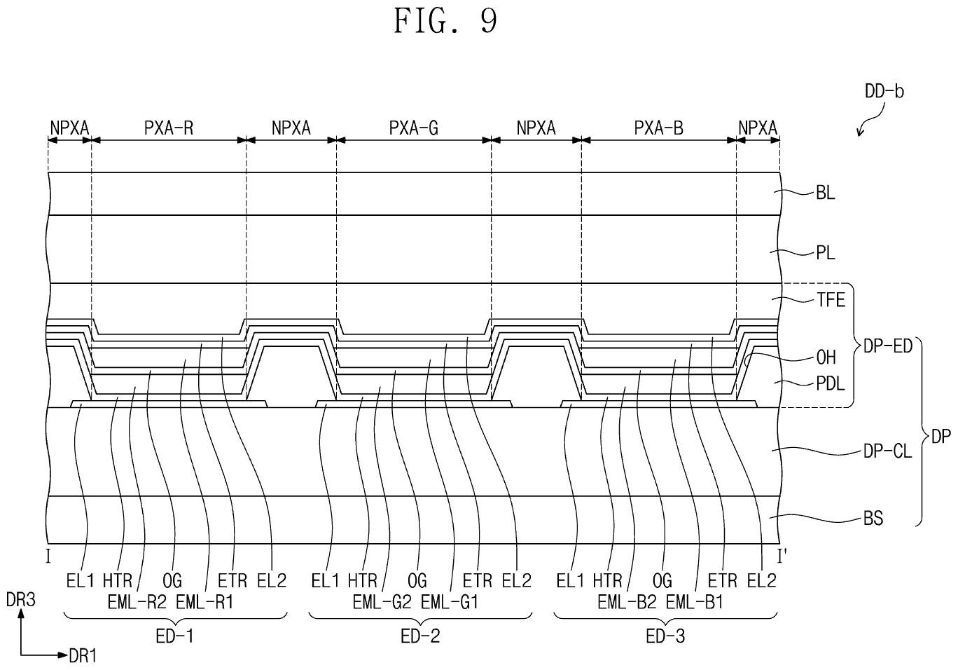

Referring to FIG. 9, a display device DD-b according to one or more embodiments may include light emitting elements ED-1, ED-2 and ED-3, in which two light-emitting layers are stacked. At least one among the light emitting elements ED-1, ED-2, and ED-3 may have a structure of the light emitting element ED according to one or more embodiments, described with reference to FIGS. 3A to 6. For example, at least one among the light emitting elements ED-1, ED-2, and ED-3 may include a light emitting layer including a first sub light emitting layer, a second light emitting layer, and a light emitting auxiliary layer containing auxiliary compounds, thereby exhibiting long-lifespan characteristics.

Compared with the display apparatus DD of one or more embodiments illustrated in FIG. 2, one or more embodiments illustrated in FIG. 9 has a difference in that the first to third light emitting elements ED-1, ED-2, and ED-3 each include two emission layers stacked in the thickness direction. In each of the first to third light emitting elements ED-1, ED-2, and ED-3, the two emission layers may be to emit (e.g., configured to emit) light in substantially the same wavelength region. In one embodiment, at least one of the two light emitting layers in each of the first to third light emitting elements ED-1, ED-2, and ED-3 includes a light emitting layer including a first sub-light emitting layer, a second light emitting layer, and a light emitting auxiliary layer containing an auxiliary compound. Therefore, the light emitting element may exhibit long-lifespan characteristics.

The first light emitting element ED-1 may include a first red emission layer EML-R₁ and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be provided between the electron transport region ETR and the emission auxiliary part OG. The second red emission layer EML-R2, the second green emission layer EML-G2, and the second blue emission layer EML-B2 may be provided between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display device layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display apparatus according to one or more embodiments may not be provided.

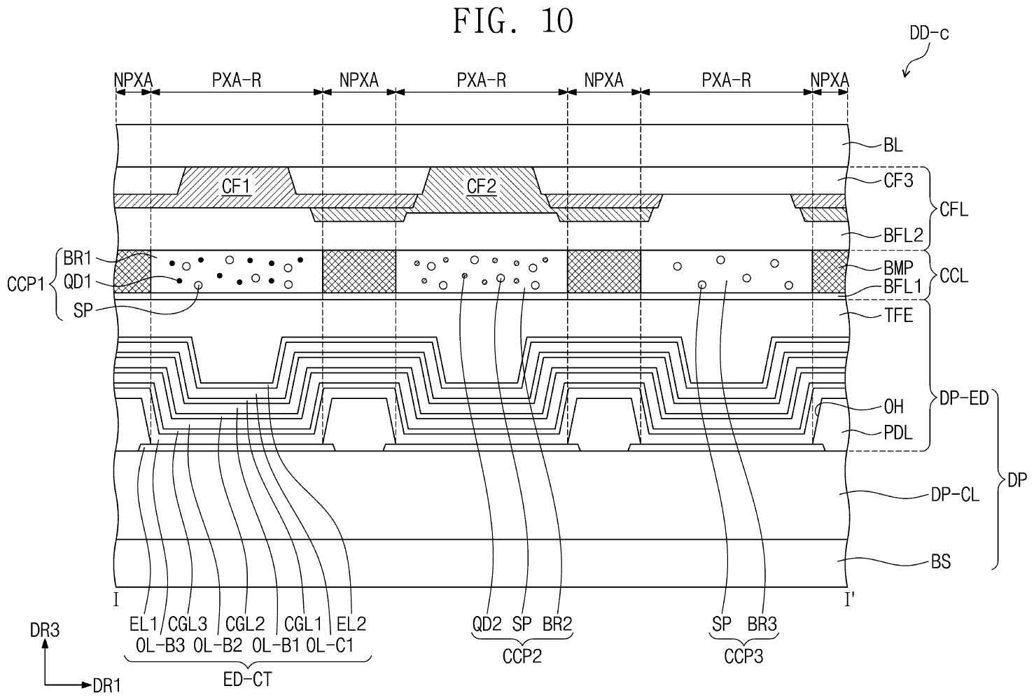

Unlike FIGS. 8 and 9, a display device DD-c in FIG. 10 may include four light emitting structures OL-B1, OL-B2, OL-B3, and OL-C1. A light emitting element ED-CT may include a first electrode EL1 and a second electrode EL2 facing each other, and first to fourth light emitting structures OL-B1, OL-B2, OL-B3, OL-C1 sequentially stacked between the first electrode and the second electrode in a thickness direction. At least one among the first to fourth light emitting structures OL-B1, OL-B2, OL-B3, and OL-C1 may include a light emitting layer including a first sub light emitting layer, a second sub light emitting layer, and a light emitting auxiliary layer containing auxiliary compounds. Therefore, the light emitting element ED-BT may exhibit long-lifespan characteristics.

Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit (e.g., configured to emit) blue light, and the fourth light emitting structure OL-C1 may be to emit (e.g., configured to emit) green light. However, the embodiment of the present disclosure is not limited thereto, and the first to fourth light emitting structures OL-B1, OL-B2, OL-B3, and OL-C1 may be to emit (e.g., configured to emit) light beams in different wavelength regions. The charge generation layers CGL1, CGL2, and CGL3 provided between adjacent light emitting structures OL-B1, OL-B2, OL-B3, and OL-C1 may include a p-type or kind charge generation layer and/or an n-type or kind charge generation layer.

In one or more embodiments, the electronic apparatus may include a display apparatus including a plurality of light emitting elements, and a control part which controls the display apparatus. The electronic apparatus of one or more embodiments may be a device that is activated according to an electrical signal. The electronic apparatus may include display apparatuses of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display apparatus for a vehicle, a game console, a portable electronic device, or a camera.

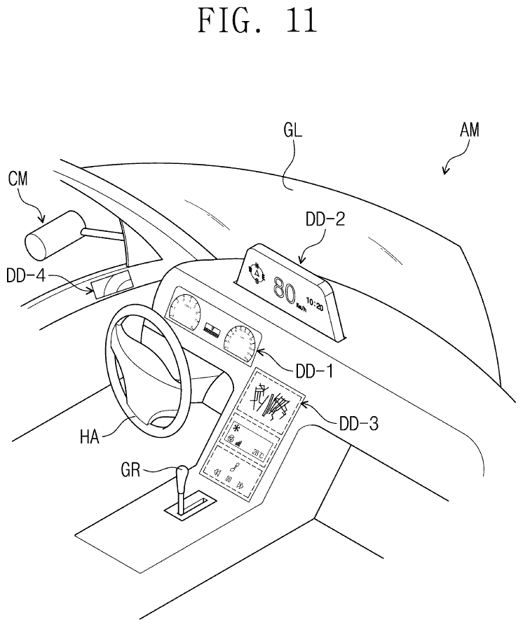

FIG. 11 is a view illustrating a vehicle AM in which first to fourth display apparatuses DD-1, DD-2, DD-3, and DD-4 are disposed. At least one among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 7 to 10.

FIG. 11 illustrates a vehicle AM, but this is an example, and the first to fourth display apparatuses DD-1, DD-2, DD-3, and DD-4 may be provided in another transportation refers to such as bicycles, motorcycles, trains, ships, and airplanes. In some embodiments, at least one among the first to fourth display apparatuses DD-1, DD-2, DD-3, and DD-4 including the same configuration as the display apparatuses DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic apparatuses unless departing from the present disclosure.

At least one (selected from) among first to fourth display devices DD-1, DD-2, DD-3, and DD-4 may include the light emitting element ED described with reference to FIGS. 3A to 6. At least one among the first to fourth display devices DD-1, DD-2, DD-3, and DD-4 may include a light emitting layer according to one or more embodiments, including a first sub light emitting layer, a second light emitting layer, and a light emitting auxiliary layer containing auxiliary compounds. Therefore, the first to fourth display devices DD-1, DD-2, DD-3, and DD-4 including the light emitting element according to one or more embodiments including the light emitting layer according to one or more embodiments including the first sub light emitting layer, the second light emitting layer, and the light emitting auxiliary layer containing auxiliary compounds may have an improved display efficiency and display lifespan.

Referring to FIG. 11, the vehicle AM may include a steering wheel HA and a gear GR for driving the vehicle AM. In some embodiments, the vehicle AM may include a front window GL provided so as to face the driver.

The first display apparatus DD-1 may be provided in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display apparatus DD-2 may be provided in a second region facing the driver's seat and overlapping the front window GL. The driver's seat may be a seat in which the steering wheel HA is disposed. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Unlike the configuration illustrated, the second information of the second display apparatus DD-2 may be projected to the front window GL to be displayed.

The third display apparatus DD-3 may be provided in a third region adjacent to the gear GR. For example, the third display apparatus DD-3 may be provided between the driver's seat and the passenger seat and may be a center information display (CID) for a vehicle for displaying third information. The passenger seat may be a seat spaced apart from the driver's seat with the gear GR provided therebetween. The third information may include information about traffic (e.g., navigation information), playing music or radio or a video (or an image), temperatures inside the vehicle AM, and/or the like.

The fourth display apparatus DD-4 may be spaced apart from the steering wheel HA and the gear GR, and may be provided in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM provided outside the vehicle AM. The fourth information may include an image outside the vehicle AM.

The described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting element, the display device and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting element and/or the display device may be formed on one integrated circuit (IC) chip or on separate IC chips. Further, the various components of the elements and/or devices may be implemented on a flexible printed circuit film, a tape carrier package (TCP), a printed circuit board (PCB), or formed on one substrate. Further, the various components of the elements and/or devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, with reference to Examples and Comparative Examples, a light emitting element of one or more embodiments of the present disclosure will be described in more detail. In some embodiments, Examples described are only illustrations to assist the understanding of the present disclosure, and the scope of the present disclosure is not limited thereto.

### Examples

### 1. Manufacturing Method of Light Emitting Element

### (1) Manufacturing Method of Light Emitting Element According to Example 1

An ITO-patterned glass substrate having a thickness of about 150 nanometer (nm) was ultrasonically washed utilizing isopropyl alcohol and pure water for about 5 minutes each. After ultrasonically washing, UV irradiation was performed for about 30 minutes, and ozone treatment was performed to form a first electrode. Then, a hole transport region was formed by sequentially depositing HAT-CN with a thickness of about 10 nm, α-NPD with a thickness of about 80 nm, and mCP with a thickness of about 5 nm on the first electrode.

Next, a first sub light emitting layer was formed with a thickness of about 17 nm by co-deposition of a DtBuCzB compound and mCBP on the hole transport region. The DtBuCzB compound and mCBP were co-deposited at a weight ratio of about 5:95. In the manufacturing of a light emitting element, the DtBuCzB compound was utilized as a dopant material.

Next, a light emitting auxiliary layer was formed by depositing 4,4-CzSPz at a thickness of about 1 nm on the first sub-light emitting layer.

Thereafter, a second sub light emitting layer was formed with a thickness of about 17 nm by co-deposition of a DtBuCzB compound and mCBP on the light emitting auxiliary layer. The DtBuCzB compound and mCBP were co-deposited at a weight ratio of about 5:95. In the manufacturing of a light emitting element, the DtBuCzB compound was utilized as a dopant material.

An electron transport region was formed by depositing TBPi with a thickness of about 30 nm and depositing LiF with a thickness of about 0.5 nm on the second sub-emitting layer.

A light emitting element was manufactured by depositing Al on the electron transport region to form a second electrode having a thickness of about 100 nm.

In one or more embodiments, the hole transport region, the light emitting layer, the electron transport region, and the second electrode were formed utilizing a vacuum deposition instrument.

Compounds according to Examples and compounds according to Comparative Examples utilized in the manufacturing of the light emitting element are as follows.

### Materials Utilized in Manufacturing of Light Emitting Element

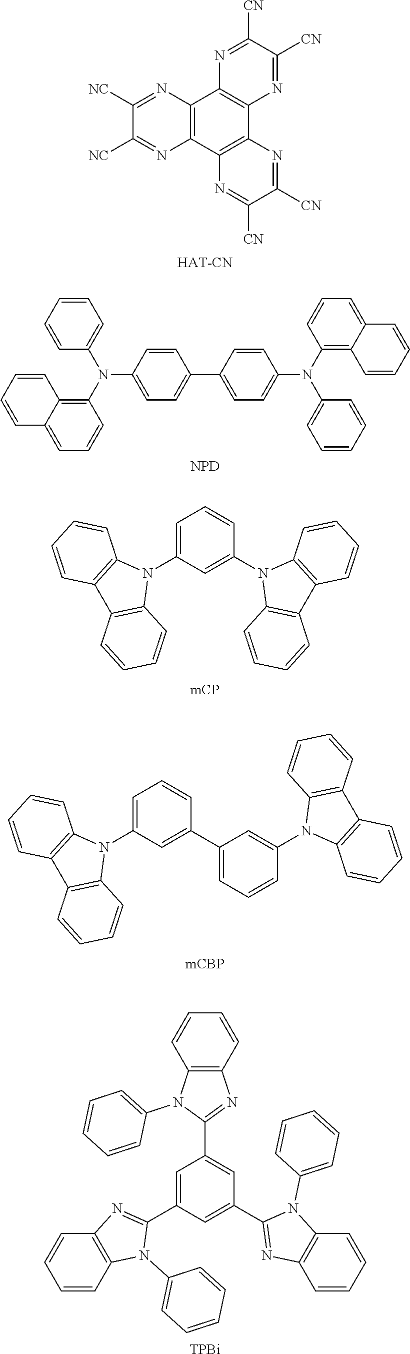

### (2) Manufacturing Method of Light Emitting Element According to Example 2

A light emitting element was manufactured in substantially the same manner as the light emitting element according to Example 1, except that the first sub light emitting layer was deposited with a thickness of about 16.5 nm, the light emitting auxiliary layer was deposited with a thickness of about 2 nm, and the second sub light emitting layer was deposited with a thickness of about 16.5 nm.

### (3) Manufacturing Method of Light Emitting Element According to Example 3

A light emitting element was manufactured in substantially the same manner as the light emitting element according to Example 1, except that the first sub light emitting layer was deposited with a thickness of about 16.0 nm, the light emitting auxiliary layer was deposited with a thickness of about 3 nm, and the second sub light emitting layer was deposited with a thickness of about 16.0 nm.

### (4) Manufacturing Method of Light Emitting Element According to Comparative Example 1

A light emitting element was manufactured in substantially the same manner as the light emitting element according to Example 1, except that the first sub light emitting layer was deposited with a thickness of about 15.5 nm, the light emitting auxiliary layer was deposited with a thickness of about 4 nm, and the second sub light emitting layer was deposited with a thickness of about 15.5 nm.

### (5) Manufacturing Method of Light Emitting Element According to Comparative Example 2

A light emitting element was manufactured in substantially the same manner as the light emitting element according to Example 1, except that a light emitting layer with a thickness of about 35 nm was formed by co-depositing of a DtBuCzB compound and mCBP at a weight ratio of about 5:95 on the hole transport region, and an electron transport region was formed on the light emitting layer.

### 2. Evaluation of Characteristics of Light Emitting Element

Table 1 shows light emitting wavelengths, chromaticity coordinates, element lifespans of the light emitting elements according to Examples 1 to 3 and Comparative Examples 1 and 2. The element lifespan is a relative lifespan with respect to 100% of the element lifespan of the light emitting element according to the Comparative Example. The relative lifespan was obtained with respect to 100% of the lifespan of the light emitting element according to Comparative Example 2 measured when the brightness was 1000 nits, and the lifespans of the light emitting elements of Examples 1 to 4 were expressed as relative values. The chromaticity coordinates represent the x, y values of the CIE chromaticity coordinates.

TABLE 1

| | | | Relative |
|---|---|---|---|
| | Light emitting | Chromaticity | lifespan |
| Classification | wavelength | coordinates | (%) |
| Example 1 | 535 nm | (0.24, 0.72) | 110 |
| Example 2 | 535 nm | (0.24, 0.72) | 120 |
| Example 3 | 535 nm | (0.24, 0.72) | 125 |
| Comparative Example 1 | 535 nm | (0.24, 0.72) | 115 |
| Comparative Example 2 | 535 nm | (0.24, 0.72) | 100 |

In Table 1, light emitting elements according to Examples 1 to 3, Comparative Examples 1 and 2 all exhibit light emitting wavelength characteristics in substantially the same wavelength region. For example, light emitting elements according to Examples 1 to 3, and Comparative Examples 1 and 2 each emit green light. Comparing the light emitting elements according to Examples 1 to 3 with the light emitting element according to Comparative Example 2 may demonstrate that the light emitting element including the light emitting auxiliary layer has a longer element lifespan than the light emitting element including no light emitting auxiliary layer. As a result, it may be confirmed that the element lifespan is improved when the light emitting auxiliary layer containing auxiliary compounds is included in the light emitting layer.

In some embodiments, comparing Examples 1 to 3 with Comparative Example 1 may verify that when the thickness of the light emitting auxiliary layer exceeds about 3 nm, the element lifespan decreases. As a result, it may be confirmed the lifespan of the light emitting element is improved when the thickness of the light emitting auxiliary layer is controlled or selected to 3 nm or less.

The light emitting element according to one or more embodiments may include a first sub light emitting layer, a light emitting auxiliary layer and a second sub light emitting layer, which are stacked in sequence. The light emitting auxiliary layer may be a layer that emits light by quenching of the excitons formed from the first sub light emitting layer and the second sub light emitting-layer. The light emitting element according to one or more embodiments may include the first sub light emitting layer, the light emitting auxiliary layer, and the second sub light emitting auxiliary layer, and thus exhibit excellent or suitable light emission efficiency and long-lifespan characteristics.

The light emitting auxiliary layer contains auxiliary compounds exhibiting aggregation-induced emission characteristics. The auxiliary compounds exhibit a higher external quantum efficiency when aggregated or crystallized than when dispersed. In some embodiments, the light emitting auxiliary layer containing auxiliary compounds exhibits an excellent or suitable external quantum efficiency in an undoped state. Therefore, a light emitting element including a light emitting auxiliary layer may exhibit high efficiency and long-lifespan characteristics.

A light emitting element according to one or more embodiments may include a light emitting auxiliary layer containing auxiliary compounds with aggregation-induced emission, thereby exhibiting long-lifespan characteristics.

A display device according to one or more embodiments may include a light emitting element including a light emitting auxiliary layer containing auxiliary compounds with aggregation-induced emission, thereby exhibiting long-lifespan characteristics.

Hitherto, the present disclosure has been described with reference to a preferred embodiment of the present disclosure, but it is understood by those skilled in the art or having ordinary knowledge of the art that one or more suitable changes and modifications can be made without departing from the spirit and scope of the present disclosure as hereinafter claimed.

Accordingly, it is understood that the technical scope of the present disclosure should not be limited to the contents set forth in the detailed description of the specification, but be defined by the appended claims and equivalents thereof.

What is claimed is:

1. A light emitting element comprising:
a first electrode;
a hole transport region on the first electrode;
a light emitting layer on the hole transport region;
an electron transport region on the light emitting layer; and
a second electrode on the electron transport region,
wherein the light emitting layer comprises
a first sub light emitting layer adjacent to the first electrode,
a second sub light emitting layer on the first sub light emitting layer, and
a light emitting auxiliary layer between the first sub light emitting layer and the second sub light emitting layer, and comprising a plurality of auxiliary compounds,
the first sub light emitting layer and the second sub light emitting layer each comprise a first compound different from the auxiliary compounds,
the light emitting auxiliary layer comprises a first state in which an average separation distance between the auxiliary compounds is a first distance, and a second state in which an average separation distance between the auxiliary compounds is a second distance smaller than the first distance, and
an external quantum efficiency when the light emitting auxiliary layer is in the second state is larger than an external quantum efficiency when the light emitting auxiliary layer is in the first state.

2. The light emitting element of claim 1, wherein
the first compound has a lowest energy level of a first excited singlet state and a lowest energy level of a first excited triplet state, and a difference between the lowest energy level of the first excited singlet and the lowest energy level of the first excited triplet state is a first energy gap,
the auxiliary compounds each have a lowest energy level of a second excited singlet state and a lowest energy level of a second excited triplet state, and a difference between the lowest energy level of the second excited singlet state and the lowest energy level of the second excited triplet state is a second energy gap, and
the second energy gap is smaller than the first energy gap.

3. The light emitting element of claim 3, wherein
the first sub light emitting layer and the second sub light emitting layer each is configured to emit light having a center wavelength of about 500 nanometer (nm) to about 560 nm.

4. The light emitting element of claim 3, wherein
the light emitting auxiliary layer is configured to emit light having a center wavelength of about 500 nm to about 560 nm.

5. The light emitting element of claim 1, wherein
the light emitting auxiliary layer has a thickness of greater than about 0 nm and less than or equal to about 3 nm.

6. The light emitting element of claim 1, wherein
the light emitting auxiliary layer is directly on the first sub light emitting layer, and
the second sub light emitting layer is directly on the light emitting auxiliary layer.

7. The light emitting element of claim 1, wherein
the first sub light emitting layer and the second sub light emitting layer each is configured to emit thermally activated delayed fluorescence.

8. The light emitting element of claim 1, wherein
the auxiliary compounds include a substituted or unsubstituted carbazole group or a substituted or unsubstituted triazine group.

9. The light emitting element of claim 8, wherein
the auxiliary compounds include at least one of 4,4-CzSPz, DMAC-TRZ, CP-BP-DMAC, CP-BP-PXZ, CP-BP-PTZ, or PTSOPO.

10. The light emitting element of claim 1, wherein
the first compound is represented by Formula F-c: 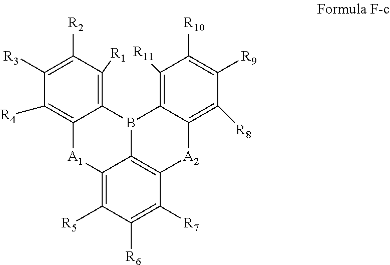
wherein, in Formula F-c,
A₁ and A₂ are each independently O, S, Se, or NRₘ,
Rₘ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R₁ to R₁₁ are each independently, a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

11. The light emitting element of claim 1, wherein
each of the first sub light emitting layer and the second sub light emitting layer further comprises a second compound and a third compound which are different from the first compound,
the second compound is represented by Formula HT-1, and
the third compound is represented by ET-1: 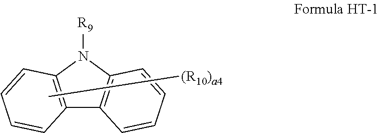
wherein, in Formula HT-1,
a4 is an integer of 0 to 8, and
R₉ and R₁₀ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. 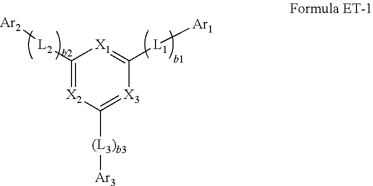
wherein, in Formula ET-1,
at least one among Y₁ to Y₃ is N, and each of the remaining Y₁ to Y₃ is CRₐ,
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

12. The light emitting element of claim 10, wherein
each of the first sub light emitting layer and the second sub light emitting layer further comprises a fourth compound represented by Formula D-1: 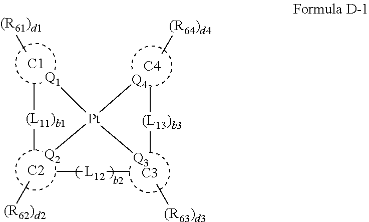
wherein, in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted hetero ring having 2 to 30 ring-forming carbon atoms,
L₁₁ to L₁₃ are each independently a direct linkage, 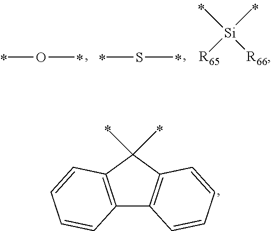
a substituted or unsubstituted divalent alkyl group having 1 to 20 carbon atoms, a substituted or unsubstituted arylene group having 6 to 30 carbon atoms, or a substituted or unsubstituted heteroarylene group having 2 to 30 ring-forming carbon atoms,
b1 to b3 are each independently 0 or 1,
d1 to d4 are each independently an integer of 0 to 4, and
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

13. A display device, divided into a first light emitting region emitting red light, a second light emitting region emitting green light, and a third light emitting region emitting blue light, the display device comprising:
a base layer, and
a display element layer on the base layer, and comprising first to third light emitting elements corresponding to the first to third light emitting regions, respectively,
wherein the first to third light emitting elements each include
a first electrode,
a light emitting layer on the first electrode, and
a second electrode on the light emitting layer,
the light emitting layer of the second light emitting element comprises
a first sub light emitting layer adjacent to the first electrode,
a second sub light emitting layer on the first sub light emitting layer, and
a light emitting auxiliary layer between the first sub light emitting layer and the second sub light emitting layer,
the first sub light emitting layer and the second sub light emitting layer each include a first compound which is a dopant, a second compound which is a hole transporting host, and a third compound which is an electron transporting host,
the light emitting auxiliary layer comprises auxiliary compounds different from the first compound,
the light emitting auxiliary layer comprises a first state in which an average separation distance between the auxiliary compounds is a first distance, and a second state in which an average separation distance between the auxiliary compounds is a second distance smaller than the first distance, and
an external quantum efficiency when the light emitting auxiliary layer is in the second state is larger than an external quantum efficiency when the light emitting auxiliary layer is in the first state.

14. The display device of claim 13, wherein
the first compound has a lowest energy level of a first excited singlet state and a lowest energy level of a first excited triplet state, and a difference between the lowest energy level of the first excited singlet state and the lowest energy level of the first excited triplet state is a first energy gap,
the auxiliary compounds have a lowest energy level of a second excited singlet state and a lowest energy level of a second excited triplet state, and a difference between the lowest energy level of the second excited singlet state and the lowest energy level of the second excited triplet state is a second energy gap, and
the second energy gap is smaller than the first energy gap.

15. The display device of claim 13, wherein
the light emitting auxiliary layer has a thickness of greater than about 0 nm and less than or equal to 3 nm.

16. The display device of claim 13, wherein
the light emitting auxiliary layer is directly on the first sub light emitting layer, and
the second sub light emitting layer is directly on the light emitting auxiliary layer.

17. The display device of claim 13, further comprising
a light control layer on the display element layer and comprising a quantum dot.

18. A display device, divided into a first light emitting region emitting red light, a second light emitting region emitting green light, and a third light emitting region emitting blue light, the display device comprising:
a base layer; and
a display element layer on the base layer, and comprising first to third light emitting elements corresponding to the first to third light emitting regions, respectively, wherein
each of the first to third light emitting elements comprises
a first electrode,
a light emitting layer on the first electrode, and
a second electrode on the light emitting layer,
the light emitting layer of the second light emitting element comprises
a first sub light emitting layer adjacent to the first electrode,
a second sub light emitting layer on the first sub light emitting layer, and
a light emitting auxiliary layer between the first sub light emitting layer and the second sub light emitting layer,
the first sub light emitting layer and the second sub light emitting layer each comprise a first compound,
the light emitting auxiliary layer comprises auxiliary compounds different from the first compound,
the light emitting auxiliary layer comprises a first state in which an average separation distance between the auxiliary compounds is a first distance, and a second state in which an average separation distance between the auxiliary compounds is a second distance smaller than the first distance, and
an external quantum efficiency when the light emitting auxiliary layer is in the second state is larger than an external quantum efficiency when the light emitting auxiliary layer is in the first state.

19. The display device of claim 18, wherein
the light emitting auxiliary layer has a thickness of greater than about 0 nm and less than or equal to about 3 nm.

20. The display device of claim 18, wherein
the first compound has a lowest energy level of a first excited singlet state and a lowest energy level of a first excited triplet state, and a difference between the lowest energy level of the first excited singlet state and the lowest energy level of the first excited triplet state is a first energy gap,
the auxiliary compounds have a lowest energy level of a second excited singlet state and a lowest energy level of a second excited triplet state, and a difference between the lowest energy level of the second excited singlet state and the lowest energy level of the second excited triplet state is a second energy gap, and
the second energy gap is smaller than the first energy gap.

21. The display device of claim 18, wherein
the light emitting auxiliary layer is directly on the first sub light emitting layer, and
the second sub light emitting layer is directly on the light emitting auxiliary layer.
